(19) United States
(12) Patent Application Publication
(10) Pub. No.: US 2023/0047644 A1
(43) Pub. Date: Feb. 16, 2023

(54) SEMICONDUCTOR STORAGE DEVICE

(71) Applicant: Kioxia Corporation, Tokyo (JP)

(72) Inventors: Shota KASHIYAMA, Yokkaichi Mie (JP); Weili CAI, Yokkaichi Mie (JP)

(73) Assignee: Kioxia Corporation, Tokyo (JP)

(21) Appl. No.: 17/835,180

(22) Filed: Jun. 8, 2022

(30) Foreign Application Priority Data
Aug. 11, 2021 (JP) 2021-131302

(51) Int. Cl. H01L 27/11582; H01L 27/11556

(52) U.S. Cl. CPC H01L 27/11582; H01L 27/11556

(57) ABSTRACT

A semiconductor storage device according to an embodiment includes a substrate, an interconnection layer region, a multi-layered body, a semiconductor body, and a columnar part. The multi-layered body has an end portion facing the interconnection layer region as an end portion in the first direction. The columnar part includes a first portion and a second portion, the first portion is at the end portion of the multi-layered body, the second portion is closer to the substrate than the first portion is. The first portion has a center. The second portion has a center. The center of the second portion in a second direction is displaced in the second direction with respect to the center of the first portion in the second direction. The second direction crosses the first direction.

### CROSS-REFERENCE TO RELATED APPLICATION

This application is based upon and claims the benefit of priority from Japanese Patent Application No. 2021-131302, filed Aug. 11, 2021; the entire contents of which are incorporated herein by reference.

### FIELD

Embodiments described herein relate generally to a semiconductor storage device.

### BACKGROUND ART

A three-dimensional memory device including a multi-layered body having a plurality of conductive layers and a plurality of insulating layers which are alternately stacked and having a plurality of columnar parts penetrating the multi-layered body in a thickness direction is known.

### BRIEF DESCRIPTION OF THE DRAWINGS

FIG. 1 is a schematic plan view showing a semiconductor storage device according to a first embodiment.

FIG. 2 is a schematic plan view showing a cell array region of the semiconductor storage device according to the first embodiment.

FIG. 3 is a schematic perspective view showing the cell array region according to the first embodiment.

FIG. 4 is a cross-sectional view taken along line A-A′ shown in FIG. 2 including a multi-layered body and a columnar part.

FIG. 5 is a partially enlarged cross-sectional view showing the columnar part of FIG. 4.

FIG. 6 is a cross-sectional view taken along line D-D′ of the multi-layered body and the columnar part shown in FIG. 5.

FIG. 7 is a partial cross-sectional view showing one example of the multi-layered body, the columnar part, and an interconnection layer region shown in FIG. 4.

FIG. 8 is a partial cross-sectional view showing another example of the multi-layered body, the columnar part, and the interconnection layer region shown in FIG. 4.

FIG. 9 is a cross-sectional view for explaining a method of manufacturing a part of one example structure according to the first embodiment.

FIG. 10 is a cross-sectional view for explaining the method of manufacturing a part of one example structure according to the first embodiment.

FIG. 11 is a cross-sectional view for explaining the method of manufacturing a part of one example structure according to the first embodiment.

FIG. 12 is a cross-sectional view for explaining the method of manufacturing a part of one example structure according to the first embodiment.

FIG. 13 is a cross-sectional view for explaining the method of manufacturing a part of one example structure according to the first embodiment.

FIG. 14 is a cross-sectional view for explaining the method of manufacturing a part of one example structure according to the first embodiment.

FIG. 15 is a cross-sectional view for explaining the method of manufacturing a part of one example structure according to the first embodiment.

FIG. 16 is a cross-sectional view for explaining the method of manufacturing a part of one example structure according to the first embodiment.

FIG. 17 is a cross-sectional view for explaining the method of manufacturing a part of one example structure according to the first embodiment.

FIG. 18 is a cross-sectional view for explaining the method of manufacturing a part of one example structure according to the first embodiment.

FIG. 19 is a cross-sectional view for explaining the method of manufacturing a part of one example structure according to the first embodiment.

FIG. 20 is a cross-sectional view for explaining the method of manufacturing a part of one example structure according to the first embodiment.

FIG. 21 is a cross-sectional view for explaining the method of manufacturing a part of one example structure according to the first embodiment.

FIG. 22 is a cross-sectional view for explaining the method of manufacturing a part of one example structure according to the first embodiment.

FIG. 23 is a cross-sectional view for explaining the method of manufacturing a part of one example structure according to the first embodiment.

FIG. 24 is a cross-sectional view for explaining a method of manufacturing a part of one example structure according to a second embodiment.

FIG. 25 is a cross-sectional view for explaining the method of manufacturing a part of one example structure according to the second embodiment.

FIG. 26 is a cross-sectional view for explaining the method of manufacturing a part of one example structure according to the second embodiment.

FIG. 27 is a cross-sectional view for explaining the method of manufacturing a part of one example structure according to the second embodiment.

FIG. 28 is a cross-sectional view for explaining the method of manufacturing a part of one example structure according to the second embodiment.

FIG. 29 is a cross-sectional view for explaining the method of manufacturing a part of one example structure according to the second embodiment.

FIG. 30 is a cross-sectional view for explaining the method of manufacturing a part of one example structure according to the second embodiment.

FIG. 31 is a cross-sectional view for explaining the method of manufacturing a part of one example structure according to the second embodiment.

FIG. 32 is a cross-sectional view for explaining the method of manufacturing a part of one example structure according to the second embodiment.

FIG. 33 is a cross-sectional view for explaining the method of manufacturing a part of one example structure according to the second embodiment.

FIG. 34 is a cross-sectional view for explaining the method of manufacturing a part of one example structure according to the second embodiment.

FIG. 35 is a cross-sectional view for explaining the method of manufacturing a part of one example structure according to the second embodiment.

FIG. 36 is a cross-sectional view for explaining the method of manufacturing a part of one example structure according to the second embodiment.

FIG. 37 is a cross-sectional view for explaining the method of manufacturing a part of one example structure according to the second embodiment.

FIG. 38 is a cross-sectional view for explaining the method of manufacturing a part of one example structure according to the second embodiment.

FIG. 39 is a partial cross-sectional view showing one example of a multi-layered body, a columnar part, and an interconnection layer region according to the second embodiment.

FIG. 40 is a cross-sectional view showing another example of the multi-layered body, the columnar part, and the interconnection layer region according to the second embodiment.

FIG. 41 is a partial cross-sectional view showing one example of a lower end portion of a columnar part and a lower end portion of an insulating part according to a third embodiment.

FIG. 42 is a partial cross-sectional view showing one example of a lower end portion of a columnar part and a lower end portion of an insulating part according to a fourth embodiment.

FIG. 43 is a cross-sectional view for explaining a method of manufacturing a part of one example structure according to the third embodiment.

FIG. 44 is a cross-sectional view for explaining the method of manufacturing a part of one example structure according to the third embodiment.

FIG. 45 is a cross-sectional view for explaining the method of manufacturing a part of one example structure according to the third embodiment.

FIG. 46 is a cross-sectional view for explaining the method of manufacturing a part of one example structure according to the third embodiment.

FIG. 47 is a cross-sectional view for explaining the method of manufacturing a part of one example structure according to the third embodiment.

FIG. 48 is a cross-sectional view for explaining the method of manufacturing a part of one example structure according to the third embodiment.

FIG. 49 is a cross-sectional view for explaining the method of manufacturing a part of one example structure according to the third embodiment.

FIG. 50 is a cross-sectional view for explaining the method of manufacturing a part of one example structure according to the third embodiment.

FIG. 51 is a cross-sectional view for explaining the method of manufacturing a part of one example structure according to the third embodiment.

FIG. 52 is a cross-sectional view for explaining the method of manufacturing a part of one example structure according to the third embodiment.

FIG. 53 is a cross-sectional view for explaining the method of manufacturing a part of one example structure according to the third embodiment.

FIG. 54 is a cross-sectional view for explaining the method of manufacturing a part of one example structure according to the third embodiment.

FIG. 55 is a cross-sectional view for explaining the method of manufacturing a part of one example structure according to the third embodiment.

FIG. 56 is a cross-sectional view for explaining the method of manufacturing a part of one example structure according to the third embodiment.

FIG. 57 is a cross-sectional view for explaining the method of manufacturing a part of one example structure according to the third embodiment.

FIG. 58 is a cross-sectional view for explaining the method of manufacturing a part of one example structure according to the third embodiment.

FIG. 59 is a cross-sectional view for explaining the method of manufacturing a part of one example structure according to the third embodiment.

FIG. 60 is a cross-sectional view for explaining the method of manufacturing a part of one example structure according to the third embodiment.

FIG. 61 is a cross-sectional view for explaining the method of manufacturing a part of one example structure according to the third embodiment.

FIG. 62 is a cross-sectional view for explaining the method of manufacturing a part of one example structure according to the third embodiment.

FIG. 63 is a cross-sectional view for explaining the method of manufacturing a part of one example structure according to the third embodiment.

FIG. 64 is a cross-sectional view for explaining the method of manufacturing a part of one example structure according to the third embodiment.

FIG. 65 is a cross-sectional view for explaining the method of manufacturing a part of one example structure according to the third embodiment.

FIG. 66 is a cross-sectional view for explaining the method of manufacturing a part of one example structure according to the third embodiment.

FIG. 67 is a cross-sectional view for explaining the method of manufacturing a part of one example structure according to the third embodiment.

FIG. 68 is a cross-sectional view for explaining the method of manufacturing a part of one example structure according to the third embodiment.

FIG. 69 is a cross-sectional view for explaining the method of manufacturing a part of one example structure according to the third embodiment.

FIG. 70 is a cross-sectional view for explaining the method of manufacturing a part of one example structure according to the third embodiment.

FIG. 71 is a cross-sectional view for explaining the method of manufacturing a part of one example structure according to the third embodiment.

FIG. 72 is a cross-sectional view for explaining the method of manufacturing a part of one example structure according to the third embodiment.

FIG. 73 is a cross-sectional view for explaining the method of manufacturing a part of one example structure according to the third embodiment.

FIG. 74 is a cross-sectional view for explaining the method of manufacturing a part of one example structure according to the third embodiment.

FIG. 75 is a cross-sectional view for explaining the method of manufacturing a part of one example structure according to the third embodiment.

FIG. 76 is a cross-sectional view for explaining the method of manufacturing a part of one example structure according to the third embodiment.

FIG. 77 is a cross-sectional view for explaining the method of manufacturing a part of one example structure according to the third embodiment.

FIG. 78 is a cross-sectional view for explaining the method of manufacturing a part of one example structure according to the third embodiment.

FIG. 79 is a cross-sectional view for explaining the method of manufacturing a part of one example structure according to the third embodiment.

FIG. 80 is a cross-sectional view for explaining the method of manufacturing a part of one example structure according to the third embodiment.

FIG. 81 is a cross-sectional view for explaining the method of manufacturing a part of one example structure according to the third embodiment.

FIG. 82 is a cross-sectional view for explaining the method of manufacturing a part of one example structure according to the third embodiment.

FIG. 83 is a cross-sectional view for explaining a method of manufacturing a part of one example structure according to the fourth embodiment.

FIG. 84 is a cross-sectional view for explaining the method of manufacturing a part of one example structure according to the fourth embodiment.

FIG. 85 is a cross-sectional view for explaining the method of manufacturing a part of one example structure according to the fourth embodiment.

FIG. 86 is a cross-sectional view for explaining the method of manufacturing a part of one example structure according to the fourth embodiment.

FIG. 87 is a cross-sectional view for explaining the method of manufacturing a part of one example structure according to the fourth embodiment.

FIG. 88 is a cross-sectional view for explaining the method of manufacturing a part of one example structure according to the fourth embodiment.

FIG. 89 is a cross-sectional view for explaining the method of manufacturing a part of one example structure according to the fourth embodiment.

FIG. 90 is a cross-sectional view for explaining the method of manufacturing a part of one example structure according to the fourth embodiment.

FIG. 91 is a cross-sectional view for explaining the method of manufacturing a part of one example structure according to the fourth embodiment.

FIG. 92 is a cross-sectional view for explaining the method of manufacturing a part of one example structure according to the fourth embodiment.

FIG. 93 is a cross-sectional view for explaining the method of manufacturing a part of one example structure according to the fourth embodiment.

FIG. 94 is a cross-sectional view for explaining the method of manufacturing a part of one example structure according to the fourth embodiment.

FIG. 95 is a cross-sectional view for explaining the method of manufacturing a part of one example structure according to the fourth embodiment.

FIG. 96 is a cross-sectional view for explaining the method of manufacturing a part of one example structure according to the fourth embodiment.

FIG. 97 is a cross-sectional view for explaining the method of manufacturing a part of one example structure according to the fourth embodiment.

FIG. 98 is a cross-sectional view for explaining the method of manufacturing a part of one example structure according to the fourth embodiment.

FIG. 99 is a cross-sectional view for explaining the method of manufacturing a part of one example structure according to the fourth embodiment.

FIG. 100 is a cross-sectional view for explaining the method of manufacturing a part of one example structure according to the fourth embodiment.

FIG. 101 is a cross-sectional view for explaining the method of manufacturing a part of one example structure according to the fourth embodiment.

FIG. 102 is a cross-sectional view for explaining the method of manufacturing a part of one example structure according to the fourth embodiment.

FIG. 103 is a cross-sectional view for explaining the method of manufacturing a part of one example structure according to the fourth embodiment.

### DETAILED DESCRIPTION

A semiconductor storage device according to an embodiment includes a substrate, an interconnection layer region, a multi-layered body, a semiconductor body, and a columnar part. The interconnection layer region is on the substrate. The multi-layered body is on the interconnection layer region. The multi-layered body includes a plurality of conductive layers and a plurality of insulating layers. The plurality of the conductive layers and the plurality of the insulating layers are alternately stacked one layer by one layer in a first direction. The first direction is a thickness direction of the substrate. The columnar part includes a semiconductor body and a memory part. The semiconductor body extends in the first direction. The memory part is between the semiconductor body and each of the plurality of the conductive layers. The columnar part penetrates the multi-layered body. The columnar part is connected to the interconnection layer region. The multi-layered body has an end portion facing the interconnection layer region as an end portion in the first direction. The columnar part includes a first portion and a second portion. The first portion is at the end portion of the multi-layered body. The second portion is closer to the substrate than the first portion is. The first portion has a center. The second portion has a center. The center of the second portion in a second direction is displaced in the second direction with respect to the center of the first portion in the second direction. The second direction crosses the first direction.

### First Embodiment

Hereinafter, a semiconductor storage device according to a first embodiment will be described with reference to the drawings.

In the following description, components having the same or similar functions are denoted by the same reference signs. Also, duplicate description of the components may be omitted. In the present application, “connection” is not limited to a case of being physically connected, and also includes a case of being electrically connected. In the present application, “xx faces yy” is not limited to a case in which xx is in contact with yy, and also includes a case in which another member is interposed between xx and yy. In the present application, “xx is provided on yy” is not limited to a case in which xx is in contact with yy, and also includes a case in which another member is interposed between xx and yy. Also, in the present application, “xx is provided on yy” is an expression for convenience only and does not define the direction of gravity. In the present specification, “parallel” and “perpendicular” also include cases of “substantially parallel” and “substantially perpendicular”.

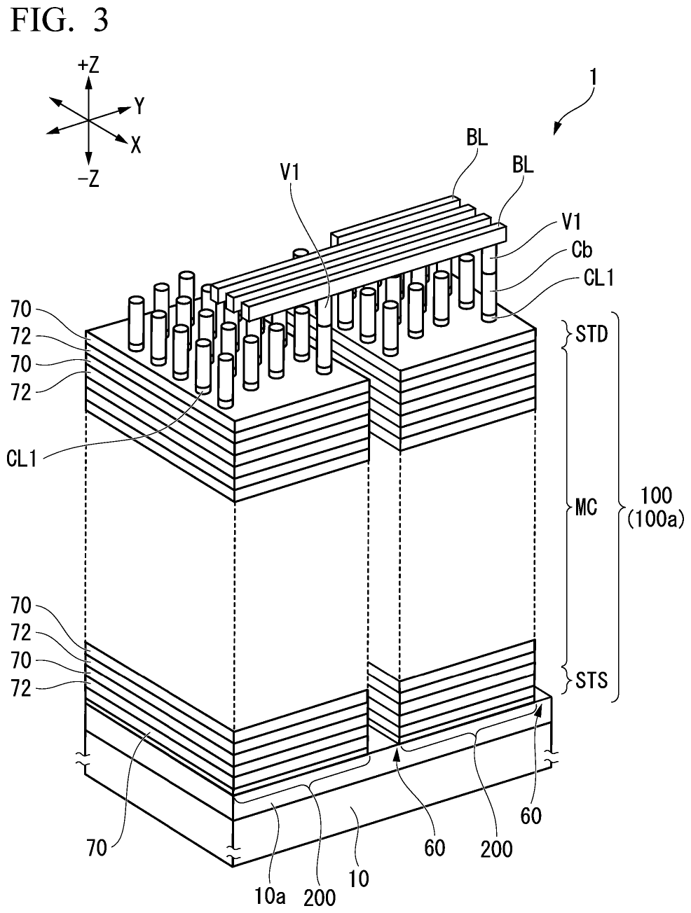

Also, an X direction, a Y direction, and a Z direction will be defined first. The X direction and the Y direction are directions along a surface of a semiconductor substrate 10 (see FIG. 3) to be described later. The X direction and the Y direction are directions intersecting each other (for example, being perpendicular to each other). That is, the Y direction crosses the X direction. The Y direction is a direction in which a bit line BL (see FIG. 3) to be described later extends. The Z direction (first direction) is a direction intersecting (for example, being perpendicular to) the X direction and the Y direction, and is a thickness direction of the semiconductor substrate 10. That is, the Z direction crosses the X direction and the Y direction. In the present specification, the “+Z direction” may be referred to as “upward” and the “−Z direction” may be referred to as “downward” as shown in FIG. 3. The +Z direction and the −Z direction are different directions by 180°. However, these expressions are for convenience only and do not define the direction of gravity.

### <Overall Configuration of Semiconductor Storage Device>

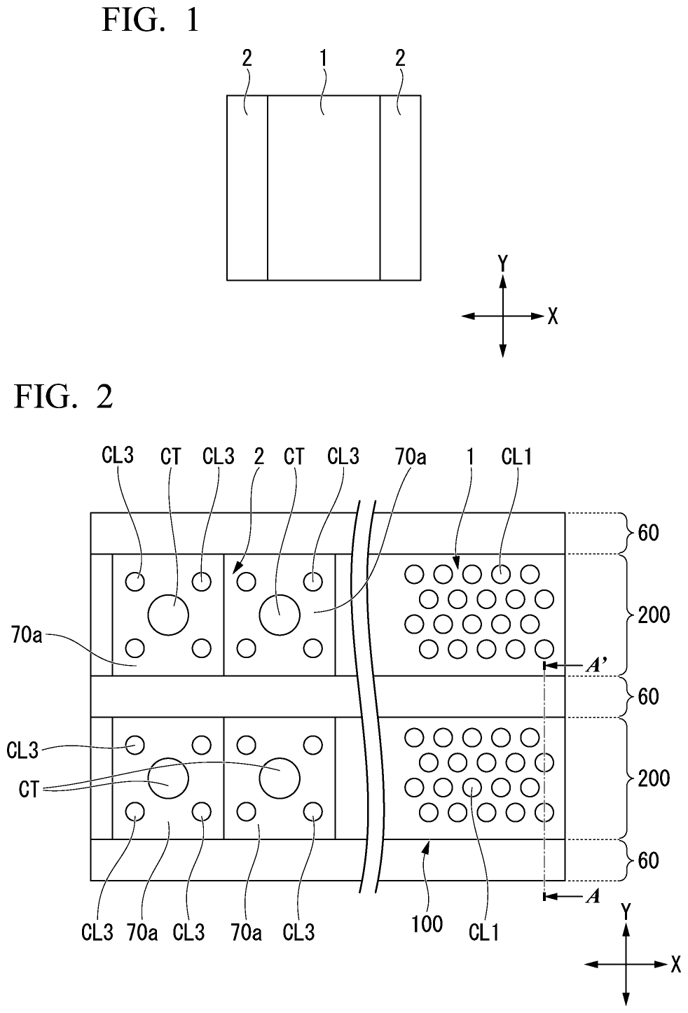

FIG. 1 is a schematic plan view showing a semiconductor storage device according to the first embodiment.

The semiconductor storage device according to the first embodiment includes a memory cell array 1 and a plurality of staircase parts 2 provided in a peripheral region positioned outside of the memory cell array 1. The memory cell array 1 and the plurality of the staircase parts 2 are provided on the same semiconductor substrate 10.

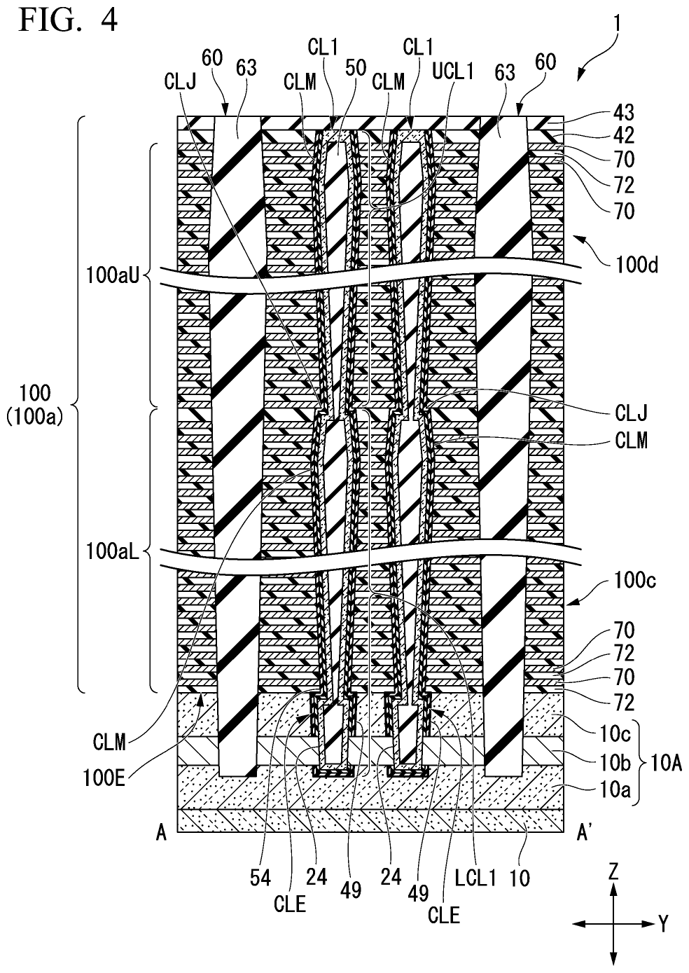

FIG. 2 is a schematic plan view showing the cell array 1 and the staircase part 2 of the semiconductor storage device according to the first embodiment. FIG. 3 is a schematic perspective view showing the memory cell array 1 according to the first embodiment. FIG. 4 is a cross-sectional view taken along line A-A′ of FIG. 2 including a multi-layered body 100 and a columnar part CL1.

As shown in FIGS. 2 to 4, the memory cell array 1 includes a part of the substrate 10, a part of the multi-layered body 100 provided on the substrate 10, a plurality of columnar parts CL1, a plurality of insulating parts 60, and an upper layer interconnection provided above the multi-layered body 100. As the upper layer interconnection, for example, a bit line 131 is shown in FIG. 3.

The substrate 10 and the multi-layered body 100 are provided across a cell array region and a staircase region. The staircase parts 2 are provided in the staircase region. The memory cell array 1 is provided in the cell array region. A portion of the multi-layered body 100 provided in the cell array region is referred to as a first multi-layered part 100a (see FIG. 3, 4, or the like). The plurality of the columnar parts CL1 are disposed in the cell array region. The columnar part CL1 has a columnar shape extending in the first multi-layered part 100a in a stacking direction (Z direction) thereof.

As shown in FIG. 2, the plurality of the columnar parts CL1 are disposed, for example, in a staggered manner. Alternatively, the plurality of the columnar parts CL1 may be disposed in a square lattice shape in the X direction and the Y direction. The insulating part 60 extends through the cell array region and the staircase region in the X direction. The insulating part 60 divides the multi-layered body 100 into a plurality of string units 200 in the Y direction. Each of the string units 200 has the cell array region and the staircase region.

As shown in FIG. 3, a plurality of bit lines BL are provided above the first multi-layered part 100a. The plurality of the bit lines BL are, for example, metal films extending in the Y direction. The plurality of the bit lines BL are separated from each other in the X direction. An upper end of a semiconductor body 20 of the columnar part CL1 to be described later is connected to the bit line BL via a contact Cb and a contact V1. A plurality of columnar parts CL1 are connected to one common bit line BL. The plurality of the columnar parts CL1 connected to the common bit line 131L includes the columnar parts CL1 each selected from each of the string units 200 separated in the Y direction by the insulating part 60.

As shown in FIG. 4, the first multi-layered part 100a includes a plurality of conductive layers 70 stacked on the substrate 10. The plurality of the conductive layers 70 are stacked one by one in a direction perpendicular to an upper surface of the substrate 10 (Z direction) with an insulating layer 72 interposed therebetween. The conductive layer 70 is, for example, a metal layer. The conductive layer 70 is, for example, a tungsten layer containing tungsten as a main component or a molybdenum layer containing molybdenum as a main component. Furthermore, the conductive layer 70 may be formed of a conductive material such as polysilicon doped with impurities. The insulating layer 72 is, for example, a silicon oxide layer containing silicon oxide as a main component.

In FIG. 3, the first multi-layered part 100a is drawn as a simple multi-layered structure of the conductive layer 70 and the insulating layer 72. Particularly, the first multi-layered part 100a employs a structure having a plurality of layers vertically stacked in the Z direction as shown in FIG. 4 to increase the number of stacks of the semiconductor storage device.

As shown in FIG. 4, the first multi-layered part 100a has a layered structure having two layers including a lower layer part 100aL and an upper layer part 100aU.

The lower layer part 100aL includes a lower multi-layered body 100c formed in a multi-layered structure of the conductive layer 70 and the insulating layer 72. A plurality of lower layer columnar parts LCL1 penetrating the lower multi-layered body 100c in the Z direction are provided in the lower multi-layered body 100c.

The upper layer part 100aU includes an upper multi-layered body 100d formed in a multi-layered structure of the conductive layer 70 and the insulating layer 72. A plurality of upper layer columnar parts UCL1 penetrating the upper multi-layered body 100d in the Z direction are provided in the upper multi-layered body 100d.

As described above, strictly speaking, the columnar part CL1 has a building-up structure of the lower layer columnar part LCL1 and the upper layer columnar part UCL1, and a joint portion CLJ is formed at the boundary portion between them. That is, each of the lower layer columnar part and the upper layer columnar part UCL1 is a part of the columnar part CL1.

As shown in FIG. 4, both the lower layer columnar part LCL1 and the upper layer columnar part UCL1 have a columnar shape such that, a diameter on a side closer to the substrate 10 is small, and the diameter gradually increases in a direction (Z direction) away from the substrate 10. Each of the lower layer columnar part LCL1 and the upper layer columnar part UCL1 has a large diameter part CLM having a maximum diameter slightly below an uppermost portion (on a side closer to the substrate 10) thereof. Each of the lower layer columnar part LCL1 and the upper layer columnar pail UCL1 has a columnar shape such that a diameter on a side above the large diameter part CLM gradually becomes smaller than that of the large diameter part CLM.

Furthermore, in the following description, regarding the columnar part CL1 having a building-up structure of the lower layer columnar part LCL1 and the upper layer columnar part UCL1, when the function and structure can be explained as one columnar part CL1, it will be simply referred to as the columnar part CL1 and will be used for explanation.

The substrate 10 is a semiconductor substrate such as, for example, a silicon substrate. An interconnection layer region 10A is provided on the substrate 10. The interconnection layer region 10A includes, for example, a semiconductor layer 10a, a source line 10b, and a semiconductor layer 10c stacked on the substrate 10. A lower end portion (second portion) CLE of the lower layer columnar part LCL1 is implanted in the semiconductor layer 10a, the source line 10b, and the semiconductor layer 10c. That is, the lower end portion CLE of the lower layer columnar part LCL1 is implanted in the interconnection layer region 10A. A detailed structure of the lower end portion CLE of the lower layer columnar part LCL1 will be described later.

The semiconductor layers 10a and 10c are formed of n-type silicon or the like having impurities added to a semiconductor such as silicon as a conductive material. The semiconductor layers 10a and 10c are formed of, for example, phosphorus-doped polysilicon. The lower end portion of the lower layer columnar part LCL1 is connected to the source line 10b with a part of a film removed as described later. The source line 10b is formed of a semiconductor layer or a conductive layer such as tungsten or tungsten silicide.

The insulating layer 72 is provided on an upper surface of the semiconductor layer 10c. The lowermost conductive layer 70 is provided on the insulating layer 72, and then the insulating layer 72 and the conductive layer 70 are alternately stacked. An insulating layer 42 is provided on the uppermost conductive layer 70, and an insulating layer 43 is provided on the insulating layer 42. The insulating layer 43 covers an upper end of the columnar part CL1.

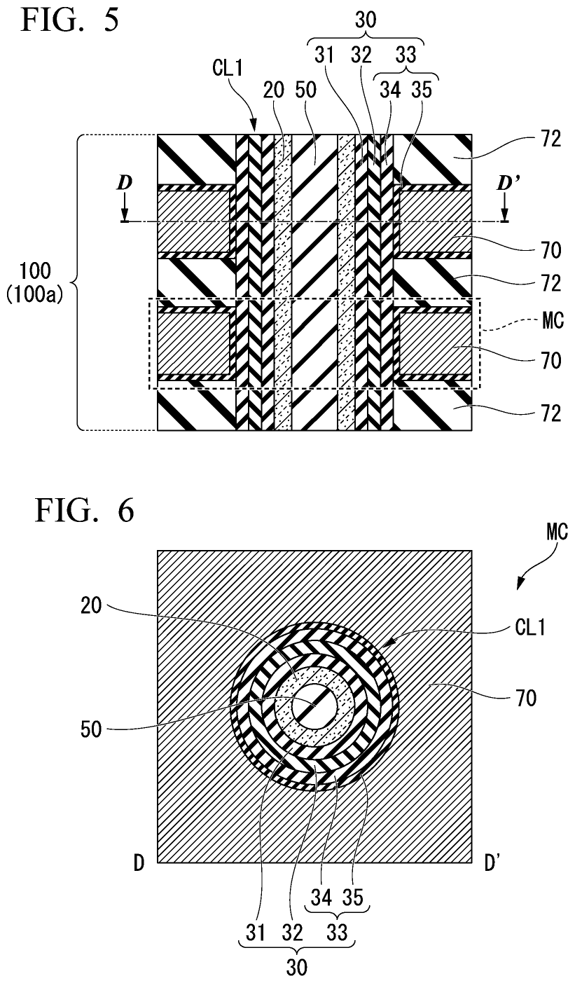

FIG. 5 is an enlarged cross-sectional view showing the columnar part CL1 and a circumferential portion of the columnar part CL1 in FIG. 4.

FIG. 6 is a cross-sectional view taken along line D-Y in FIG. 5A.

The columnar part CL1 includes a multi-layered film (memory him) 30, the semiconductor body 20, and a core part 50 that has insulating properties.

The semiconductor body 20 extends to be continuous in an annular shape in the first multi-layered part 100a in the stacking direction (Z direction). The multi-layered film 30 is provided between the conductive layer 70 and the insulating layer 72, and the semiconductor body 20, and surrounds the semiconductor body 20 from an outer circumferential side. The core part 50 is provided on an inner side of the annular semiconductor body 20. An upper end side of the semiconductor body 20 is connected to the bit line BL via the contact Cb and the contact V1 shown in FIG. 3.

The multi-layered film 30 includes a tunnel insulating film 31, a charge storage film (memory part) 32, and a block insulating film 33. The tunnel insulating film 31, the charge storage film 32, and the block insulating film 33 are provided between the semiconductor body 20 and the conductive layer 70 in that order from the semiconductor body 20 side. The charge storage film 32 is provided between the tunnel insulating film 31 and the block insulating film 33.

In a region in which the lower end portion CLE of the lower layer columnar part LCL1 is in contact with the source line 10b, a part of the tunnel insulating film 31, the charge storage film 32, and the block insulating film 33 is partially removed. Therefore, a connection part 24 is formed on a part of a side surface of the semiconductor body 20. The semiconductor body 20 is in direct contact with the source line 10b at the connection part 24 facing the source line 10b.

The semiconductor body 20, the multi-layered film 30, and the conductive layer 70 form a memory cell MC. The memory cell MC has a vertical transistor structure having the conductive layer 70 surrounding a circumference of the semiconductor body 20 via the multi-layered film 30.

In the memory cell MC having a vertical transistor structure, the semiconductor body 20 is, for example, a silicon channel body, and the conductive layer 70 functions as a control gate. The charge storage film 32 functions as a data storage layer that stores electric charge injected from the semiconductor body 20.

The semiconductor storage device of the embodiment is a non-volatile semiconductor storage device.

The memory cell MC is, for example, a charge trap type memory cell. The charge storage film 32 has a large number of trap sites that capture electric charge in a film having insulating properties. The charge storage film 32 includes, for example, a silicon nitride film. Alternatively, the charge storage film 32 may be a conductive floating gate having a circumference surrounded by an insulator.

The tunnel insulating film 31 serves as a potential barrier when electric charge is injected from the semiconductor body 20 into the charge storage film 32 or when electric charge stored in the charge storage film 32 is released to the semiconductor body 20. The tunnel insulating film 31 includes, for example, a silicon oxide film.

The block insulating film 33 inhibits the electric charge stored in the charge storage film 32 being released to the conductive layer 70. Also, the block insulating film 33 inhibits back tunneling of the electric charge from the conductive layer 70 to the columnar part CL1.

The block insulating film 33 includes, for example, a first block film 34 and a second block film 35. The first block film 34 is, for example, a silicon oxide film. The second block film 35 is a metal oxide film having a higher dielectric constant than the silicon oxide film. As the metal oxide film, for example, an aluminum oxide film, a zirconium oxide film, and a hafnium oxide film can be exemplified.

The first block film 34 is provided between the charge storage film 32 and the second block film 35. The second block film 35 is provided between the first block film 34 and the conductive layer 70.

The second block film 35 is also provided between the conductive layer 70 and the insulating layer 72. The second block film 35 is continuously formed along an upper surface, a lower surface, and a side surface on the multi-layered film 30 side of the conductive layer 70. The second block films 35 adjacent to each other are not continuous in the stacking direction of the first multi-layered part 100a. The second block films 35 are disconnected from each other.

Also, the second block film 35 may be formed to be continuous in the stacking direction of the first multi-layered part 100a without the second block film 35 being formed between the conductive layer 70 and the insulating layer 72. Alternatively, the block insulating film 33 may be a single-layer film that is continuous in the stacking direction of the first multi-layered part 100a.

Also, a metal nitride film may be formed between the second block film 35 and the conductive layer 70, or between the insulating layer 72 and the conductive layer 70. This metal nitride film is, for example, a titanium nitride film, and can function as a barrier metal, an adhesion layer, and a seed metal of the conductive layer 70.

As shown in FIG. 3, a drain side selection transistor STD is provided in an upper layer portion (upper end portion of the columnar part CL1) of the first multi-layered part 100a. A source side selection transistor STS is provided in the lower layer part 100aL of the first multi-layered part 100a. At least the uppermost conductive layer 70 functions as a control gate for the drain side selection transistor STD. At least the lowermost conductive layer 70 functions as a control gate for the source side selection transistor STS.

A plurality of memory cells MC are provided between the drain side selection transistor STD and the source side selection transistor STS. The plurality of the memory cells MC, the drain side selection transistor STD, and the source side selection transistor STS are connected in series through the semiconductor body 20 of the columnar part CL1 to form one memory string. The memory string is disposed, for example, in a staggered manner in a plane direction parallel to an XY plane. The plurality of the memory cells MC are three-dimensionally provided in the X direction, the Y direction, and the Z direction.

### <Structure of Lower End Portion of Lower Layer Columnar Part>

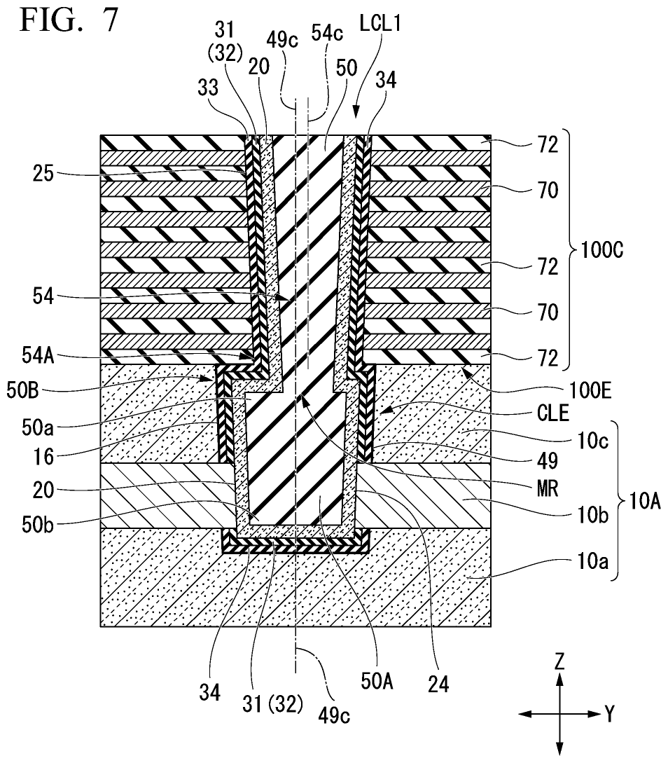

FIG. 7 shows an enlarged cross section of the lower end portion (second portion) CLE of the lower layer columnar part LCL1.

The lower end portion CL1 of the lower layer columnar part LCL1 is implanted in the interconnection layer region 10A as shown in FIG. 7. More specifically, a core end portion 50A is formed at a lower end portion of the core part 50 of the lower layer columnar part LCL1.

The lower multi-layered body 100c includes an end portion 100E facing the interconnection layer region 10A. The lower end portion CLE of the lower layer columnar part LCL1 penetrates the end portion 100E in the Z direction and is implanted in the interconnection layer region 10A. A portion of the lower layer columnar part LCL1 close to a lower end thereof passing through the end portion 100h of the lower multi-layered body 10c is referred to as a first portion 54.

An outer diameter of the core end portion 50A is larger than an outer diameter of the first portion 54 of the lower layer columnar part LCL1.

An upper portion 50a of the core end portion 50A is positioned inside the semiconductor layer 10c. The core end portion 50A extends to penetrate the source line 10b such that a lower portion 50b of the core end portion 50A reaches a portion between the source line 10b and the semiconductor layer 10a. The semiconductor body 20 is formed to surround the core end portion 50A from a circumferential surface to a bottom surface thereof.

In the core end portion 50A, the tunnel insulating film 31, the charge storage film 32, and the first block film 34 are removed in a portion implanted in the source line 10b to form the connection part 24 of the semiconductor body 20. In this connection part 24, the semiconductor body 20 is in direct contact with the source line 10b. The tunnel insulating film 31, the charge storage film 32, and the first block film 34 are formed around a portion surrounded by the semiconductor layer 10a in a lower end portion of the core end portion 50A.

As shown in FIGS. 4 and 7, a large diameter part 49 is formed at the lower end portion CLE of the lower layer columnar part LCL1. The large diameter part 49 is formed by surrounding the above-described core end portion 50A with the tunnel insulating film 31, the charge storage film 32, and the first block film 34. A position of a center 49c of the large diameter part 49 is displaced from a position of a center 54c of the first portion 54 of the lower layer columnar part LCL1 in the Y direction. A positional displacement part MR is formed at a connecting portion between a lower end of the first portion 54 and an upper end of the large diameter part 49.

In the embodiment, as shown in FIG. 7, the position of the center 54c of the first portion 54 of the lower layer columnar part LCL1 is displaced to the right side from the position of the center 49c of the large diameter part 49. An amount of the positional displacement is, for example, smaller than a radius of the lower end of the first portion 54 of the lower layer columnar part LCL1.

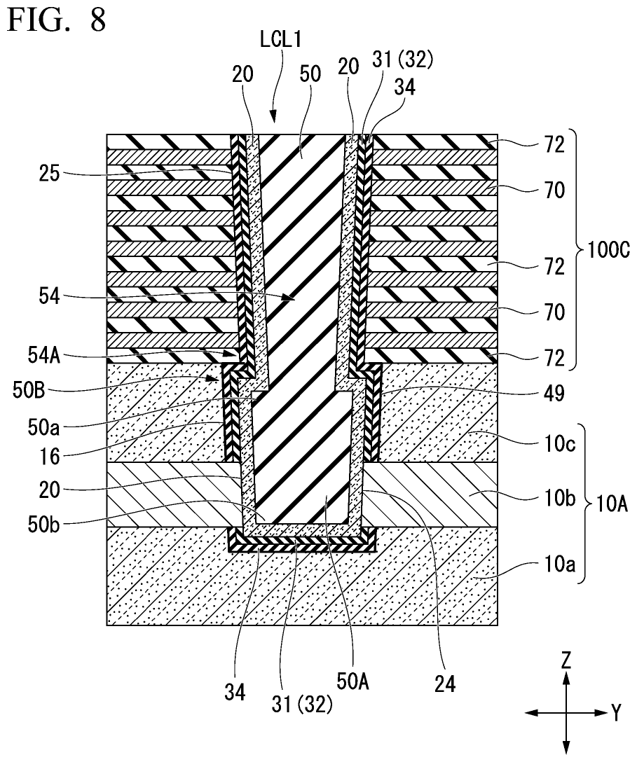

FIG. 8 shows a structure of a case in which the position of the center 49c of the large diameter part 49 and the position of the center 54c of the first portion 54 of the lower layer columnar part LCL1 coincide with each other. In the structure of the lower layer columnar part LCL1 shown in FIG. 8, other structures are the same as the structure of the lower layer columnar part LCL1 shown in FIG. 7.

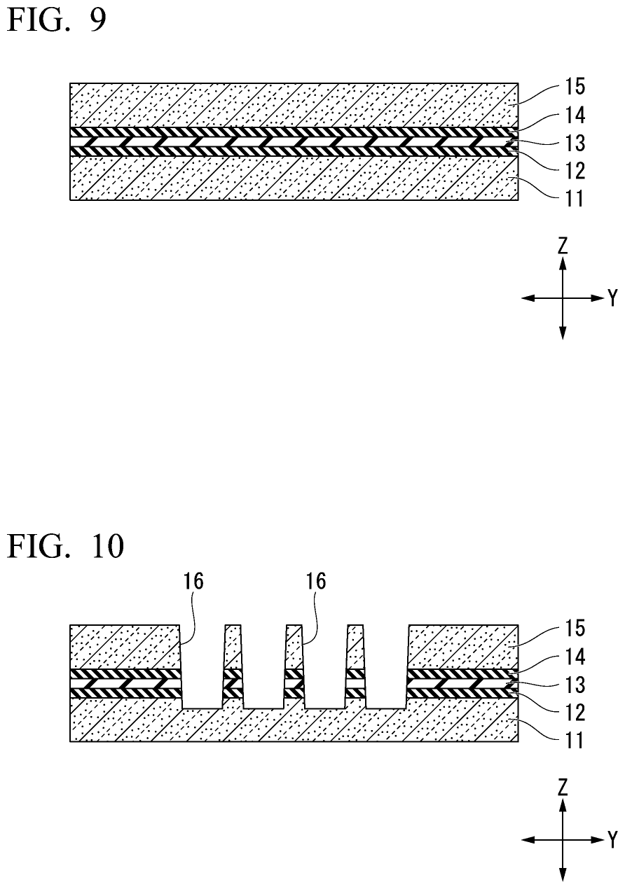

As will be described in detail in a manufacturing method to be described later with reference to FIGS. 9 to 23, in the structure of the embodiment, a bottom memory hole 16 is formed in advance in a region that will become the interconnection layer region 10A, and then a lower multi-layered body 23 is formed on the interconnection layer region 10A. Thereafter, a lower memory hole 25 is formed in the lower multi-layered body 23 by ion etching to allow the bottom memory hole 16 and the lower memory hole 25 to communicate with each other. Therefore, a position of a center of the lower memory hole 25 and a position of a center of the bottom memory hole 16 may be displaced in the Y direction as shown in FIG. 7 due to a positioning accuracy of ion etching or the like.

However, when a plurality of lower layer columnar parts LCL1 are manufactured, the position of the center 49c of the large diameter part 49 and the position of the center 54c of the First portion 54 of the lower layer columnar part LCL1 may also coincide with each other as shown in FIG. 8. That is, when the plurality of the lower layer columnar parts LCL1 are manufactured, some of the lower layer columnar parts LCL1 may also not have a center position displacement as shown in FIG. 8. Therefore, in the structure of the embodiment, the lower layer columnar part LCL1 shown in FIG. 8, which does not have a center position displacement, may be included in a part of the plurality of the formed lower layer columnar parts LCL1.

When the lower layer columnar part LCL1 having the large diameter part 49 is employed as shown in FIGS. 4, 7, and 8, even when the position of the center of the lower memory hole 25 and the position of the center of the bottom memory hole 16 are displaced, the lower end portion CLE of the lower layer columnar part LCL1 can be formed without any trouble.

As will be described in the manufacturing method to be described later, when the lower layer columnar part LCL1 is formed, the bottom memory hole 16 which is a base of the large diameter part 49 is formed, and then the lower memory hole 25 which is a base of the first portion 54 of the lower layer columnar part LCL1 is formed in a subsequent deposition process.

Furthermore, when the bottom memory hole 16 is formed in the interconnection layer region 10A in advance and then the lower multi-layered body 100c is formed on the interconnection layer region 10A, an effect of not unnecessarily expanding an inner diameter of the lower memory hole 25 formed in the lower multi-layered body 100c can be obtained as will be described later. This effect will be described in association with the manufacturing method to be described later.

Next, a configuration of the insulating part (separation part) 60 will be described.

As shown in FIGS. 2 and 4, the insulating part 60 includes an insulating film 63. Furthermore, the insulating film 63 is omitted in FIG. 3.

The insulating film 63 extends in the X direction and the Z direction. For example, as shown in FIG. 4, the insulating film 63 is provided so that it is adjacent to the first multi-layered part 100a, extends in the Z direction, and reaches an upper side of the semiconductor layer 10a.

As described above, a lower end portion of the semiconductor body 20 in the columnar part CL1 shown in FIG. 4 is in contact with the source line 10b.

Next, an outline of the staircase part 2 will be described.

The staircase part 2 is also separated into a part of the string unit 200 by the insulating part 60. A columnar body CL3 and a contact part CT are provided in the staircase part 2, and thereby a terrace part 70a is provided.

### <Manufacturing Method of First Embodiment>

Next, a manufacturing method of the semiconductor storage device according to the first embodiment will be described with reference to FIGS. 9 to 23. The cross sections of FIGS. 9 to 23 correspond to the cross section of FIG. 4.

A semiconductor layer 11, a protective layer 12, a sacrificial layer 13, a protective layer 14, and a semiconductor layer 15 are stacked on the semiconductor substrate 10. The semiconductor substrate 10 is omitted in FIG. 9. The semiconductor layer 11 is, for example, a phosphorus-doped polycrystalline silicon layer. The protective layers 12 and 14 are, for example, silicon oxide films. The sacrificial layer 13 is, for example, an undoped polycrystalline silicon layer. The semiconductor layer 15 is, for example, an undoped or phosphorus-doped polycrystalline silicon layer.

As shown in FIG. 10, a plurality of bottom memory holes 16 are formed. In the embodiment, since the plurality of the columnar parts CL1 are formed in a staggered manner as shown in FIG. 2, the bottom memory holes 16 are formed corresponding to positions at which the columnar parts CL1 are formed. The bottom memory holes 16 can be formed by an etching method such as reactive ion etching. Each of the bottom memory holes 16 has a depth such that the bottom memory hole 16 penetrates the semiconductor layer 15, the protective layer 14, the sacrificial layer 13, and the protective layer 12, and the bottom memory hole 16 reaches the semiconductor layer 11 at a predetermined depth.

An inner diameter of an upper end portion of the bottom memory hole 16 is formed to be larger than an inner diameter of a lower end portion of the lower memory hole 25 which is later formed on the bottom memory hole 16.

As shown in FIG. 11, a stopper material layer 17 is formed to fill the bottom memory hole 16 and cover an upper surface of the semiconductor layer 15. A carbon film or the like can be applied to the stopper material layer 17. A material forming the stopper material layer 17 is preferably a material having a high etching selectivity with respect to the lower multi-layered body 23 formed of a multi-layered body of an insulating layer 19 and a sacrificial layer 21 to be formed later.

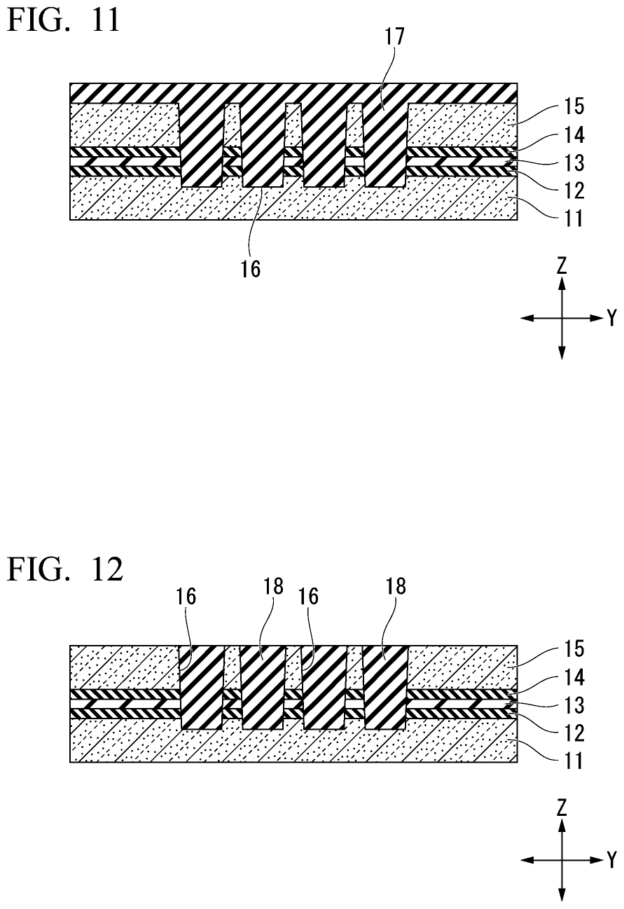

As shown in FIG. 12, etching back is performed to remove the stopper material layer 17 stacked on the semiconductor layer 15, leaving only the stopper material layer 17 that has filled the bottom memory hole 16. Therefore, a configuration having the bottom memory hole 16 filled with the stopper material 18 is obtained.

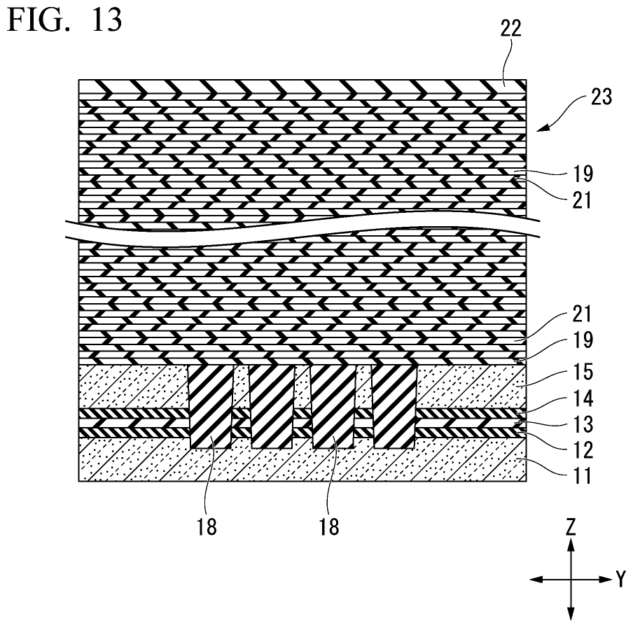

As shown in FIG. 13, the lower multi-layered body 23 is formed by alternately stacking the insulating layer 19 and the sacrificial layer 21 and by forming the insulating layer 22 on the uppermost sacrificial layer 21. The insulating layers 19 and 22 are, for example, silicon oxide films, and the sacrificial layer 21 is, for example, a silicon nitride film.

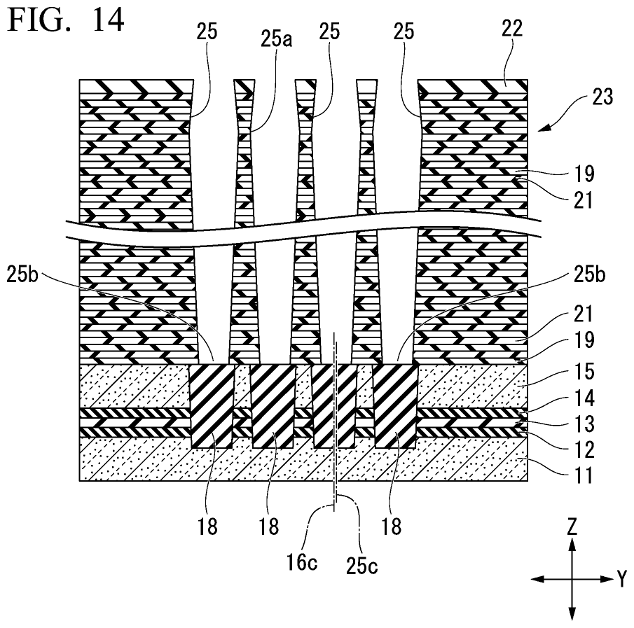

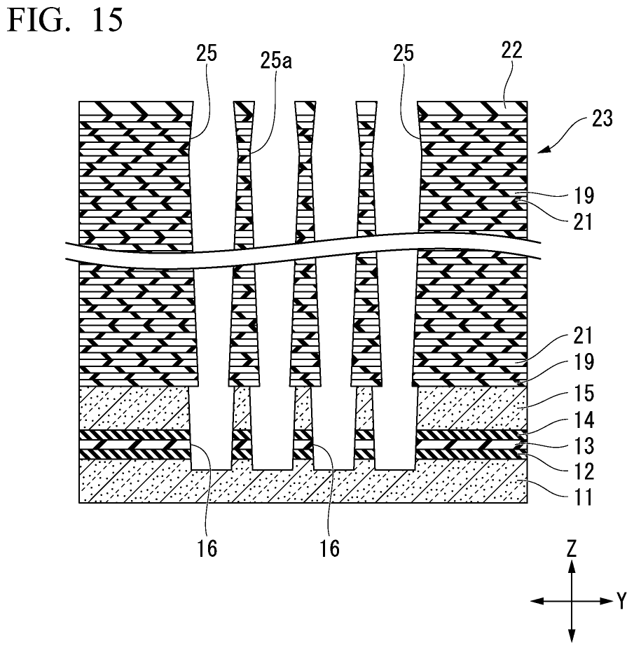

As shown in FIG. 14, the lower memory hole 25 extending from a top part to a bottom part of the lower multi-layered body 23 is formed with respect to the lower multi-layered body 23 to correspond to the formation position of the bottom memory hole 16 described above. The lower memory hole 25 can be formed by an etching method such as reactive ion etching.

The lower memory hole 25 has a shape such that an inner diameter gradually decreases toward a lower end portion side thereof. An enlarged inner diameter part 25a is formed at a position slightly lower than an upper end of the lower memory hole 25. A lower end portion 25b of the lower memory hole 25 reaches an upper surface of the stopper material 18.

Here, due to an error in positioning accuracy when the lower memory hole 25 is formed, a position of a center 25c of the lower memory hole 25 and a position of a center 16c of the bottom memory hole 16 may be displaced in the Y direction (left-right direction) of FIG. 14.

However, even when a center position displacement is assumed to occur, since a diameter of the upper end portion of the stopper material 18 is slightly larger than an inner diameter of the lower end portion 25b of the lower memory hole 25, a likelihood that the lower end portion 25b of the lower memory hole 25 will be displaced from an upper surface of the stopper material 18 in the Y direction is reduced.

As shown in FIG. 15, the stopper material 18 is removed via the lower memory hole 25 by a method such as ashing to allow the lower memory hole 25 and the bottom memory hole 16 to communicate with each other. In this method, only the stopper material 18 can be removed, and the inner diameter of the lower memory hole 25 is not unnecessarily expanded.

On the other hand, as an assumption, a manufacturing method is conceivable which forms the lower multi-layered body 23 on the semiconductor layer 15 in FIG. 9 and forms a lower memory hole reaching the semiconductor layer 11 from the upper surface of the lower multi-layered body 23. FIG. 9 shows a state in which the bottom memory hole 16 is not formed.

This manufacturing method is a method of creating a deep lower memory hole reaching the semiconductor layer 11 from the upper surface of the lower multi-layered body 23 only by etching without providing the stopper material 18.

However, when this method is employed, the enlarged inner diameter part 25a of the lower memory hole 25 may become larger than expected due to variations in etching conditions or the like.

In this case, a likelihood that a distance between the adjacent lower memory holes 25 and 25 will become smaller than expected, and this will cause a trouble in forming the columnar part performed in a subsequent process is conceivable. Also, there is a likelihood that this phenomenon will cause a trouble in further increasing a density of memory cells and reducing the chip size. That is, if the distance between the lower memory holes 25 is reduced, there is a possibility that the adjacent lower memory holes 25 will come into contact with each other. This will cause a trouble in further increasing a density of memory cells and reducing the chip size.

On the other hand, when the method of removing the stopper material 18 after the lower memory hole 25 is formed using the stopper material 18 described above is employed, since the problem that the enlarged inner diameter part 25a becomes larger than expected does not easily occur. Therefore, it is possible to provide a structure that can withstand even higher density of memory cells and reduction in chip size.

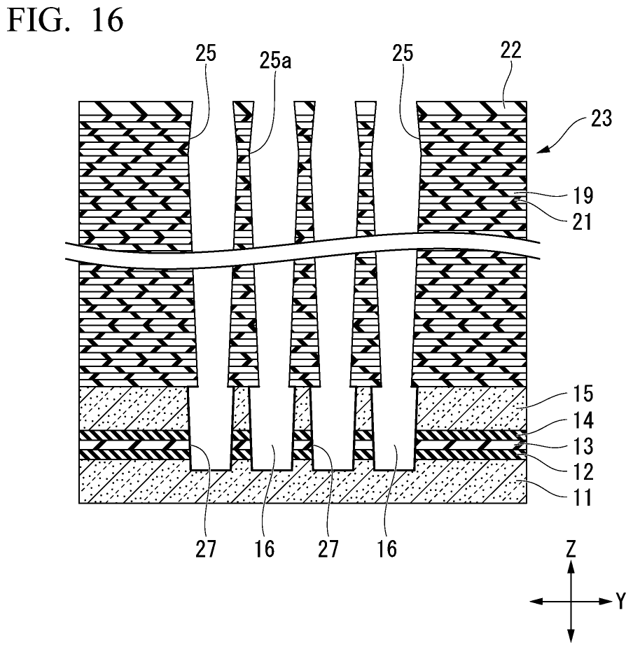

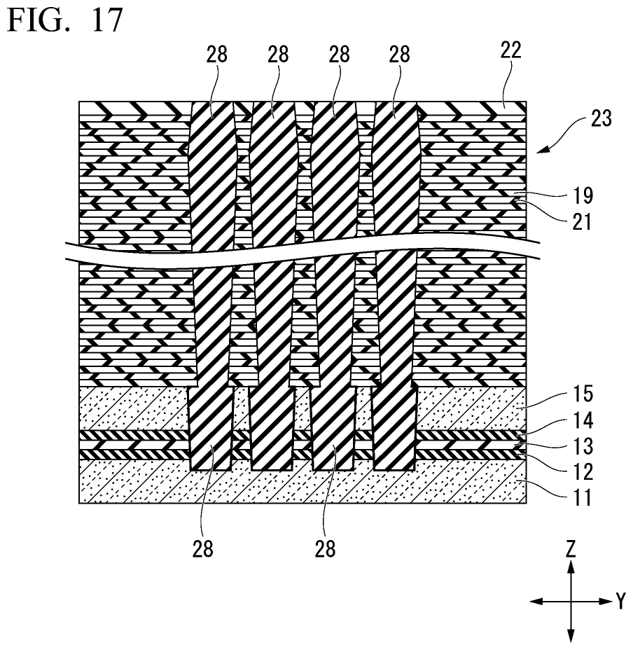

As shown in FIG. 16, the semiconductor layers 11 and 15 exposed on an inner surface of the bottom memory hole 16 are oxidized to form a silicon oxide layer 27.

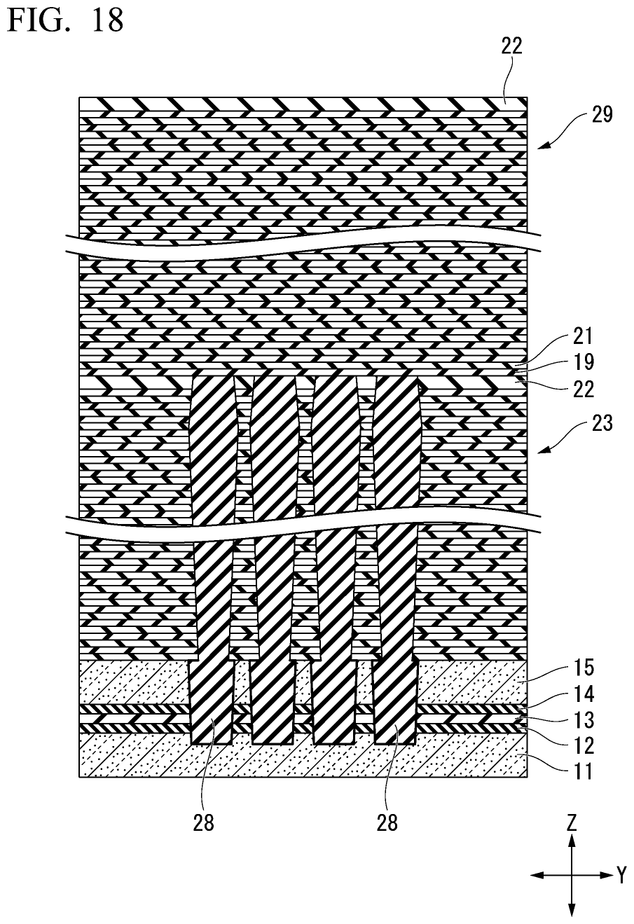

As shown in FIG. 17, a filler 28 is formed to fill the bottom memory hole 16 and the lower memory hole 25. A carbon film or the like can be applied to the filler 28.

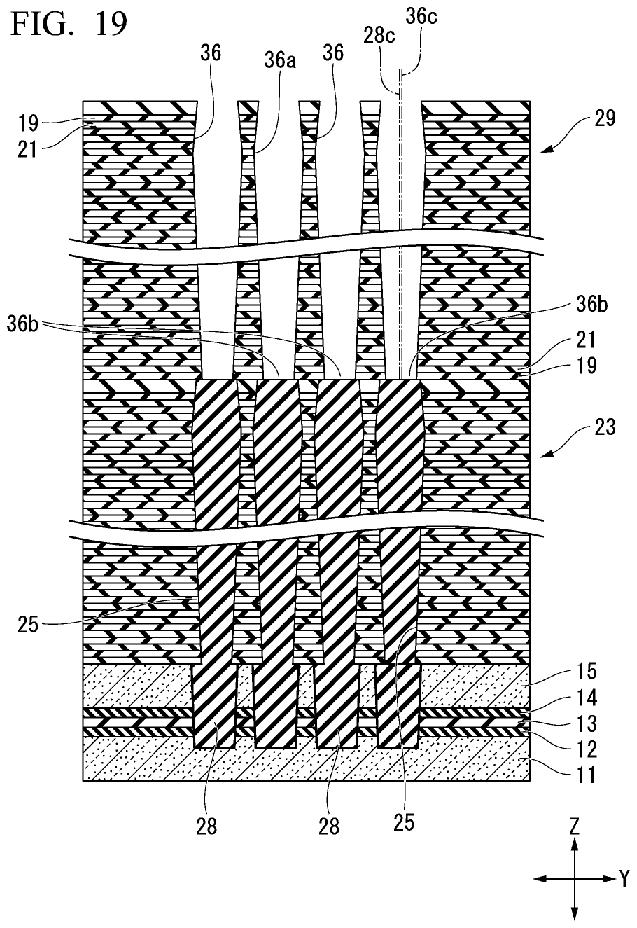

As shown in FIG. 18, an upper multi-layered body 29 is formed on the lower multi-layered body 23. A structure of the upper multi-layered body 29 is the same as that of the lower multi-layered body 23, the insulating layer 19 and the sacrificial layer 21 are alternately stacked, and the insulating layer 22 is formed on the uppermost sacrificial layer 21.

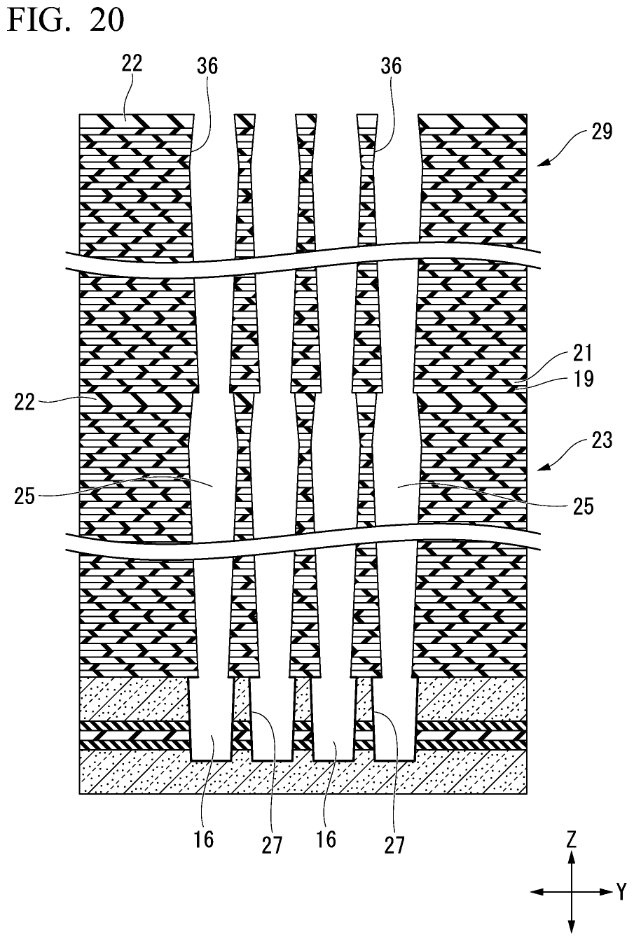

As shown in FIG. 19, an upper memory hole 36 extending from a top part to a bottom part of the upper multi-layered body 29 is formed with respect to the upper multi-layered body 29 to correspond to the formation position of the lower memory hole 25 described above. The upper memory hole 36 can be formed by an etching method such as reactive ion etching.

The upper memory hole 36 has a shape such that an inner diameter gradually decreases toward a lower end portion side thereof. An enlarged inner diameter part 36a is formed at a position slightly lower than an upper end of the upper memory hole 36. A lower end portion 36b of the upper memory hole 36 reaches an upper end portion of the filler 28.

Here, due to an error in positioning accuracy when the upper memory hole 36 is formed, a position of a center 36c of the upper memory hole 36 and a position of a center 28c of the columnar filler 28 may be displaced in the Y direction (left-right direction) of FIG. 19.

Even when the positional displacement is assumed to occur, since a diameter of the upper surface of the stopper material 18 is slightly larger than an inner diameter of the lower end portion 36b of the upper memory hole 36, the lower end portion 25b of the lower memory hole 25 is not displaced from the upper surface of the stopper material 18 in the Y direction.

The upper memory hole 36 is at a position at which the upper layer columnar part UCL1 is provided. The lower memory hole 25 is at a position at which the lower layer columnar part LCL1 is provided. Therefore, in order to obtain the columnar part CL1 having the upper layer columnar part UCL1 and the lower layer columnar part LCL1 which are reliably joined, it is important to have a configuration having the upper memory hole 36 and the lower memory hole 25 which can reliably communicate with each other.

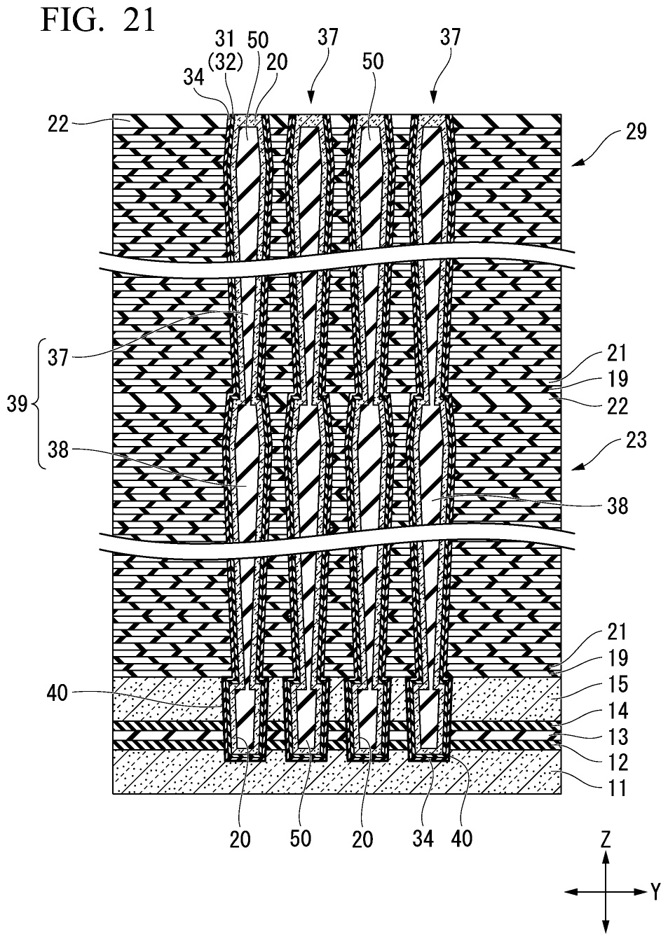

As shown in FIG. 20, the filler 28 of the lower memory hole 25 and the stopper material 18 of the bottom memory hole 16 are removed via the upper memory hole 36 by a method such as ashing. Therefore, the upper memory hole 36, the lower memory hole 25, and the bottom memory hole 16 communicate with each other. In the above-described process of removing the carbon film by a method such as ashing, only the filler 28 and the stopper material 18 can be removed.

Therefore, the upper memory hole 36 and the lower memory hole 25 having target inner diameters can be obtained without unnecessarily expanding the inner diameters of the upper memory hole 36 and the lower memory hole 25.

As shown in FIG. 21, depositions serving as a base for forming the columnar part LCL1 are performed in the bottom memory hole 16, the lower memory hole 25, and the upper memory hole 36. Depositions of the first block film 34, the charge storage film 32, the tunnel insulating film 31, the semiconductor body 20, and the core part 50 are performed. Therefore, an upper layer base columnar part 37 as a base for the upper layer columnar part UCL1 is formed, a lower layer base columnar part 38 as a base for the lower layer columnar part LCL1 is formed. Both the upper layer base columnar part 37 and the lower layer base columnar part 38 can be collectively referred to as a base columnar part 39.

A large diameter part 40 formed by the first block film 34, the charge storage film 32, the tunnel insulating film 31, the semiconductor body 20, and the core part 50 is formed at a lower end portion of the lower layer base columnar part 38. The large diameter part 40 is formed by these films deposited in the bottom memory hole 16. Of the first block film 34, the charge storage film 32, the tunnel insulating film 31, the semiconductor body 20, and the core part 50, the core part 50 is the thickest. Therefore, the core part 50 occupies most of the large diameter part 40, and the first block film 34, the charge storage film 32, the tunnel insulating film 31, and the semiconductor body 20 are formed to surround the core part 50 of the large diameter part 40.

In FIG. 21, for the sake of simplification of the drawing, the charge storage film 32 and the tunnel insulating film 31 are simplified and drawn as one layer film.

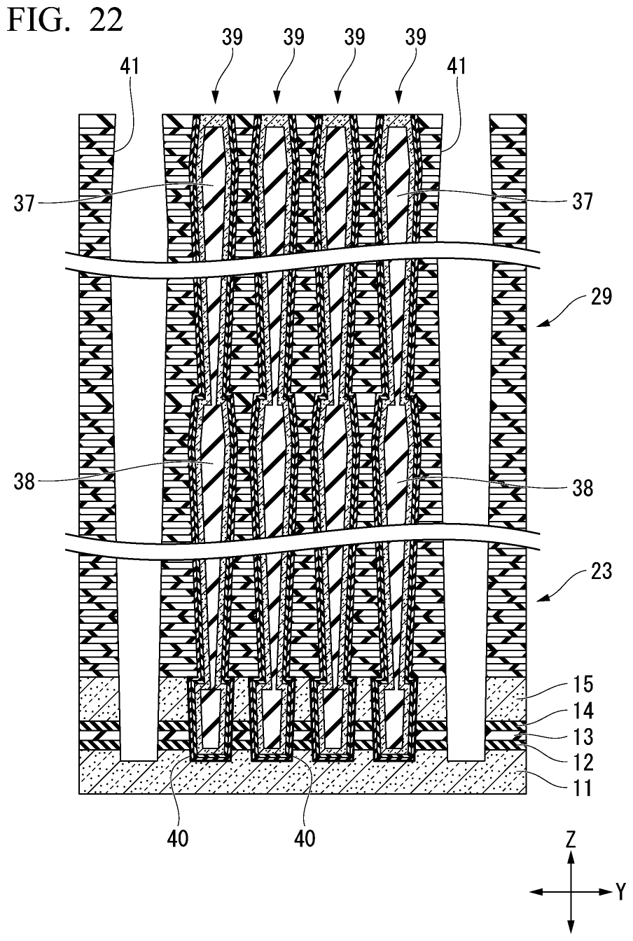

As shown in FIG. 22, slits 41 are formed, for example, on both sides of four base columnar parts 39 in the Y direction (left-right direction). The slits 41 can be formed by an etching method such as reactive ion etching. Hach of the slits 41 is formed to penetrate the upper multi-layered body 29 and the lower multi-layered body 23 in the Z direction and reaches the semiconductor layer 11. The slit 41 has a depth that penetrates the semiconductor layer 15, the protective layer 14, the sacrificial layer 13, and the protective layer 12, and reaches the semiconductor layer 11 at a predetermined depth.

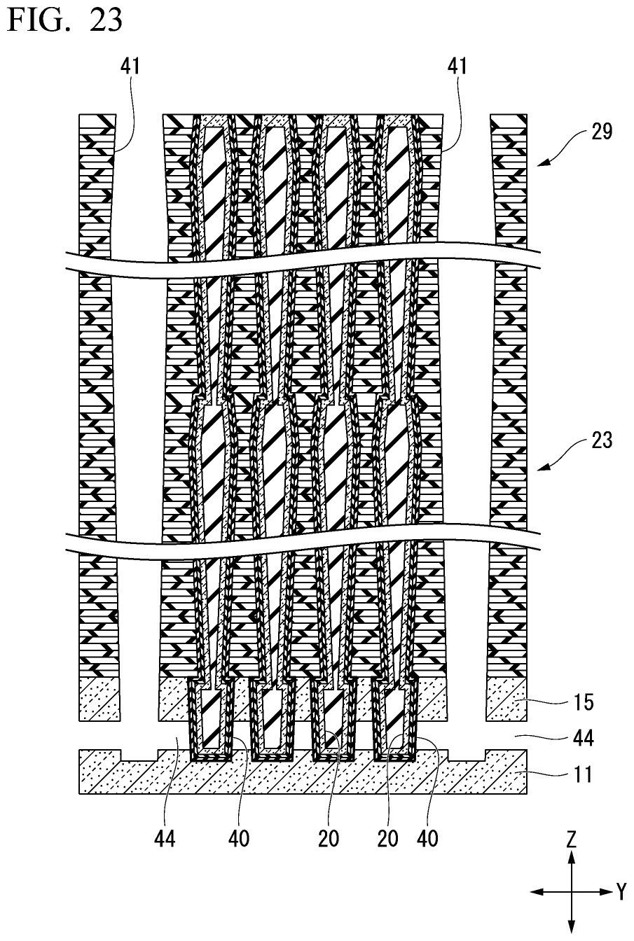

As shown in FIG. 23, etching processing using an etchant is performed through the slit 41 to remove the protective layer 14, the sacrificial layer 13, and the protective layer 12, and a hollow part 44 is formed.

From the state shown in FIG. 23, a liner film (not shown) is formed on an inner surface of the slit 41, and etching is performed with respect to the large diameter part 40 formed at the lower end portion of the lower layer base columnar part 38 exposed to the hollow part 44. Due to this etching, the first block film 34, the charge storage film 32, and the tunnel insulating film 31 on an outer circumferential side of the large diameter part 40 are removed. Due to this etching, the semiconductor body 20 can be exposed to the hollow part 44.

Thereafter, when a semiconductor layer is deposited to fill the hollow part 44, since the source line 10b shown in FIG. 4 can be formed, the interconnection layer region 10A including the semiconductor layer 10a, the source line 10b, and the semiconductor layer 10c can be formed.

After the interconnection layer region 10A is formed, the liner film is removed, and etching is performed through the slit 41 to remove the sacrificial layer 21 stacked on the lower multi-layered body 23 and the upper multi-layered body 29. The sacrificial layer 21 can be removed by an etchant or an etching gas supplied through the slit 41. The hollow can be formed at a portion at which the sacrificial layer 21 is formed.

When the second block film 35 and the conductive layer 70 are formed in the hollow, a structure equivalent to the structure shown in FIGS. 4 to 6 can be manufactured.

Furthermore, the process from removing the sacrificial layer through the slit 41 to forming the conductive layer is known in this type of three-dimensional memory, and for details, the process described in Japanese Unexamined Patent Application, First Publication No. 2018-142654 or the like can be referred to.

In the configuration of the embodiment configured as described above, the bottom memory hole 16 filled with the stopper material 18 shown in FIG. 12 is formed, the lower multi-layered body 23 shown in FIG. 13 is formed, and then the lower memory hole 25 shown in FIG. 14 is formed. Therefore, the position of the center 16c of the bottom memory hole 16 and the position of the center 25c of the lower memory hole 25 may be displaced in the Y direction as shown in FIG. 14.

However, a Y-direction length (inner diameter) at the upper portion of the bottom memory hole 16 is larger than a Y-direction length (inner diameter) of the lower end portion 25b of the lower memory hole 25.

Therefore, even if the center position displacement occurs slightly, the lower end portion 25b of the lower memory hole 25 can be reliably reached to the upper surface of the stopper material 18. That is, the lower end portion of the lower layer columnar part LCL1 can be reliably connected to the upper surface side of the large diameter part 49 that is formed in the bottom memory hole 16 in a subsequent process. Here, the lower end portion of the lower layer columnar part LCL1 is formed in the lower memory hole 25 in a subsequent process.

Also, even if a process cycle is performed which provides the stopper material 18 as shown in FIGS. 10 to 14 and thereafter removes the stopper material 18 by ashing or the like, the lower memory hole 25 having a target inner diameter can be formed without unnecessarily expanding the inner diameter of the lower memory hole 25.

Therefore, inner diameters of the adjacent lower memory holes 25 can be prevented from expanding. Therefore, it is possible to provide a semiconductor storage device that can support a high-density disposition of the lower memory hole 25, support an increase in density of the memory cell MC, and reduce the chip size. Since the fact that the lower memory hole 25 can be disposed at a high density is equivalent to a high-density disposition of the columnar part CL1, this results in an increase in density of the memory cell MC and reduction in chip size.

### <Second Manufacturing Method and Second Embodiment>

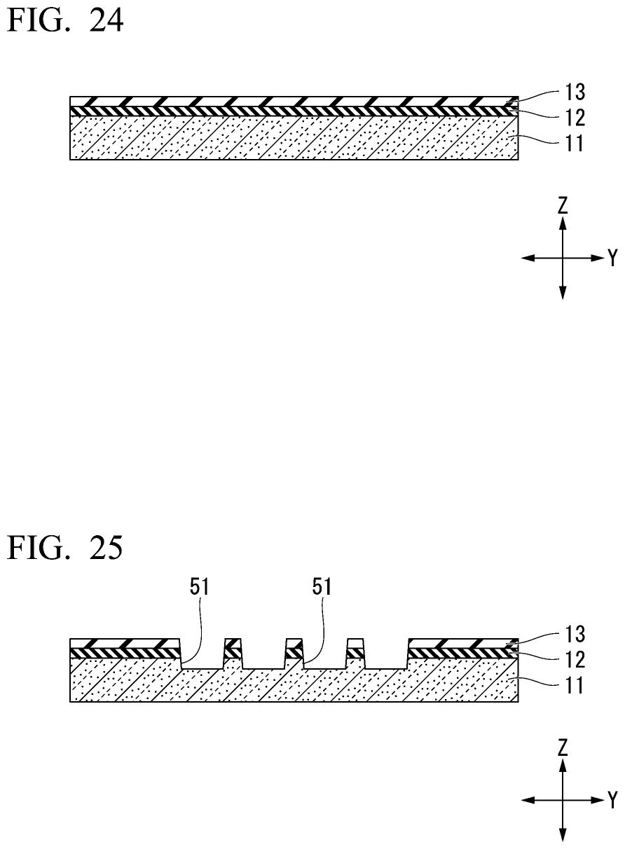

A second manufacturing method and a second embodiment will be described with reference to FIGS. 24 to 40.

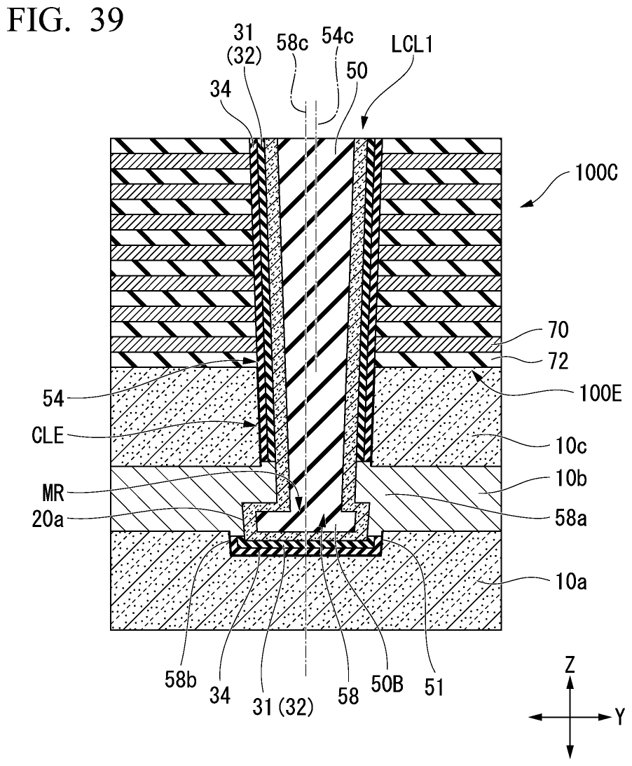

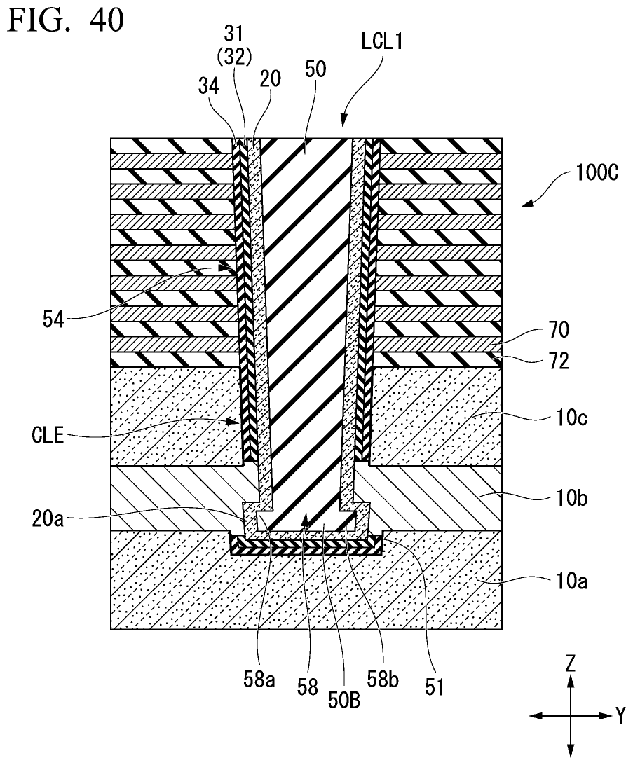

The cross sections of FIGS. 24 to 40 correspond to the cross section of FIG. 4. When the method described below with reference to FIGS. 24 to 38 is performed, the structure according to the second embodiment shown in FIGS. 39 and 40 can be manufactured.

FIG. 24 shows a state in which a semiconductor layer 11, a protective layer 12, and a sacrificial layer 13 are stacked on a semiconductor substrate 10 for which description is omitted.

As shown in FIG. 25, a plurality of bottom memory holes 51 are formed. In the embodiment, since a plurality of columnar parts CL1 are formed in a staggered manner as shown in FIG. 2, the bottom memory holes 51 are formed corresponding to positions at which the columnar parts CL1 are formed. The bottom memory holes 51 can be formed by an etching method such as reactive ion etching. Each of the bottom memory holes 51 has a depth such that the bottom memory hole 51 penetrates the sacrificial layer 13 and the protective layer 12, and the bottom memory hole 51 reaches the semiconductor layer 11 at a predetermined depth.

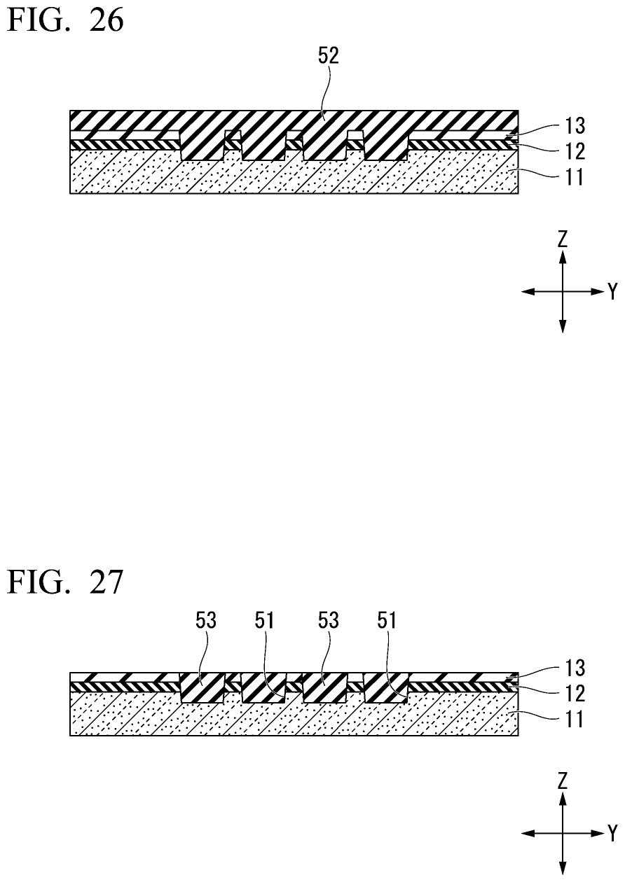

As shown in FIG. 26, a stopper material layer 52 is deposited to fill the bottom memory hole 51 and cover an upper surface of the sacrificial layer 13. A carbon film or the like can be applied to the stopper material layer 52. A material forming the stopper material layer 52 is preferably a material having a high etching selectivity with respect to a lower multi-layered body 23 formed of a multi-layered body of an insulating layer 19 and a sacrificial layer 21 to be formed later.

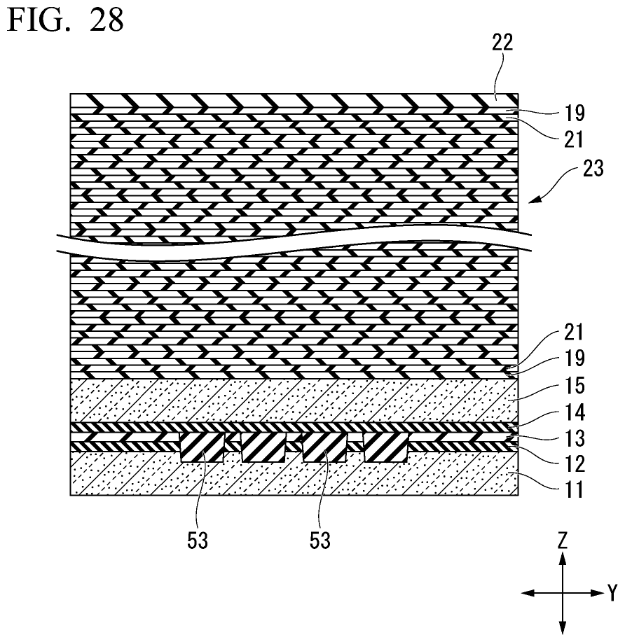

As shown in FIG. 27, etching back is performed to remove the stopper material layer 52 stacked on the sacrificial layer 13, leaving only a stopper material 53 that fills the bottom memory hole 51. Therefore, a configuration having the bottom memory hole 51 filled with the stopper material 53 is obtained.

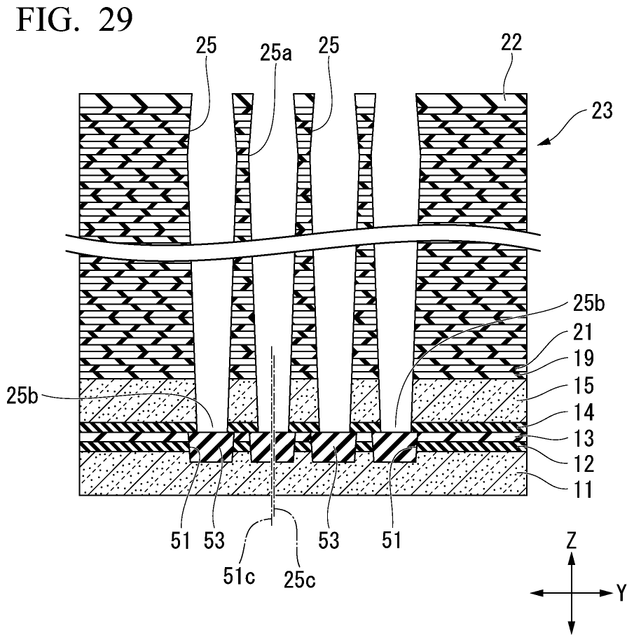

As shown in FIG. 28, a protective layer 14 and a semiconductor layer 15 are formed on the sacrificial layer 13 and the stopper material 53. The lower multi-layered body 23 is formed by alternately stacking the insulating layer 19 and the sacrificial layer 21 on the semiconductor layer 15 and by forming an insulating layer 22 on the uppermost sacrificial layer 21.

As shown in FIG. 29, a lower memory hole 25 extending from a top part to a bottom part of the lower multi-layered body 23 is formed with respect to the lower multi-layered body 23 to correspond to the formation position of the bottom memory hole 51 described above. The lower memory hole 25 can be formed by an etching method such as reactive ion etching.

The lower memory hole 25 has a shape such that an inner diameter gradually decreases toward a lower end portion side thereof. An enlarged inner diameter part 25a is formed at a position slightly lower than an upper end of the lower memory hole 25. A lower end portion 25b of the lower memory hole 25 reaches the stopper material 53.

Here, due to an error in positioning accuracy when the lower memory hole 25 is formed, a position of a center 25c of the lower memory hole 25 and a position of a center 51c of the bottom memory hole 51 may be displaced in the Y direction (left-right direction) of FIG. 29.

However, since a Y-direction length (diameter) of an upper portion of the bottom memory hole 51 is larger than a Y-direction length (inner diameter) of the lower end portion 25b of the lower memory hole 25, the positional displacement described above can be absorbed. Therefore, the lower end portion 25b of the lower memory hole 25 can reliably reach an upper surface of the stopper material 53.

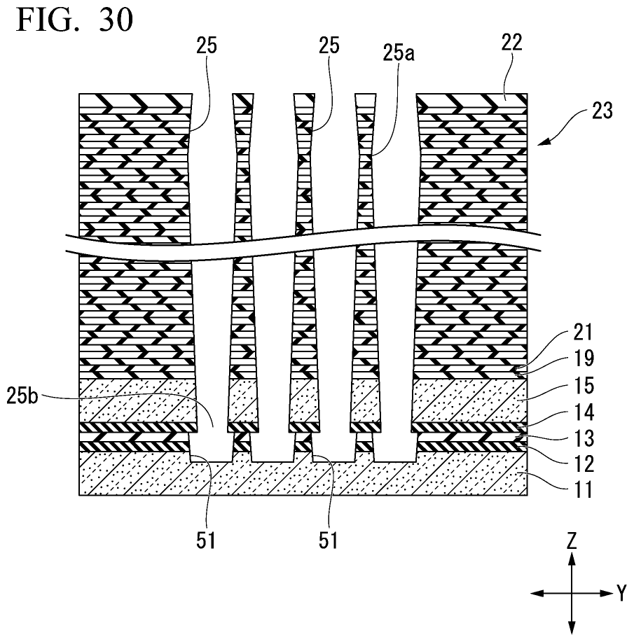

As shown in FIG. 30, the stopper material 53 is removed via the lower memory hole 25 by a method such as ashing to allow the lower memory hole 25 and the bottom memory hole 51 to communicate with each other. In this method, only the stopper material 53 can be removed, and the inner diameter of the lower memory hole 25 is not unnecessarily expanded.

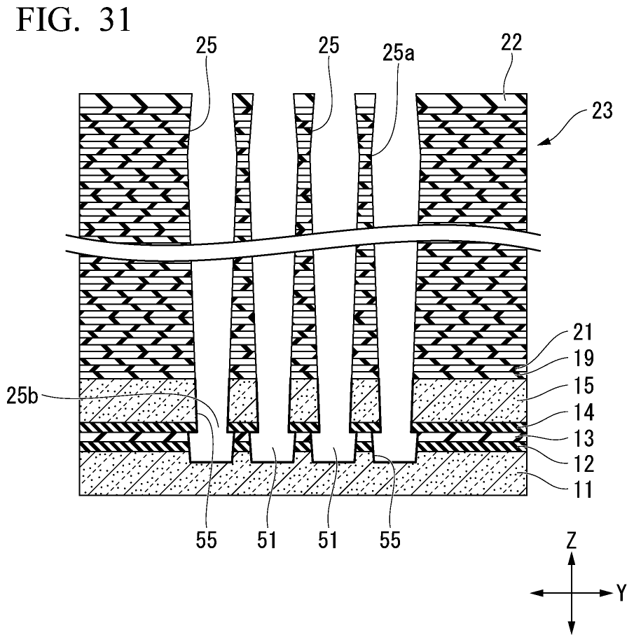

As shown in FIG. 31, the semiconductor layers 11 and 15 exposed to an inner surface of the bottom memory hole 51 and a bottom portion of the lower memory hole 25 are oxidized to form a silicon oxide layer 55.

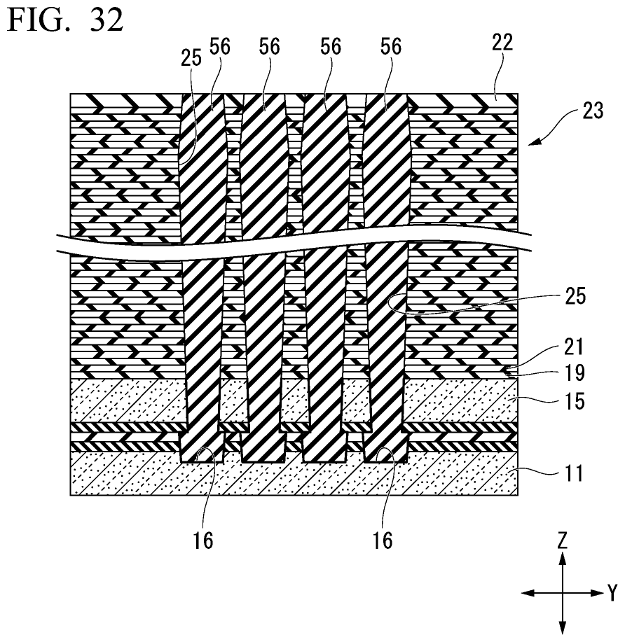

As shown in FIG. 32, a filler 56 is formed to fill the bottom memory hole 51 and the lower memory hole 25. A carbon film or the like can be applied to the filler 56.

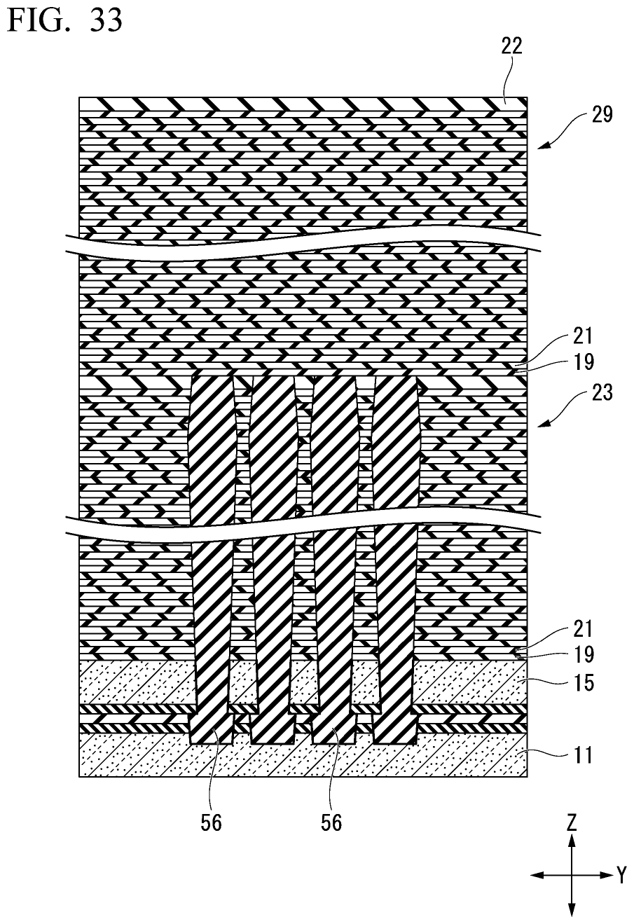

As shown in FIG. 33, an upper multi-layered body 29 is formed on the lower multi-layered body 23. A structure of the upper multi-layered body 29 is the same as that of the lower multi-layered body 23, the insulating layer 19 and the sacrificial layer 21 are alternately stacked, and the insulating layer 22 is formed on the uppermost sacrificial layer 21.

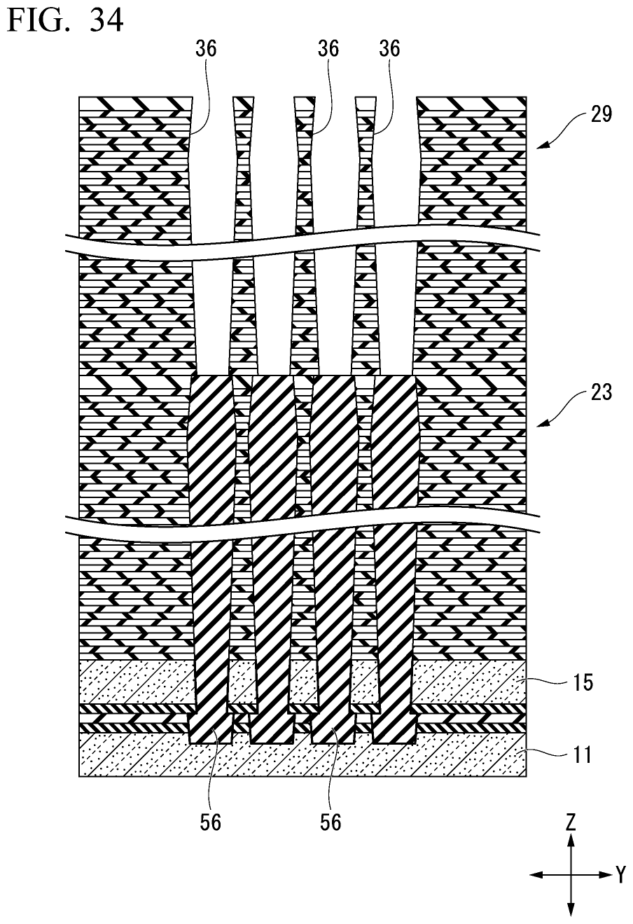

As shown in FIG. 34, an upper memory hole 36 extending from a top part to a bottom part of the upper multi-layered body 29 is formed with respect to the upper multi-layered body 29 to correspond to the formation position of the lower memory hole 25 described above. The upper memory hole 36 can be formed by an etching method such as reactive ion etching.

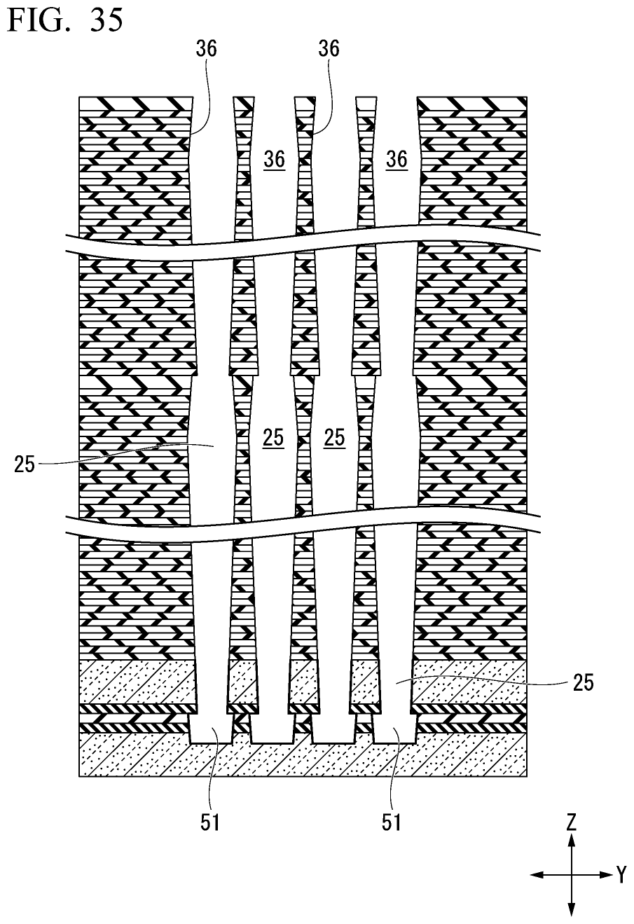

As shown in FIG. 35, the filler 56 is removed via the lower memory hole 25 by a method such as ashing to allow the upper memory hole 36, the lower memory hole 25, and the bottom memory hole 51 to communicate with each other.

In this method, only the filler 56 can be removed, and the inner diameter of the lower memory hole 25 is not unnecessarily expanded.

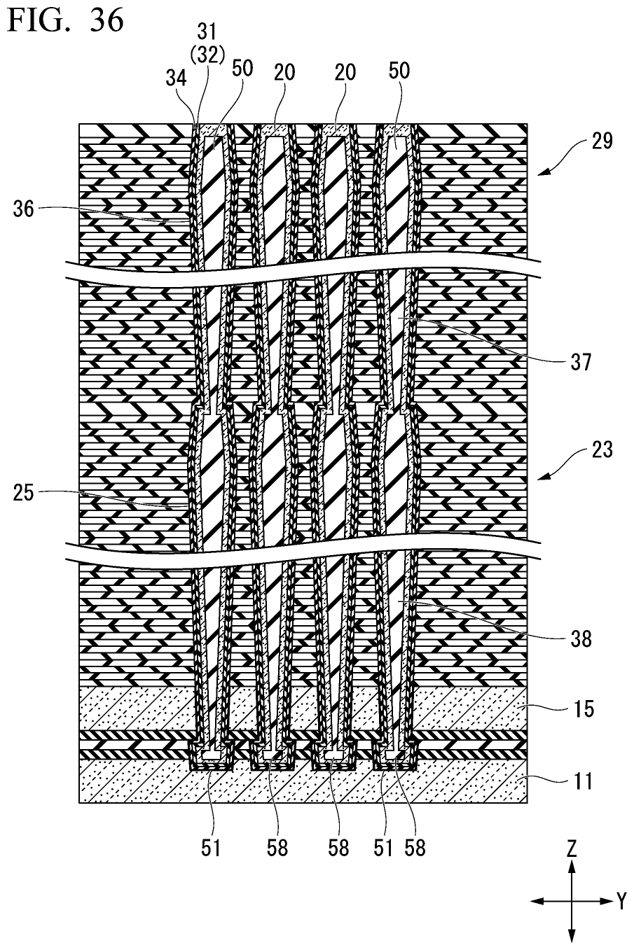

As shown in FIG. 36, depositions serving as a base for forming a columnar part LCL1 are performed in the bottom memory hole 51, the lower memory hole 25, and the upper memory hole 36. Depositions of a first block film 34, a charge storage film 32, a tunnel insulating film 31, the semiconductor body 20, and a core part 50 are performed to form an upper layer base columnar part 37 as a base for an upper layer columnar part UCL1 and a lower layer base columnar part 38 as a base for the lower layer columnar part LCL1.

A large diameter part 58 formed by a first block film 34, a charge storage film 32, a tunnel insulating film 31, a semiconductor body 20, and a core part 50 is formed at a lower end portion of a lower layer base columnar part 38. The large diameter part 58 is formed by these films deposited on the bottom memory hole 51. Of the first block film 34, the charge storage film 32, the tunnel insulating film 31, the semiconductor body 20, and the core part 50, the core part 50 is the thickest. Therefore, the core part 50 occupies most of the large diameter part 58, and the first block film 34, the charge storage film 32, the tunnel insulating film 31, and the semiconductor body 20 are formed to surround the core part 50 of the large diameter part 58.

In FIG. 36, for the sake of simplification of the drawing, the first block film 34, the charge storage film 32, and the tunnel insulating film 31 are simplified and drawn as one layer film.

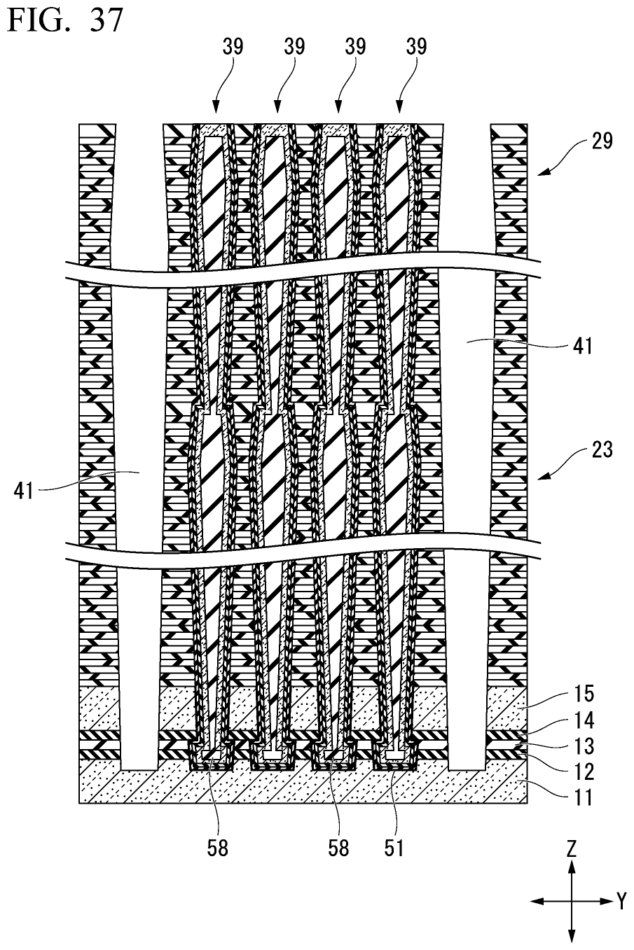

As shown in FIG. 37, slits 41 are formed on both sides in the Y direction (left-right direction) of a region. In the region, four base columnar parts 39 are formed. The slits 41 can be formed by an etching method such as reactive ion etching. Each of the slits 41 is formed to penetrate the upper multi-layered body 29 and the lower multi-layered body 23 in the Z direction and reaches an interconnection layer region 10A. The slit 41 has a depth such that the slit 41 penetrates the semiconductor layer 15, the protective layer 14, the sacrificial layer 13, and the protective layer 12, and the slit 41 reaches the semiconductor layer 11 at a predetermined depth.

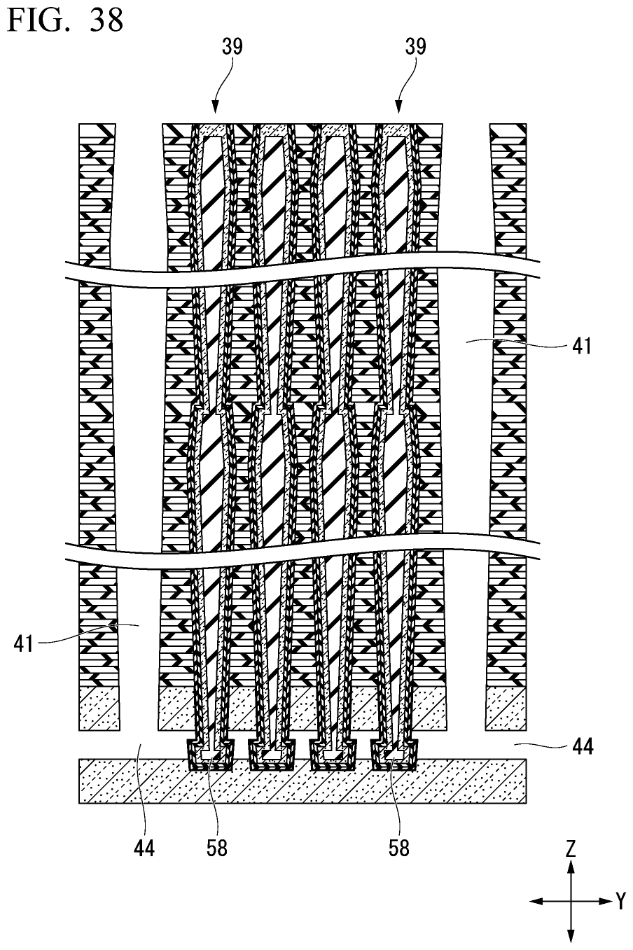

As shown in FIG. 38, etching processing using an etchant is performed through the slit 41 to remove the protective layer 14, the sacrificial layer 13, and the protective layer 12 formed in a region that will become the interconnection layer region 10A, and a hollow part 44 is formed.

From the state shown in FIG. 38, a liner film is formed on an inner surface of the slit 41, and etching is performed with respect to the large diameter part 58 formed at the lower end portion of the lower layer base columnar part 38 exposed to the hollow part 44. Due to this etching, the first block film 34, the charge storage film 32, and the tunnel insulating film 31 on an outer circumferential side of the large diameter part 58 are removed. Due to this etching, a connection part of the semiconductor body 20 can be formed in the hollow part 44.

Thereafter, when a conductive layer is deposited to fill the hollow part 44, a source line 10b equivalent to the source line 10b shown in FIG. 4 can be formed. Therefore, the interconnection layer region 10A having a semiconductor layer 10a, the source line 10b, and a semiconductor layer 10c can be formed.

After the interconnection layer region 10A is formed, the liner film is removed, and etching is performed through the slit 41 to remove the sacrificial layer 21 stacked on the lower multi-layered body 23 and the upper multi-layered body 29. The sacrificial layer 21 can be removed by an etchant or an etching gas supplied through the slit 41, and the hollow can be formed at a portion at which the sacrificial layer 21 is formed.

When a block insulating film and an electrode are formed in the hollow, the structure according to the second embodiment whose detailed structure is shown in FIGS. 39 and 40 can be realized.

### Second Embodiment

FIG. 39 shows a structure of the semiconductor storage device of the second embodiment having a center position displacement, and FIG. 40 shows a structure of the semiconductor storage device of the second embodiment without a center position displacement. The structures shown in FIGS. 39 and 40 are structures manufactured by the method described with reference to FIGS. 24 to 38.

The structure of FIG. 39 corresponds to the structure having a center position displacement shown in FIG. 7 in the first embodiment described above, and the structure of FIG. 40 corresponds to the structure that does not have a center position displacement shown in FIG. 8 in the first embodiment described above.

A lower end portion CLE of the lower layer columnar part LCL1 is implanted in the interconnection layer region 10A as shown in FIG. 39. More specifically, a core end portion 50B having a large diameter is formed at a lower end portion of the core part 50 of the lower layer columnar part LCL1. The large diameter part 58 is formed by the semiconductor body 20, the tunnel insulating film 31, the charge storage film 32, and the first block film 34 surrounding the core end portion 50B having the large diameter. An upper portion 58a of the large diameter part 58 is positioned inside the source line 10b, and a lower portion 58b of the large diameter pan 58 is formed at a boundary position with the semiconductor layer 10a.

In a formation region of the source line 10b, the tunnel insulating film 31, the charge storage film 32, and the first block film 34 are partially removed, and a connection part 20a of the semiconductor body 20 is formed. In the connection part 20a, the semiconductor body 20 is directly connected to the source line 10b. The tunnel insulating film 31, the charge storage film 32, and the first block film 34 are formed in a portion implanted in the semiconductor layer 10a in the lower portion 58b of the large diameter part 58.

At a boundary portion between the source line 10b and the semiconductor layer 10c shown in FIG. 39, removal of the tunnel insulating film 31, the first block film 34, and the like is performed to a side slightly above the boundary position between the source line 10b and the semiconductor layer 10c. Therefore, an extension part is formed in this portion so that a part of the source line 10b bites into the semiconductor layer 10c side.

At a boundary portion between the source line 10b and the semiconductor layer 10a shown in FIG. 39, removal of the tunnel insulating film 31, the first block film 34, and the like is performed to a side slightly below the boundary position between the source line 10b and the semiconductor layer 10a. Therefore, an extension part is formed in this portion so that a part of the source line 10b bites into the semiconductor layer 10a side.

The generation of the extension pan of the source line 10b is a result of removing the tunnel insulating film 31, the first block film 34, and the like beyond the boundary between the source line 10b and the semiconductor layer 10c by isotropic etching when the protective layer 12, the sacrificial layer 13, and the protective layer 14 are removed by etching as shown in FIG. 38.

As shown in FIG. 39, a center 58c of the large diameter pan 58 provided at the lower end portion CLE of the lower layer columnar par LCL1 and a center 54c of a first portion 54 of the lower layer columnar part LCL1 positioned at a bottom portion of a lower multi-layered body 100c have a positional displacement in the Y direction.

A positional displacement pan MR is formed at a connecting portion between a lower end of the first portion 54 of the lower layer columnar part LCL1 and an upper end of the large diameter part 58.

In the embodiment, as shown in FIG. 39, the position of the center 54c of the first portion 54 of the lower layer columnar part LCL1 is slightly displaced to the right side from the position of the center 58c of the large diameter part 58. An amount of the positional displacement is preferably smaller than a radius of the first portion 54 of the lower layer columnar part LCL1.

FIG. 40 shows a structure when the position of the center 58c of the large diameter part 58 and the position of the center 54c of the first portion 54 of the lower layer columnar part LCL1 coincide with each other. In the structure of the lower layer columnar part LCL1 shown in FIG. 40, other structures are the same as the structure of the lower layer columnar part LCL1 shown in FIG. 39.

The point that an extension part of the source line 10b is formed at a portion at which the tunnel insulating film 31, the first block film 34, and the like are removed in the boundary portion between the source line 10h and the semiconductor layer 10c is also the same as that of the structure shown in FIG. 39. The point that an extension part of the source line 10b is formed at a portion at which the tunnel insulating film 31, the first block film 34, and the like are removed in the boundary portion between the source line 10b and the semiconductor layer 10a is also the same as that of the structure shown in FIG. 39.

In the structures shown in FIGS. 39 and 40, as described in detail in the manufacturing method described with reference to FIGS. 24 to 38, the bottom memory hole 51 is formed in advance in the interconnection layer region 10A and then the lower multi-layered body 23 is formed on a region that will become the interconnection layer region 10A. Thereafter, the lower memory hole 25 is formed in the lower multi-layered body 23 by ion etching to allow the bottom memory hole 51 and the lower memory hole 25 to communicate with each other. Therefore, the position of the center of the lower memory hole 25 and the position of the center of the bottom memory hole 51 may be slightly displaced in the Y direction due to an accuracy in ion etching.

However, when a plurality of lower layer columnar parts LCL1 are manufactured, the position of the center 58c of the large diameter part 58 may also coincide with the position of the center 54c of the first portion 54 of the lower layer columnar part LCL1 as shown in FIG. 40. That is, when the plurality of the lower layer columnar parts LCL1 are manufactured, some of the lower layer columnar parts LCL1 may also not have a center position displacement as shown in FIG. 40.

Therefore, in the structure according to the second embodiment, the structure of the lower layer columnar part LCL1 shown in FIG. 40, which does not have a center position displacement, may be included in a part of the plurality of the formed lower layer columnar parts LCL1.

Even in the structure having the lower layer columnar part LCL1 of the structure shown in FIGS. 39 and 40, the same effects as those obtained in the first embodiment described above can be obtained.

### Third Embodiment

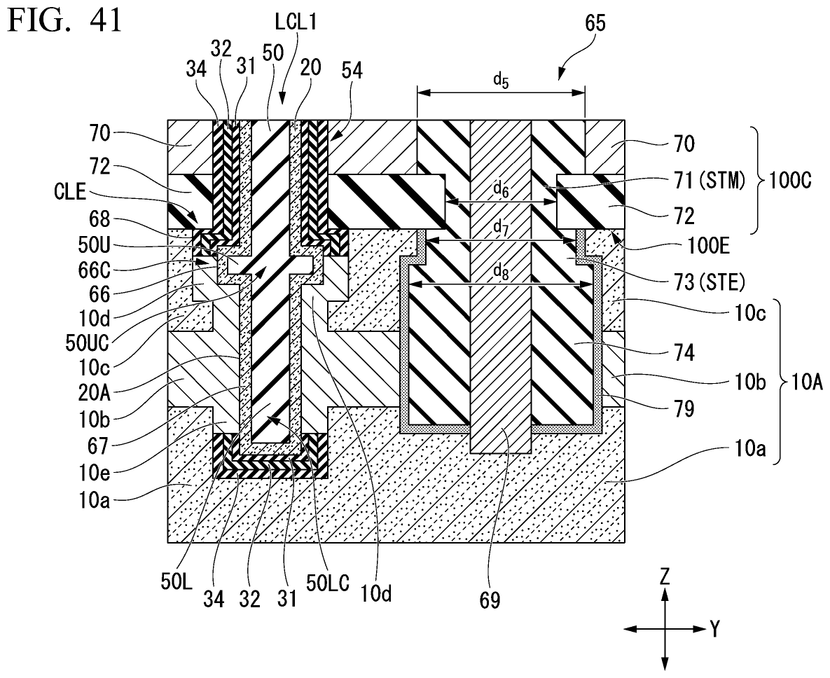

FIG. 41 shows a structure according to a third embodiment.

The structure according to the third embodiment is partially different from the structure according to the first embodiment. In the first embodiment, the lower end portion (second portion) CLE of the lower layer columnar part LCL1 is connected to the interconnection layer region 10A. Also, the structure of the insulating part 60 provided in the first embodiment is partially different in the third embodiment.

In addition, the structures of the lower multi-layered body 100c and the upper multi-layered body 100d, the structure of the upper layer columnar part UCL1, and the like are the same as those in the first embodiment.

In FIG. 41, the portion shown on the left side in the figure shows a lower end portion CLE of a lower layer columnar part LCL1 according to the third embodiment, and the portion shown on the right side in the figure shows a lower end portion of an insulating part 65 according to the third embodiment.

In the third embodiment, it is the same as the structure according to the first embodiment in that an interconnection layer region 10A has a structure having a semiconductor layer 10a, a source line 10b, and a semiconductor layer 10c which are stacked in that order from a semiconductor substrate 10 side.

In the third embodiment, it is also the same as the first embodiment in that the lower layer columnar part LCL1 includes a core part 50, a semiconductor body 20, a tunnel insulating film 31, a charge storage film 32, and a first block film 34 in that order from the inside.

Also, although not shown in FIG. 41, it is also the same as the first embodiment in that a lower multi-layered body 100c and an upper multi-layered body 100d are stacked on the interconnection layer region 10A to provide the lower layer columnar part LCL1 and an upper layer columnar part UCL1.

In the third embodiment, a large diameter part 66 is formed in a portion of the lower end portion CLE of the lower layer columnar part LCL1 facing an inner side of the semiconductor layer 10c. The large diameter part 66 is formed by covering a portion with a large diameter formed in a part of the core part 50 with the semiconductor body 20.

The large diameter part 66 is provided on an upper side of the semiconductor layer 10c, and a thickness of the large diameter part 66 in a Z direction (vertical direction in FIG. 41) is smaller than a thickness (film thickness) of the semiconductor layer 10c in the Z direction. In the cross section shown in FIG. 41, the large diameter part 66 and the core part 50 on upper and lower sides of the large diameter part 66 are formed in a cross shape.

In the lower end portion CLE of the lower layer columnar part LCL1, a small diameter part 67 having an outer diameter smaller than that of the large diameter part 66 is formed at a portion below the large diameter part 66. In other words, the lower layer columnar part LCL1 includes the large diameter part 66 and the small diameter part 67. The large diameter part 66 is positioned at a portion at which the lower layer columnar part LCL1 faces the interconnection layer region 10A. The large diameter part 66 is positioned at a boundary position between the multi-layered body and the interconnection layer region 10A. The small diameter part 67 is closer to the substrate than the large diameter part 66 is. The small diameter part 67 is formed of the core part 50 and the semiconductor body 20 that covers the core part 50.

The small diameter part 67 penetrates the semiconductor layer 10c and the source line 10b and reaches a predetermined depth of the semiconductor layer 10a. The core part 50 has a lower core part 50L and an upper core part 50U. The lower core part 50L is positioned at a portion at which the lower layer columnar part LCL1 penetrates a bottom portion of the lower multi-layered body 100c. In other words, the lower core part 50L is positioned below the upper core part 50U. The upper core part 50U is positioned at a bottom portion of the lower multi-layered body 100c. In other words, the position of the upper core part 50U corresponds to that of the large diameter part 66.

The outer diameter of the small diameter part 67 is equal to an outer diameter of a lower combined portion 50LC formed of the lower core part 50L and the semiconductor body 20.

The outer diameter of the large diameter part 66 is larger than an outer diameter of an upper combined portion 50UC formed of the upper core part 50U and the semiconductor body 20.

As shown in FIG. 41, in the lower end portion CLE of the lower layer columnar part LCL1, the semiconductor body 20 is formed to be positioned on outer circumference of the small diameter part 67 and the large diameter part 66. The semiconductor body 20 in the lower end portion CLE of the lower layer columnar part LCL1 is surrounded by the semiconductor layer 10c on a circumferential side of the large diameter part 66.

A connection part 20A is formed in the semiconductor body 20 in the small diameter part 67 below the large diameter part 66, and the connection part 20A is connected to the source line 10b. In other words, the large diameter part 66 has a circumferential portion 66C. The large diameter part 66 is positioned at a portion at which the lower layer columnar part LCL1 is provided on the interconnection layer region 10A. The large diameter part 66 is positioned at a boundary position between the multi-layered body and the interconnection layer region 10A. The semiconductor body 20 includes a connection part 20A. The connection part 20A of the semiconductor body 20 is provided on the circumferential portion 66C of the large diameter part 66.

As shown in FIG. 41, the tunnel insulating film 31, the charge storage film 32, and the first block film 34 are formed on an inner side of the semiconductor layer 10c around the core part 50 on a side above the large diameter part 66. A ring-shaped maximum diameter part 68 having a larger outer diameter than the ring-shaped large diameter part 66 is formed in this portion. The maximum diameter part 68 and the large diameter part 66 have a shape such that the ring of the maximum diameter part 68 and the ring of the large diameter part 66 having diameters different from each other are vertically stacked in two stages. In FIG. 41, the maximum diameter part 68 and the large diameter part 66 have a shape such that the maximum diameter part 68 and the large diameter part 66 are stacked so as to have a step. In other words, the lower layer columnar part LCL1 includes the maximum diameter part 68 and the large diameter part 66. The maximum diameter part 68 is positioned at a portion at which the lower layer columnar part LCL1 is provided on the interconnection layer region 10A. The maximum diameter part 68 and the large diameter part 66 overlaps each other at a boundary position between the lower multi-layered body 100c and the interconnection layer region 10A.

In the lower end portion CLE of the lower layer columnar part LCL1, the tunnel insulating film 31, the charge storage film 32, and the first block film 34 are formed around the small diameter part 67 implanted in the semiconductor layer 10a.

In the configuration of FIG. 41, the large diameter part 66 and the small diameter part 67 are formed in the lower end portion CLE of the lower layer columnar part LCL1, and the large diameter part 66 and the small diameter part 67 are implanted in the interconnection layer region 10A.

An extension part 10d of the source line 10b is formed to cover the semiconductor body 20 formed around the large diameter part 66 and the small diameter part 67 below the large diameter part 66. The extension part 10d is formed of the same material as a material forming the source line 10b. The extension part 10d extends from a part of the source line 10b to cover a circumference of the large diameter part 66 and the small diameter part 67 below the large diameter part 66.

A lower end portion of the small diameter part 67 extends to reach an upper side of the semiconductor layer 10a at a predetermined depth, and an extension part 10e of the source line 10b is formed to cover the extended portion. The extension part 10e is formed of the same material as the material forming the source line 10b. The extension part 10e extends from a part of the source line 10b to cover the semiconductor body 20 around the lower end portion of the small diameter part 67.

The semiconductor body 20 that is present from around the large diameter part 66 to around the small diameter part 67 is connected to the source line 10b via both portions of the extension part 10d and the extension part 10c. Due to the presence of the extension part 10d and the extension part 10e, a structure that is advantageous in terms of contact properties between the semiconductor body 20 and the source line 10b can be obtained.

In the structure shown in FIG. 41, at the lower end portion of the insulating part 65, a thin wall part 71 is formed inside an insulating layer 72, a first thick wall part 73 is formed inside the semiconductor layer 10c below the thin wall part 71, and a second thick wall part 74 is formed below the first thick wall part 73.

As shown in FIG. 41, in the lower end portion of the insulating part 65, a width (width of the thin wall part 71 in the Y direction) d₆ of a portion in contact with the lowermost insulating layer 72 of the lower multi-layered body 100c is smaller than a width d₅ of a portion in contact with a lowermost conductive layer 70 of the lower multi-layered body 100c.

At the lower end portion of the insulating part 65, a width (width of the second thin wall part 73 in the Y direction) d₇ of a portion positioned on an upper side of the semiconductor layer 10c is formed to be slightly larger than the width d₆ described above. At the lower end portion of the insulating part 65, a width (width of the thick wall part 74 in the Y direction) d₄ of a portion extending from the semiconductor layer 10c to the semiconductor layer 10a past the source line 10b is formed to be slightly larger than the width di described above and the width d₈ is slightly larger than the width d₅.

Therefore, the Y-direction dimension (d₇) of the thick wall part 73 is larger than the Y-direction width dimension (d₆) of the thin wall part 71 in the insulating part 65.

A multi-layered body 100 includes an end portion 100E which is a portion facing the interconnection layer region 10A. The insulating part 65 includes the thin wall part 71 (third portion: STM) positioned in the end portion 100E of the multi-layered body 100. It can be explained that the insulating part 65 includes the first thick wall part 73 (fourth portion: STE) that is positioned closer to the substrate 10 than the thin wall part 71 (third portion: STM) is. In the insulating part 65, the Y-direction width d₇ of the fourth portion STE (thick wall part 73) is larger than the Y-direction width d₆ of the third portion STM (thin wall part 71).

Furthermore, a silicon oxide layer 79 is formed to surround a circumference of the second thin wall part 73 and a circumference of the thick wall part 74.

As shown in FIG. 41, an interconnection layer 69 penetrating the insulating part 65 in the Z direction is formed. A lower end portion of the interconnection layer 69 penetrates the insulating part 65 and reaches the semiconductor layer 10a below the insulating part 65. Although description is omitted in FIG. 41, an upper side of the interconnection layer 69 penetrates an upper side of the insulating pan 65 and extends above the multi-layered body 100 shown in FIG. 3. Furthermore, when the interconnection layer 69 is provided in the insulating pan 65, the interconnection layer 69 can be extended to an upper side of the multi-layered body 100 and connected to a source interconnection (not shown) disposed adjacent to a bit line BL.

A planar shape of the insulating part 65 shown in FIG. 41 will be described with respect to FIG. 64 for explaining a manufacturing method. In the planar shape of the insulating part 65, a plurality round hole-shaped holes adjacent to each other are connected, and each a hole is filled with an insulating material. The insulating part 65 is formed by forming the plurality of the round hole-shaped holes adjacent to each other at predetermined intervals in a direction (X direction) and by removing boundary portions of the plurality of the holes adjacent to each other by etching. Here, the X direction is a direction in which the insulating part 65 extends. A portion of the connected hole formed by connecting the plurality of the holes is filled with the insulating material, and therefore the insulating part can be formed.

A manufacturing method of the insulating part 65 and a shape thereof in a plan view will be described in detail later.

### <Effects of Structure of Third Embodiment>

In the structure according to the third embodiment, the large diameter part 66 and the maximum diameter part 68 are provided in the interconnection layer region 10A.

In the structure according to the third embodiment, a diameter of the portion at which the lower layer columnar part LCL1 passes through the interconnection layer region 10A is larger than a diameter of the portion at which the lower layer columnar part LCL1 penetrates the lower multi-layered body 100e. Then, as will be shown in the manufacturing method to be described later, the lower end portion of the lower layer columnar part LCL1 is formed in a portion based on the bottom memory hole 80 formed in the interconnection layer region 10A. A first portion of the lower layer columnar part LCL1 is formed in the lower multi-layered body 100c. In this case, in the same manner as in the cases of the first and second embodiments described above, even when a positional displacement occurs in the Y direction, the effect can be obtained that the first portion of the lower layer columnar part LCL1 can be reliably joined to the lower end portion of the lower layer columnar part LCL1.

Furthermore, as will be described in the manufacturing method to be described later, the effect obtained in the first and second embodiments can also be obtained in the structure according to the third embodiment. Specifically, the effect can be obtained that the inner diameter of the lower memory hole 25 is not unnecessarily large when the lower memory hole 25 is formed after the bottom memory hole 80 is formed.

### Fourth Embodiment

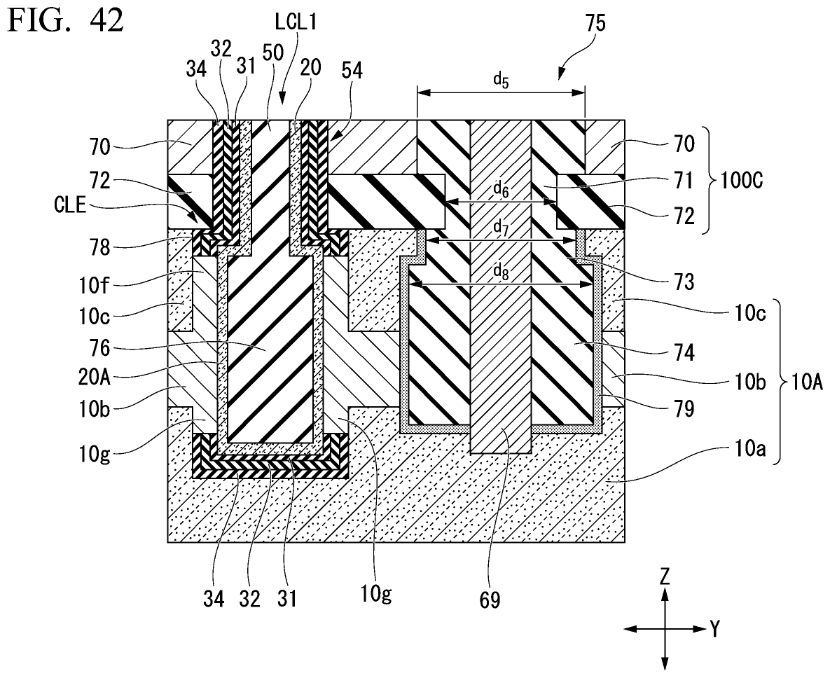

FIG. 42 shows a structure according to a fourth embodiment. A structure according to the fourth embodiment is partially different from the structure according to the first embodiment in that the lower end portion of the lower layer columnar part LCL1 is connected to the interconnection layer region 10A. Also, a structure of the portion provided in the first embodiment is partially different from that of the fourth embodiment in that the lower end portion of the insulating part 60 is implanted in the interconnection layer region 10A.

In FIG. 42, the portion shown on the left side in the figure shows a lower end portion of a lower layer columnar part LCL1 according to the fourth embodiment, and the portion shown on the right side in the figure shows a lower end portion of the insulating part 75 according to the fourth embodiment.

In the fourth embodiment, it is the same as the structure of first embodiment in that an interconnection layer region 10A has a structure having a semiconductor layer 10a, a source line 10b, and a semiconductor layer 10c which are stacked in that order from the lower layer side.

In the fourth embodiment, it is also the same as the first embodiment in that the lower layer columnar part LCL1 includes a core part 50, a semiconductor body 20, a tunnel insulating film 31, a charge storage film 32, and a block insulating film 33 in that order from the inside.

Also, although not shown in FIG. 42, it is also the same as the first embodiment in that a lower multi-layered body 100c and an upper multi-layered body 100d are stacked on the interconnection layer region 10A to provide the lower layer columnar part LCL1 and an upper layer columnar part UCL1.

In the fourth embodiment, a large diameter part 76 formed of the core part 50 and the semiconductor body 20 around the core part 50 is formed from a portion of a lower end portion CLE of the lower layer columnar part LCL1 passing through an upper side of the semiconductor layer 10c to a lower end of the lower layer columnar part LCL1. The large diameter part 76 is provided over the semiconductor layer 10c, the source line 10b, and the semiconductor layer 10a.

As shown in FIG. 42, on the lower end portion side of the lower layer columnar part LCL1, the semiconductor body 20 is formed on an outer circumferential side of the large diameter part 76. The semiconductor body 20 is in direct contact with the source line 10b and the semiconductor layer 10c on a circumferential side of the large diameter part 76.

As shown in FIG. 42, around the core part 50 on a side above the large diameter part 76, the tunnel insulating film 31, the charge storage film 32, and a first block film 34 are formed on an inner side of the semiconductor layer 10c to cover a circumference of the core part 50, and a ring-shaped maximum diameter part 78 having a larger outer diameter than the large diameter part 76 is formed in this portion.

At the lower end portion of the lower layer columnar part LCL1, the tunnel insulating film 31, the charge storage film 32, and the first block film 34 are formed around the large diameter part 76 implanted in the semiconductor layer 10a.

In the configuration of FIG. 42, the large diameter part 76 is formed at the lower end portion of the lower layer columnar part LCL1, and the large diameter part 76 is implanted in the interconnection layer region 10A.

More specifically, an extension part 10f of the source line 10b is formed to cover the semiconductor body 20 formed around an upper portion of the large diameter part 76. The extension part 10f is formed of the same material as a material forming the source line 10b. The extension part 10f extends from a part of the source line 10b to cover the semiconductor body 20 formed around the upper portion of the large diameter part 76.

A lower end portion of the large diameter part 76 extends to reach an upper side of the semiconductor layer 10a at a predetermined depth, and an extension part 10g of the source line 10b is formed to cover the extended portion. The extension part 10g is formed of the same material as the material constituting the source line 10b. The extension part 10g extends to cover the semiconductor body 20 formed around a lower portion of the large diameter part 76 from a part of the source line 10b.

Therefore, the semiconductor body 20 around the large diameter part 76 is connected to the source line 10b via both portions of the extension part 10f and the extension part 10g. Therefore, a structure that is advantageous in terms of contact properties between the semiconductor body 20 and the source line 10b can be obtained.

In the cross section shown on the right side of FIG. 42, a structure of the lower end portion of the insulating part 75 is similar to the structure of the lower end portion of the insulating part 65 shown in FIG. 41.

As shown in FIG. 42, a Y-direction width dimension d₆ is smaller than a Y-direction width dimension di. A Y-direction width dimension d₇ is larger than the Y-direction width dimension de. A Y-direction width dimension dx is larger than the Y-direction width dimension d₇. The Y-direction width dimension dᵣ is larger than the Y-direction width d₅.

As shown in FIG. 42, a thin wall part 71 is formed, a first thick wall pan 73 is formed, and a second thick wall part 74 is formed.

Therefore, a Y-direction width dimension of the thick wall part 73 of the insulating part 75 is larger than a Y-direction width dimension of the thin wall part 71 of the insulating part 75.

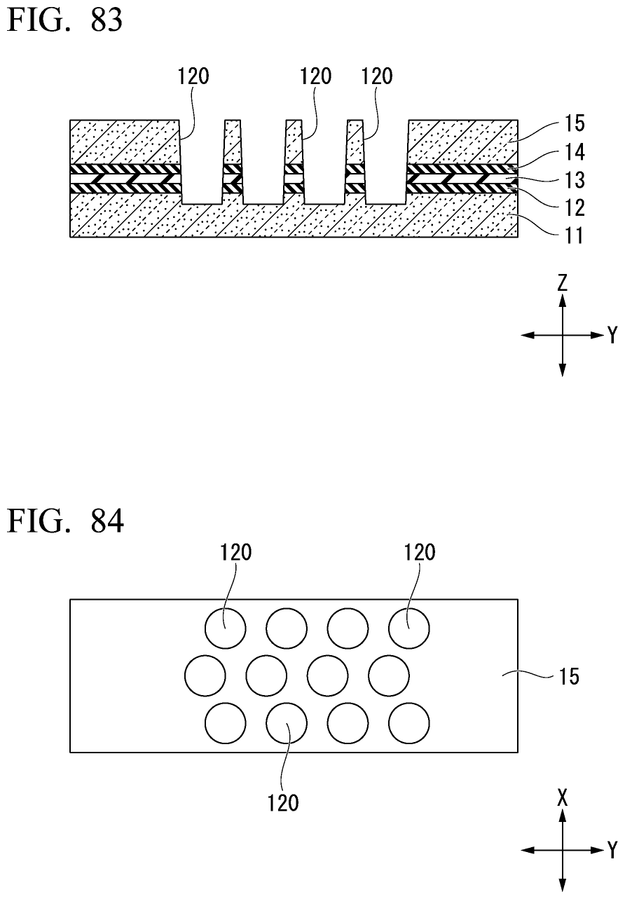

However, the insulating part 75 shown in FIG. 42 has a groove-shaped shape having a uniform width. While the insulating part 65 shown in FIG. 41 has a structure having a plurality of round hole-shaped holes which are connected, the insulating part 75 is a groove-shaped slit having a uniform inner width. Details of the insulating part 75 will be shown in a manufacturing method to be described later with reference to FIGS. 83 to 103.

Even in the structure according to the fourth embodiment having the lower layer columnar part LCL1 and the insulating part 75 of the configuration shown in FIG. 42, the same operation and effects as the structure according to the third embodiment described above can be obtained.

### <Manufacturing Method of Third Embodiment>

Next, a manufacturing method of the semiconductor storage device according to the third embodiment will be described with reference to FIGS. 43 to 64. Of FIGS. 43 to 64, figures shown as a cross section correspond to the cross section of FIG. 4.

FIG. 43 shows a state in which a semiconductor layer 11, a protective layer 12, a sacrificial layer 13, a protective layer 14, and a semiconductor layer 15 are stacked on the semiconductor substrate 10 for which description is omitted. The semiconductor layer 11 is, for example, a phosphorus-doped polycrystalline silicon layer. The protective layers 12 and 14 are, for example, silicon oxide films. The sacrificial layer 13 is, for example, an undoped polycrystalline silicon layer. The semiconductor layer 15 is, for example, an undoped or phosphorus-doped polycrystalline silicon layer.

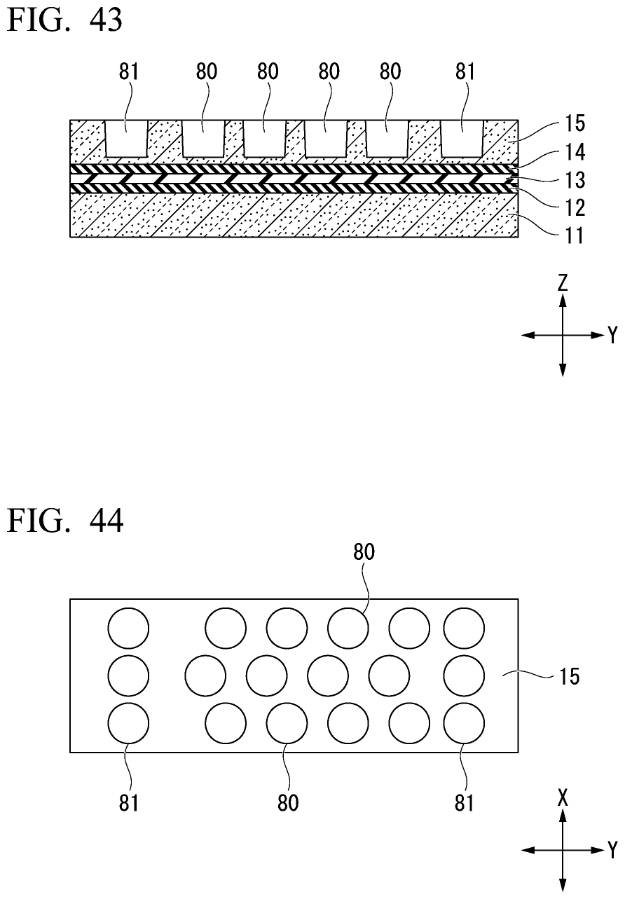

As shown in FIG. 43, a plurality of bottom memory holes 80 and bottom slit holes 81 are formed. In the embodiment, since a plurality of columnar parts CL1 are formed in a staggered manner as shown in FIG. 2, the bottom memory holes 80 are formed corresponding to positions at which the columnar parts CL1 should be formed. Also, each of the bottom slit holes 81 is formed to have a slight gap in a direction (X direction in FIG. 44) in which the insulating part 60 shown in FIG. 2 extends. FIG. 44 shows a plan view showing formation positions of the bottom memory hole 80 and the bottom slit hole 81.

The bottom memory hole 80 and the bottom slit hole 81 can be formed by an etching method such as reactive ion etching. The bottom memory hole 80 and the bottom slit hole 81 are formed in the semiconductor layer 15 at a depth close to the protective layer 14 so that the bottom memory hole 80 and the bottom slit hole 81 do not reach the protective layer 14.

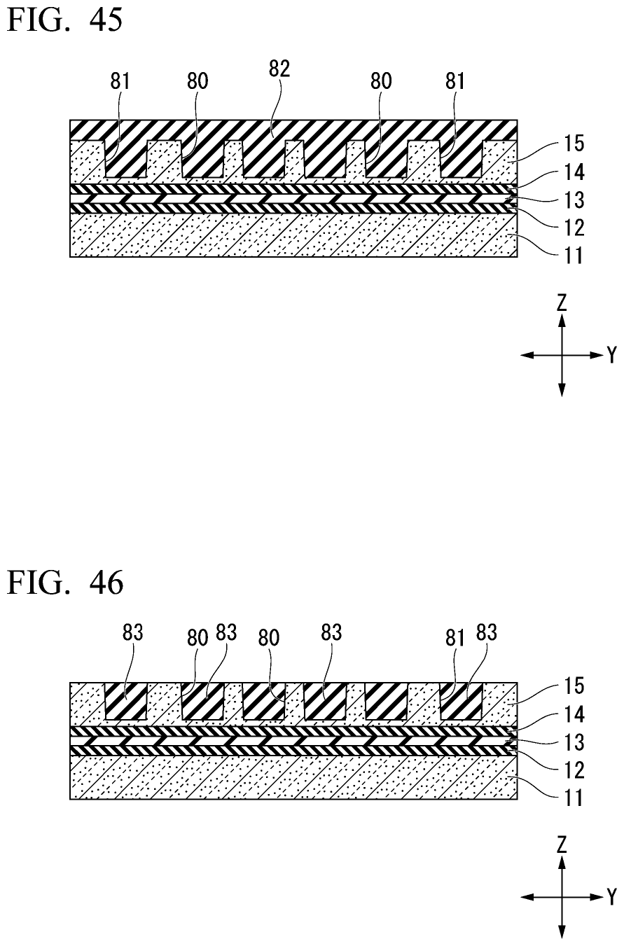

As shown in FIG. 45, a stopper material layer 82 is formed to fill the bottom memory hole 80 and the bottom slit hole 81 and cover an upper surface of the semiconductor layer 15. A carbon film or the like can be applied to the stopper material layer 82. A material forming the stopper material layer 82 is preferably a material having a high etching selectivity with respect to a lower multi-layered body 23 formed of a multi-layered body of an insulating layer 19 and a sacrificial layer 21 to be formed later.

As shown in FIG. 46, etching back is performed to remove the stopper material layer 82 stacked on the semiconductor layer 15, leaving only a stopper material 83 that fills the bottom memory hole 80 and the bottom slit hole 81. Therefore, a configuration is obtained which has the bottom memory hole 80 and the bottom slit hole 81 which are filled with the stopper material 83. FIG. 47 is a plan view showing the state shown in FIG. 46.

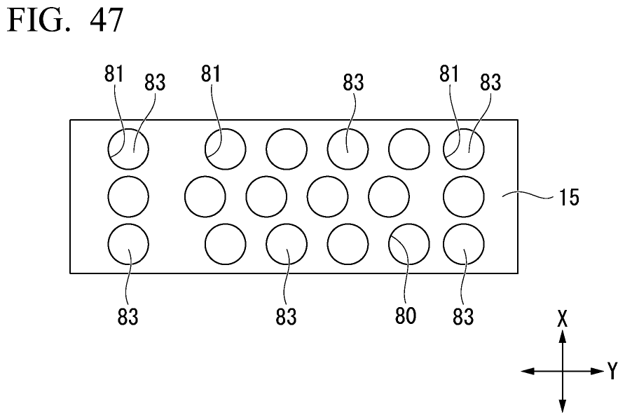

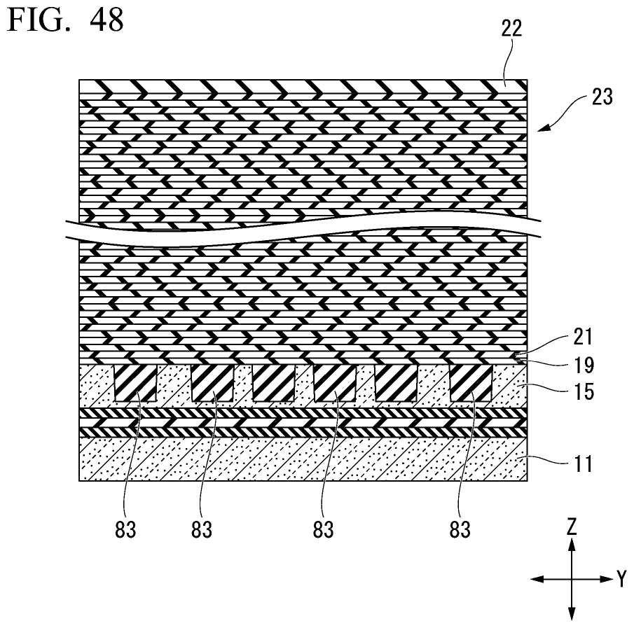

As shown in FIG. 48, the insulating layer 19 and the sacrificial layer 21 are alternately stacked, an insulating layer 22 is formed on the uppermost sacrificial layer 21, and therefore the lower multi-layered body 23 is formed. The insulating layers 19 and 22 are, for example, silicon oxide films, and the sacrificial layer 21 is, for example, a silicon nitride film.

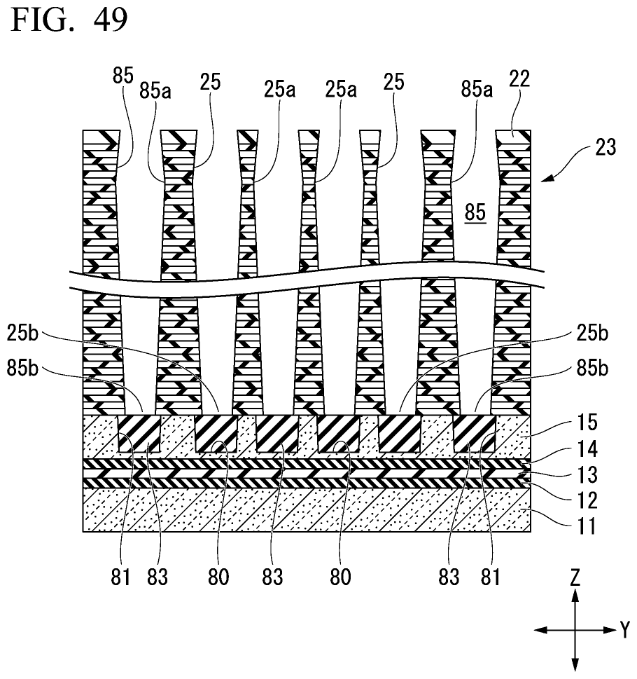

As shown in FIG. 49, the lower memory hole 25 extending from a top part to a bottom part of the lower multi-layered body 23 is formed with respect to the lower multi-layered body 23 to correspond to the formation position of the bottom memory hole 80 described above. At the same time, a lower slit hole 85 extending from the top part to the bottom part of the lower multi-layered body 23 is formed with respect to the lower multi-layered body 23 to correspond to the formation position of the bottom slit hole 81 described above.

The lower memory hole 25 and the lower slit hole 85 can be formed by an etching method such as reactive ion etching.

The lower memory hole 25 and the lower slit hole 85 have shapes in which inner diameters gradually decrease toward lower end portion sides thereof. An enlarged inner diameter part 25a is formed at a position slightly lower than an upper end of the lower memory hole 25. A lower end portion 25b of the lower memory hole 25 reaches the stopper material 83. The lower slit hole 85 has a shape such that the inner diameter gradually decreases toward a lower end portion side thereof. An enlarged inner diameter part 85a is formed at a position slightly lower than an upper end of the lower slit hole 85. A lower end portion 85b of the lower slit hole 85 reaches the stopper material 83.

Due to an error in positioning accuracy when the lower memory hole 25 and the lower slit hole 85 are formed, a position of a central axis of the lower memory hole 25 and a position of a center of the bottom memory hole 80 may be ally displaced in the Y direction (left-right direction) of FIG. 49. Also, a position of a center of the lower slit hole 85 and a position of a center of the bottom slit hole 81 may be displaced in the Y direction (left-right direction) of FIG. 49.

Even when the positional displacement is assumed to occur, since a diameter of an upper end portion of the stopper material 83 is slightly larger than an inner diameter of a lower end portion 25b of the lower memory hole 25, the lower end portion 25b of the lower memory hole 25 does not deviate in the Y direction from the upper end portion of the stopper material 83.

Also, since the diameter of the upper end portion of the stopper material 83 is slightly larger than an inner diameter of the lower end portion 85b of the lower slit hole 85, the lower end portion 85b of the lower slit hole 85 is not displaced in the Y direction from the upper end portion of the stopper material 83.

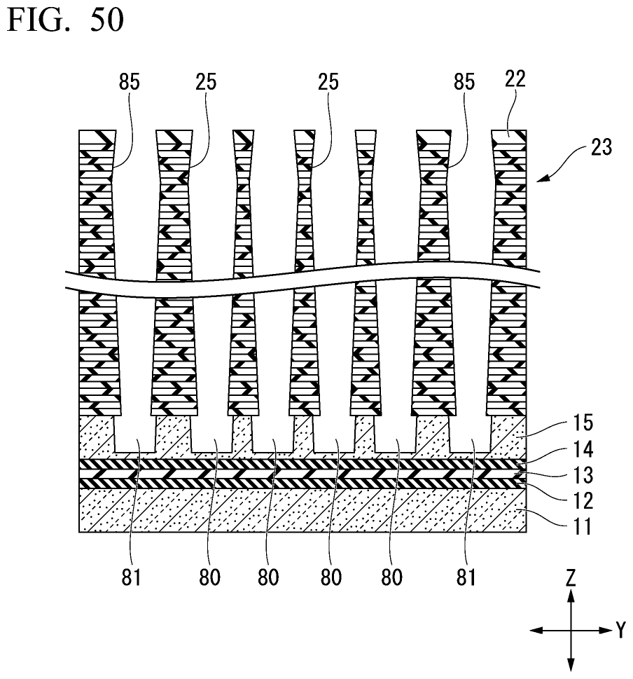

As shown in FIG. 50, the stopper material 83 is removed via the lower memory hole 25 by a method such as ashing, and the stopper material 83 is also removed via the lower slit hole 85 by ashing. Due to the ashing, the lower memory hole 25 and the bottom memory hole 80 communicate with each other, and the lower slit hole 85 and the bottom slit hole 81 communicate with each other.

In this method, only the stopper material 83 can be removed, and the inner diameter of the lower memory hole 25 and the inner diameter of the lower slit hole 85 are not unnecessarily expanded.

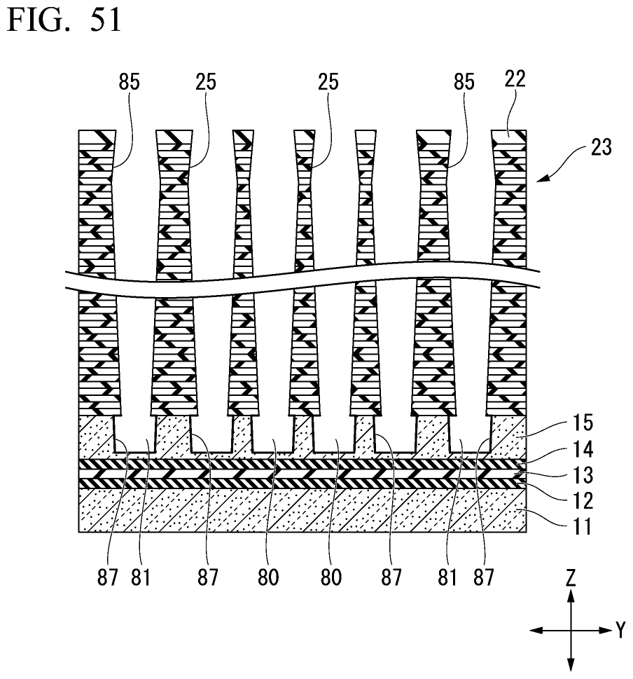

As shown in FIG. 51, the semiconductor layer 15 exposed to an inner surface of the bottom memory hole 80 and the bottom slit hole 81 is oxidized to form a silicon oxide layer 87.

As shown in FIG. 52, a filler 88 is formed to fill the bottom memory hole 80 and the lower memory hole 25, and to fill the bottom slit hole 81 and the lower slit hole 85. A carbon film or the like can be applied to the filler 88.

As shown in FIG. 53, a protective film 89 is formed on an upper surface of the lower multi-layered body 23 to cover an upper surface of the filler 88 that fills the lower slit hole 85.

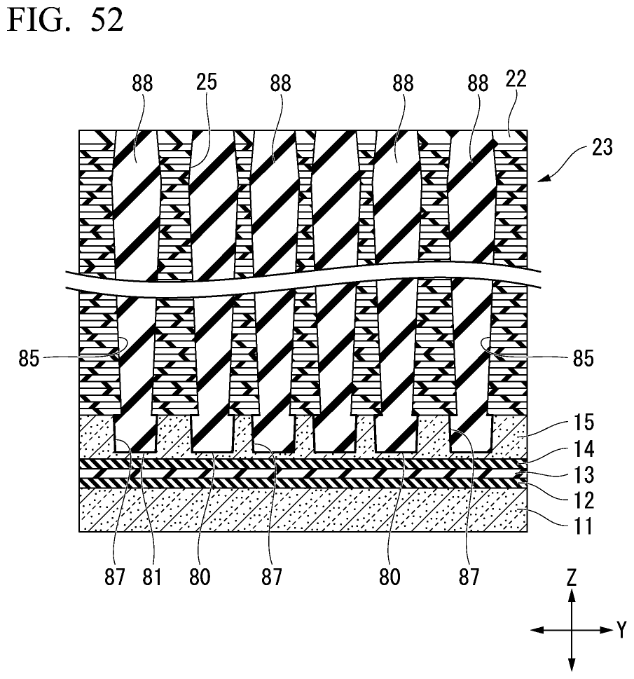

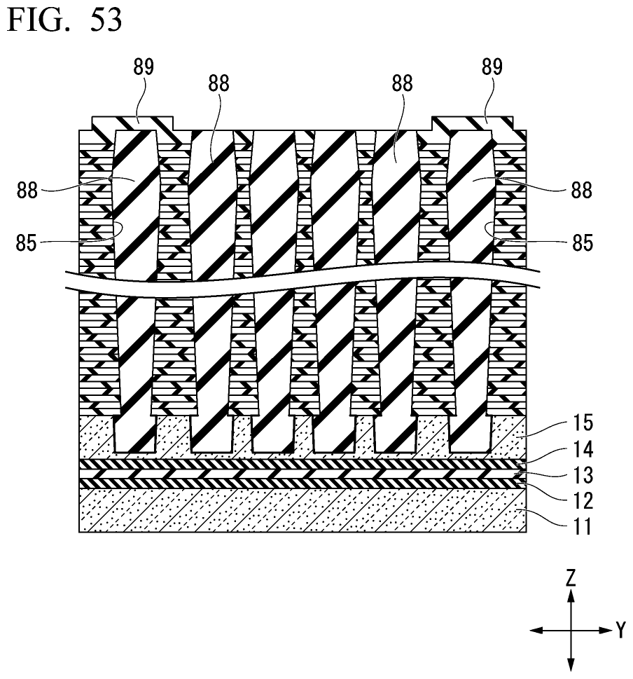

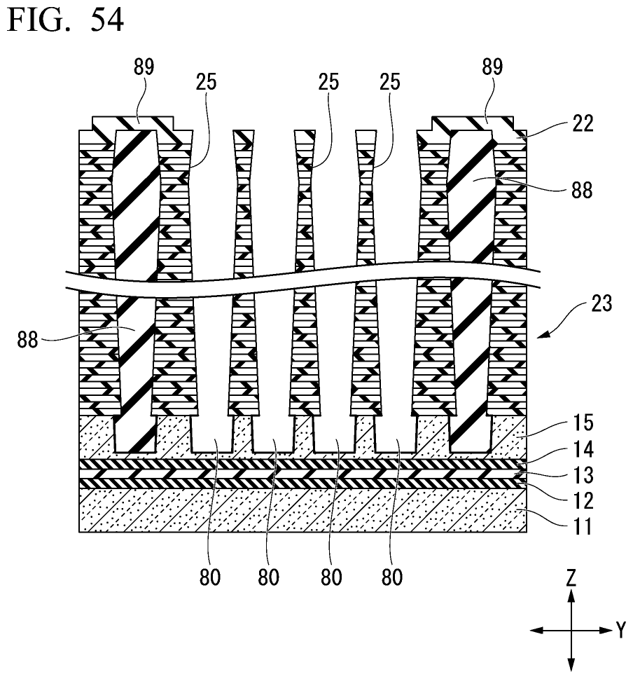

As shown in FIG. 54, the filler 88 of the lower memory hole 25 is removed by a method such as ashing to open the lower memory hole 25 and the bottom memory hole 80.

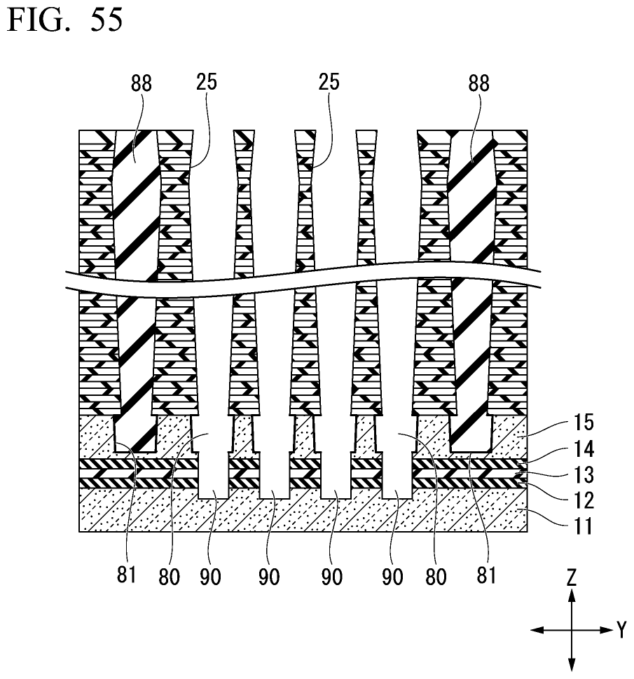

As shown in FIG. 55, a bottom of the opened bottom memory hole 80 is further scraped off by ion etching. A stretched hole 90 penetrating a bottom portion of the semiconductor layer 15, the protective layer 14, the sacrificial layer 13, and the protective layer 12, and reaching a predetermined depth of the semiconductor layer 11 is formed. Also, the protective film 89 formed on the upper surface of the lower multi-layered body 23 is removed.

As shown in FIG. 56, a filler 91 is formed to fill the lower memory hole 25, the bottom memory hole 80, and the stretched hole 90 that are opened earlier. A carbon film or the like can be applied to the filler 91.

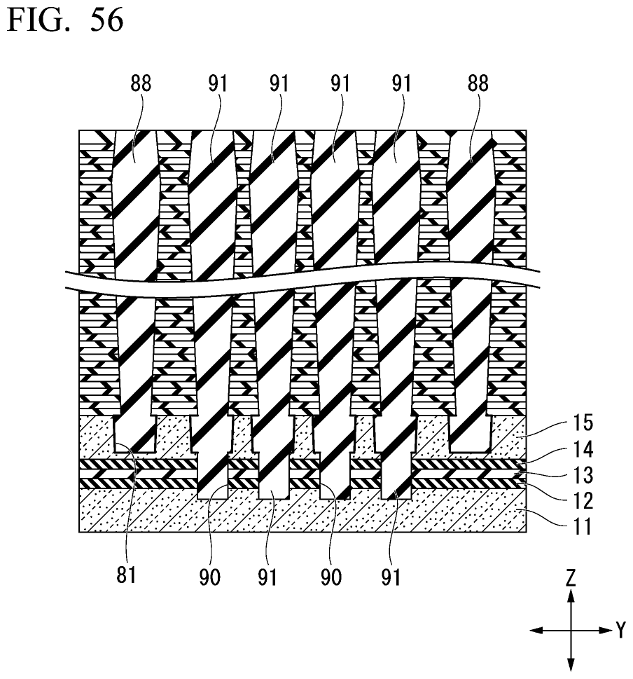

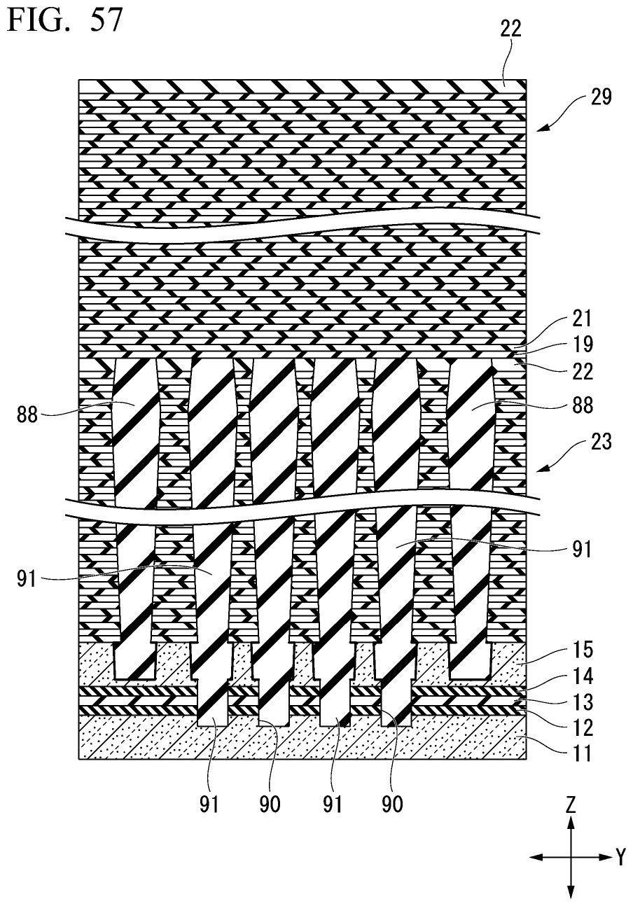

As shown in FIG. 57, an upper multi-layered body 29 is formed on the lower multi-layered body 23. A structure of the upper multi-layered body 29 is the same as that of the lower multi-layered body 23, the insulating layer 19 and the sacrificial layer 21 are alternately stacked, and the insulating layer 22 is formed on the uppermost sacrificial layer 21.

As shown in FIG. 58, an upper memory hole 92 extending from a top part to a bottom part of the upper multi-layered body 29 is formed with respect to the upper multi-layered body 29 to correspond to the formation position of the lower memory hole 25 described above. Also, at the same time as the formation of the upper memory hole 92, an upper slit hole 93 is formed to correspond to the formation position of the lower slit hole 85. The upper memory hole 92 and the upper slit hole 93 can be formed by an etching method such as reactive ion etching.

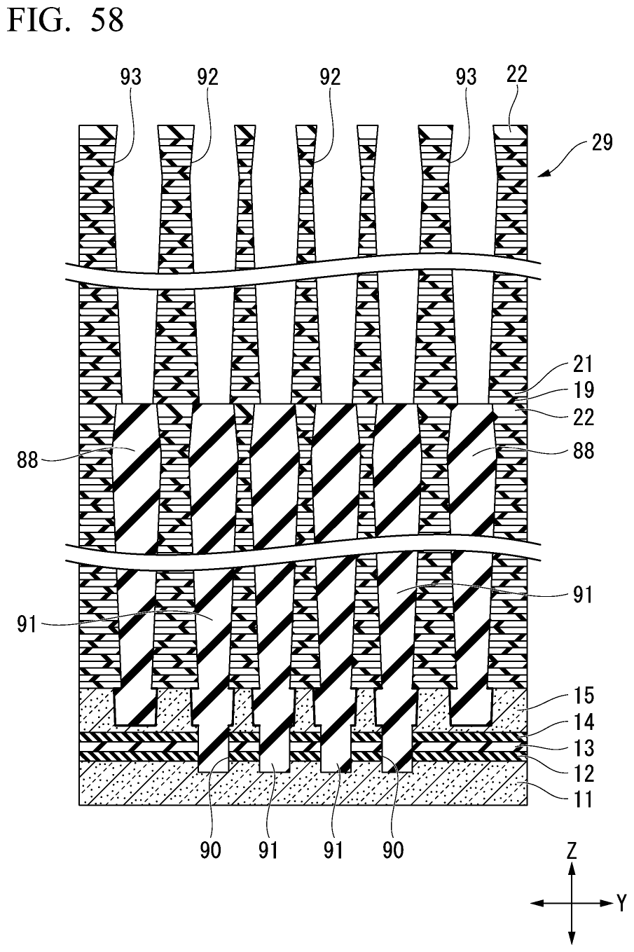

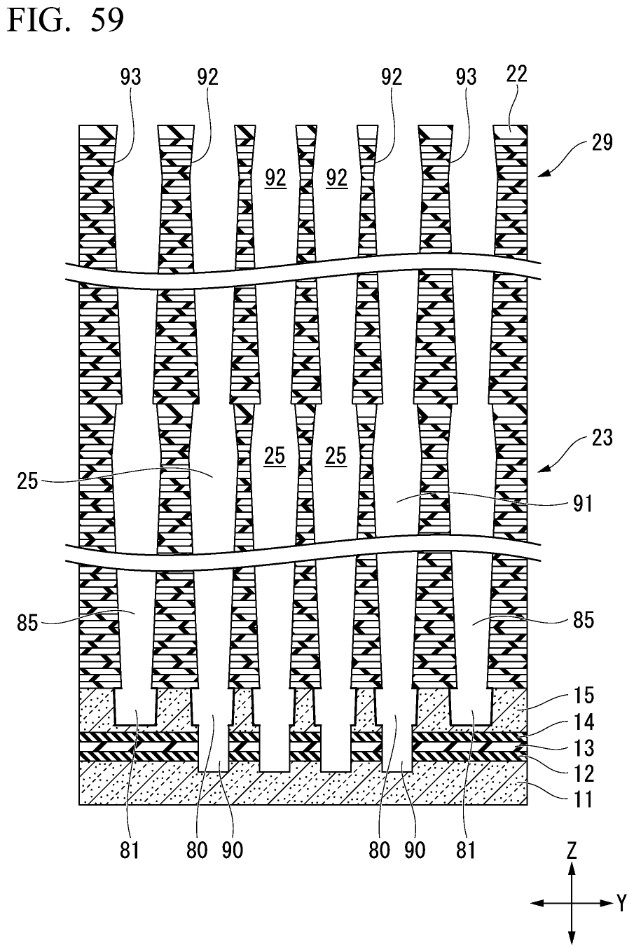

As shown in FIG. 59, the fillers 88 and 91 formed in the lower multi-layered body 23 are removed by a method such as ashing. Therefore, the upper memory hole 92, the lower memory hole 25, the bottom memory hole 80, and the stretched hole 90 communicate with each other. Furthermore, the upper slit hole 93, the lower slit hole 85, and the bottom slit hole 81 communicate with each other. FIG. 60 shows a plan view showing the upper multi-layered body 29 in a state in which each of these holes is allowed to communicate.

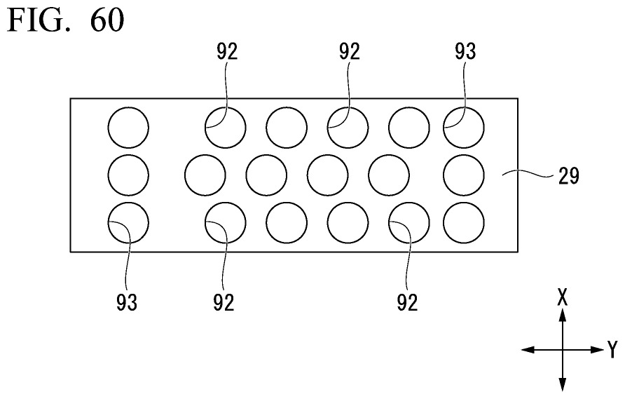

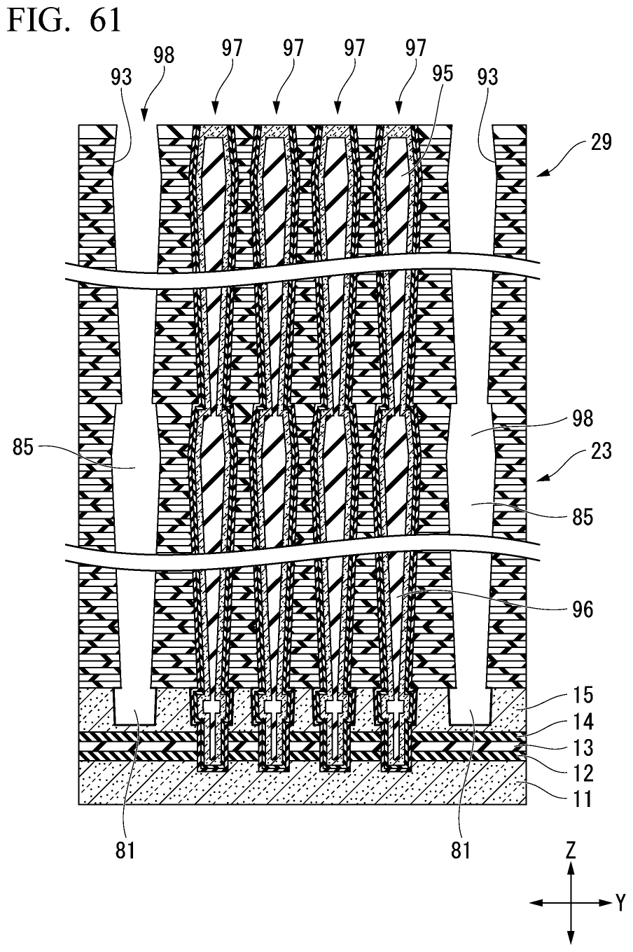

As shown in FIG. 61, depositions serving as a base for forming the columnar part LCL1 are performed in the stretched hole 90, the bottom memory hole 80, the lower memory hole 25, and the upper memory hole 92. Depositions of the first block film 34, the charge storage film 32, the tunnel insulating film 31, the semiconductor body 20, and the core part 50 are performed to form an upper layer base columnar part 95 as a base for the upper layer columnar part UCL1 and a lower layer base columnar part 96 as a base for the lower layer columnar part LCL1. Both the upper layer base columnar part 95 and the lower layer base columnar part 96 are collectively referred to as a base columnar part 97. FIG. 62 shows a plan view showing the upper multi-layered body 29 in a state in which the base columnar part 97 is formed.

As shown in the cross section of FIG. 61, the upper slit hole 93, the lower slit hole 85, and the bottom slit hole 81 are communicated with each other to form one hole 98. Also, a plurality of holes 98 are disposed in the X direction as shown in the plan view shown in FIG. 62.

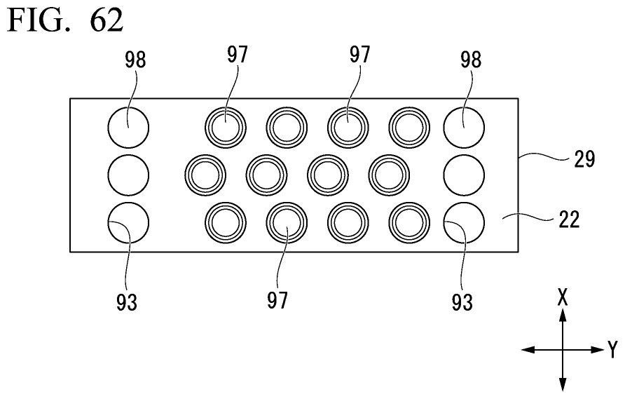

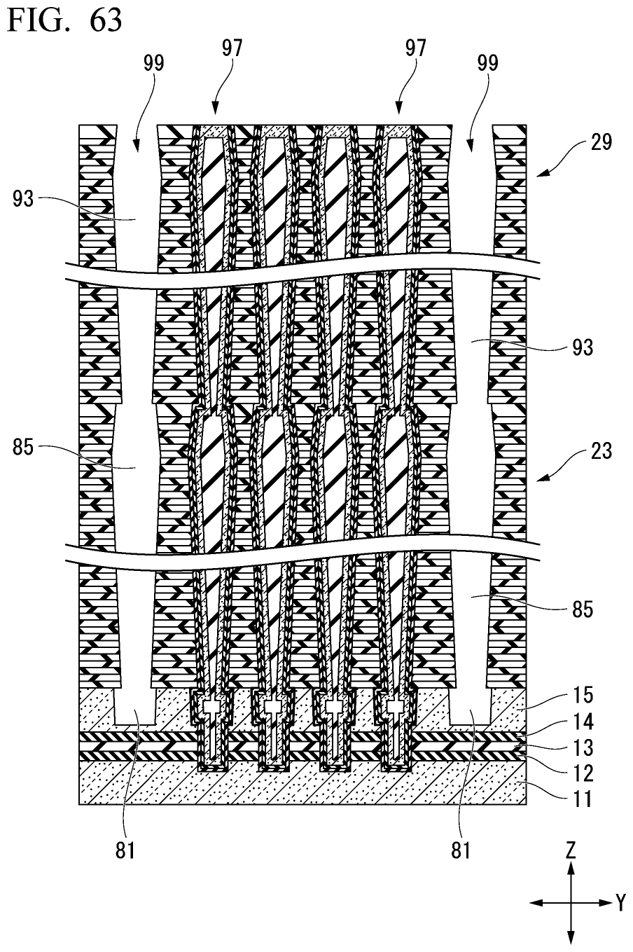

As shown in FIGS. 63 and 64, portions between the plurality of the holes 98 disposed in the X direction are removed by etching, and the holes 98 disposed in the X direction are connected to form a connected hole slit 99 shown in FIGS. 63 and 64. An inner side wall portion of the connected hole slit 99 is formed in a waveform in the X direction as shown in FIG. 64 as an example.

The states shown in FIGS. 63 and 64 are equivalent to the states of FIGS. 23 and 38 described above. Therefore, when the same method as the method described above is applied, the interconnection layer region 10A can be formed, the conductive layer 70 can be formed, and the insulating part can be formed by filling the insulating layer in the connected hole slit 99.

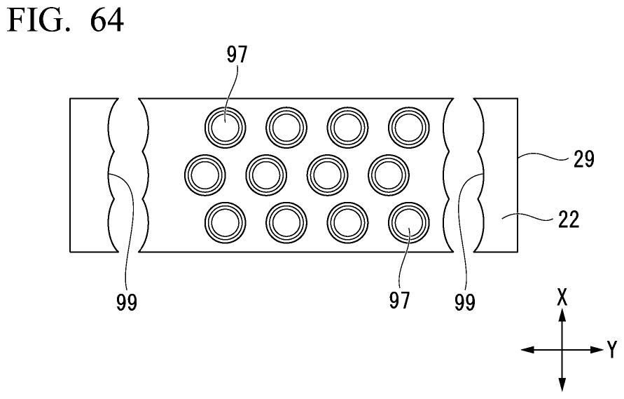

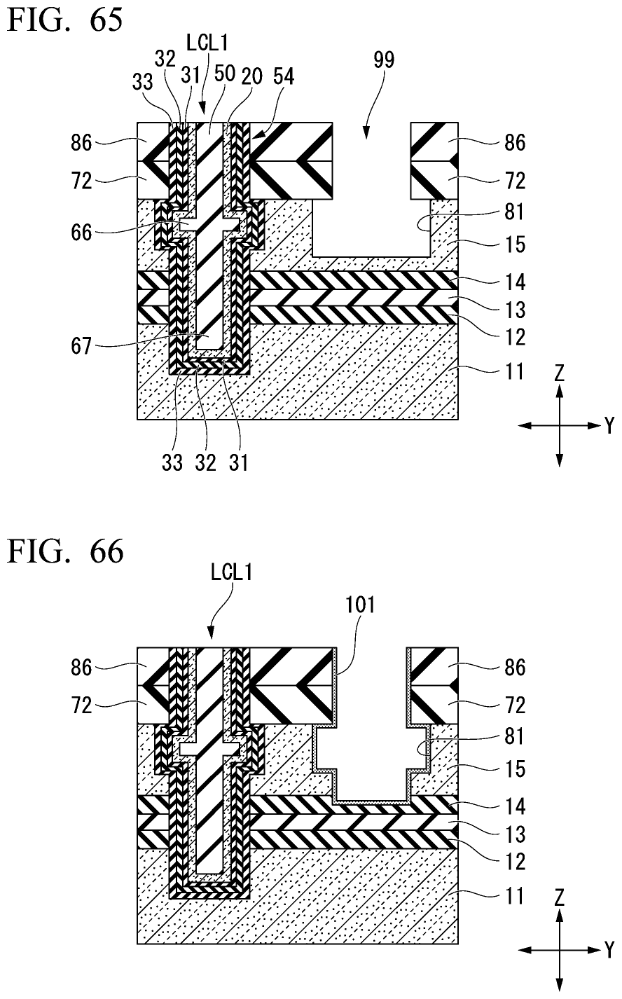

In the embodiment, a manufacturing method in a case of obtaining the structure shown in FIG. 41 from the state shown in FIGS. 63 and 64 will be described below with reference to FIGS. 65 to 82.

In FIG. 65, the portion shown on the left side in the figure shows the lower end portion of the lower layer columnar part LCL1 according to the third embodiment, and the portion shown on the right side in the figure indicates a lower end portion of the connected hole slit 99 according to the third embodiment.

FIGS. 65 to 82 used in the following description are shown as cross-sectional views in a state in which the lower end portion of the lower layer columnar part LCL1 and the lower end portion of the connected hole slit 99 are shown adjacent to each other on the left and right in each drawing for simplification of description.

The cross-sectional structure of the lower end portion of the lower layer columnar part LCL1 shown on the left side of FIG. 65 is equivalent to the cross-sectional structure of the lower end portion of the lower layer columnar part LCL1 shown on the left side of FIG. 41.

The connected hole slit 99 shown on the right side of FIG. 65 corresponds to the connected hole slit 99 in the state shown in FIGS. 63 and 64.

While the lower multi-layered body 100c shown in FIG. 41 has a multi-layered structure of the insulating layer 72 and the conductive layer 70, the structure shown in FIG. 65 is different in terms of having a multi-layered structure of the insulating layer 72 and the sacrificial layer 86. As will be described later, the sacrificial layer 86 is removed by etching, and then a conductive layer is formed in the portion at which the sacrificial layer 86 has been present. The multi-layered structure of the insulating layer 72 and the sacrificial layer 86 is the same structure as the lower multi-layered body 23 formed of the insulating layer 19 and the sacrificial layer 21 described in the previous example.

As shown in FIG. 65, the bottom slit hole 81 is formed at a bottom portion of the connected hole slit 99, and a bottom portion of the bottom slit hole 81 reaches a bottom portion side of the semiconductor layer 15.

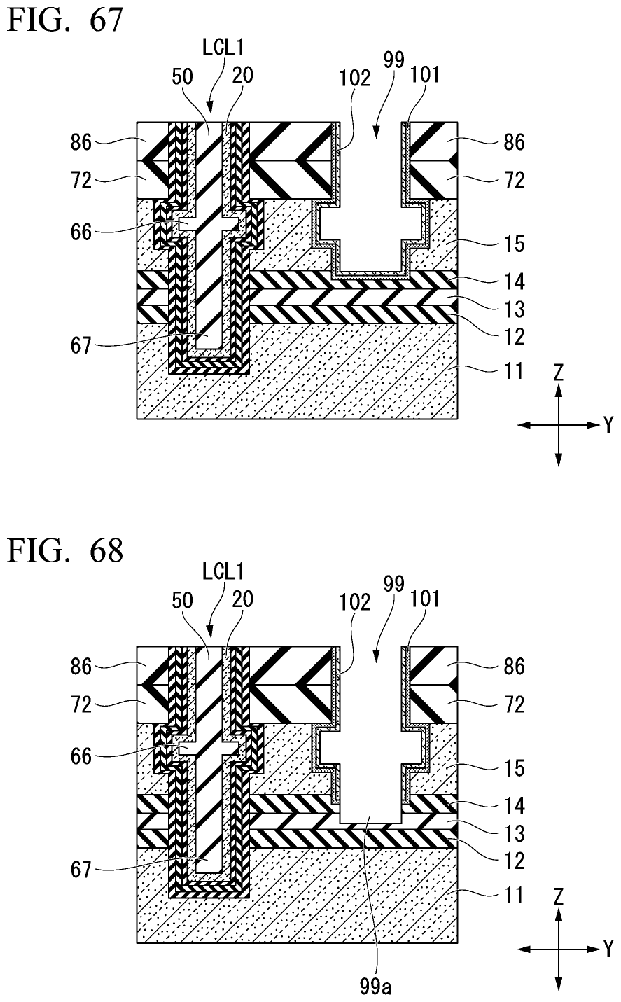

Reactive ion etching is performed to make the bottom portion of the bottom slit hole 81 reach the protective layer 14, and then an inner surface of the connected hole slit 99 is oxidized to form an oxide layer 101 as shown in FIG. 66, and an amorphous Si layer 102 is formed on an inner surface of the oxide layer 101 as shown in FIG. 67.

As shown in FIG. 68, reactive ion etching is performed, and a bottom surface of the connected hole slit 99 (bottom surface of the bottom slit hole 81) is dug down until it reaches the sacrificial layer 13 to form the stretched part 99a.

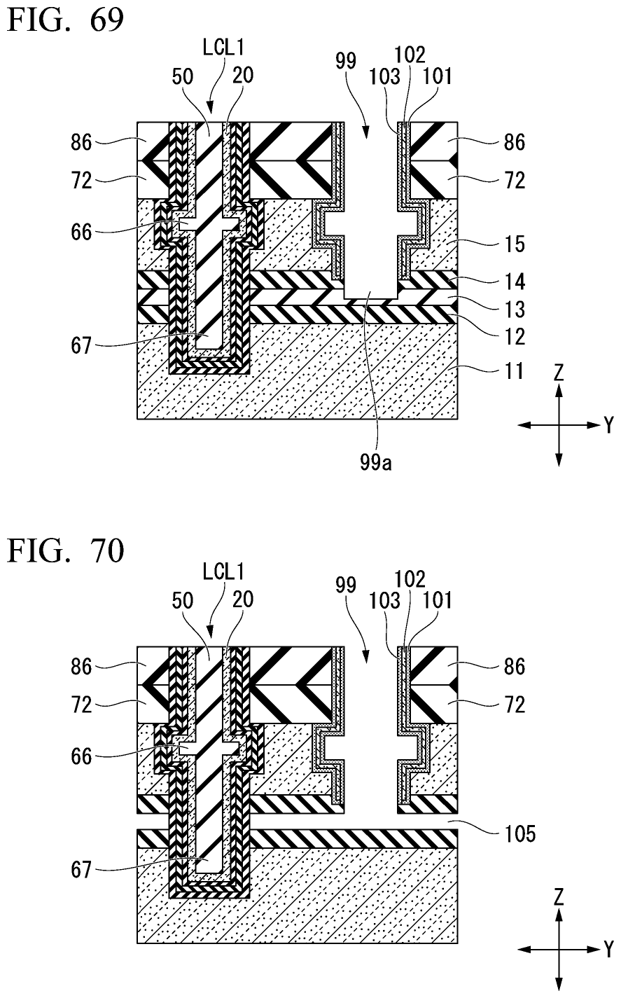

As shown in FIG. 69, the amorphous Si layer 102 on the inner surface of the connected hole slit 99 is oxidized to form a liner layer 103.

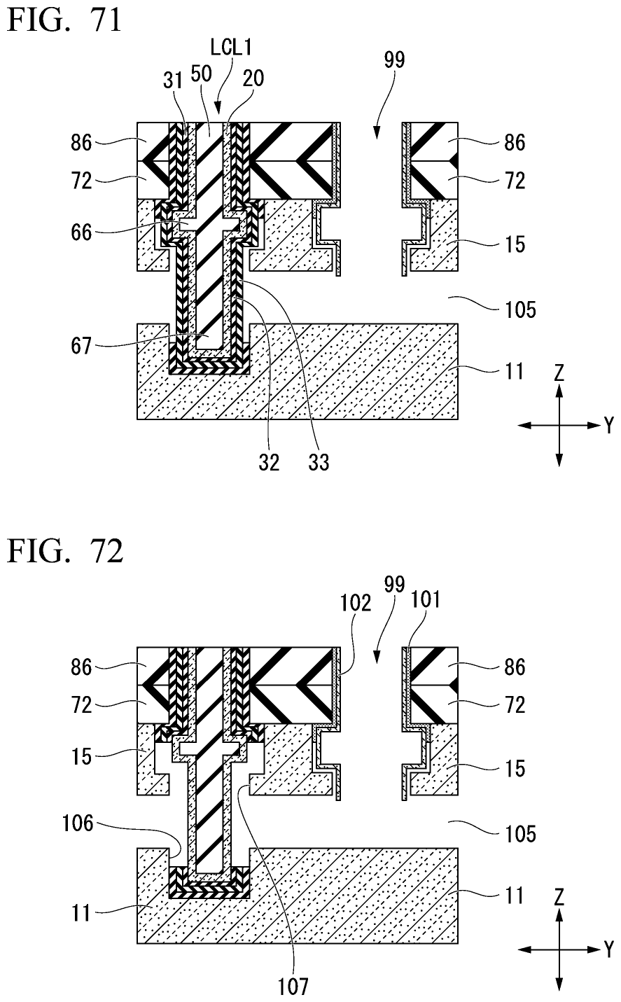

As shown in FIGS. 70 and 71, the protective layers 12 and 14 and the sacrificial layer 13 are removed using an etchant or an etching gas through the connected hole slit 99, and a hollow part 105 is formed between the upper semiconductor layer 11 and the lower semiconductor layer 15.

As shown in FIG. 72, the tunnel insulating film 31, the charge storage film (charge storage part) 32, and the block insulating film 33 on the lower end portion of the lower layer columnar part LCL1 exposed in the hollow part 105 are removed by etching through the connected hole slit 99.

Furthermore, as shown in FIG. 72, due to the etching described above, some of the tunnel insulating film 31, the charge storage film 32, and the block insulating film 33 buried in the semiconductor layers 11 and 15 on the lower end portion side of the lower layer columnar part LCL1 are also removed.

Therefore, the tunnel insulating film 31, the charge storage filmi 32, and the first block film 34 around the lower end portion of the lower layer columnar part LCL1 are also removed, and thereby, in the region those are removed, a recessed part 106 is formed in the semiconductor layer 11, and a recessed part 107 is formed in the semiconductor layer 15.

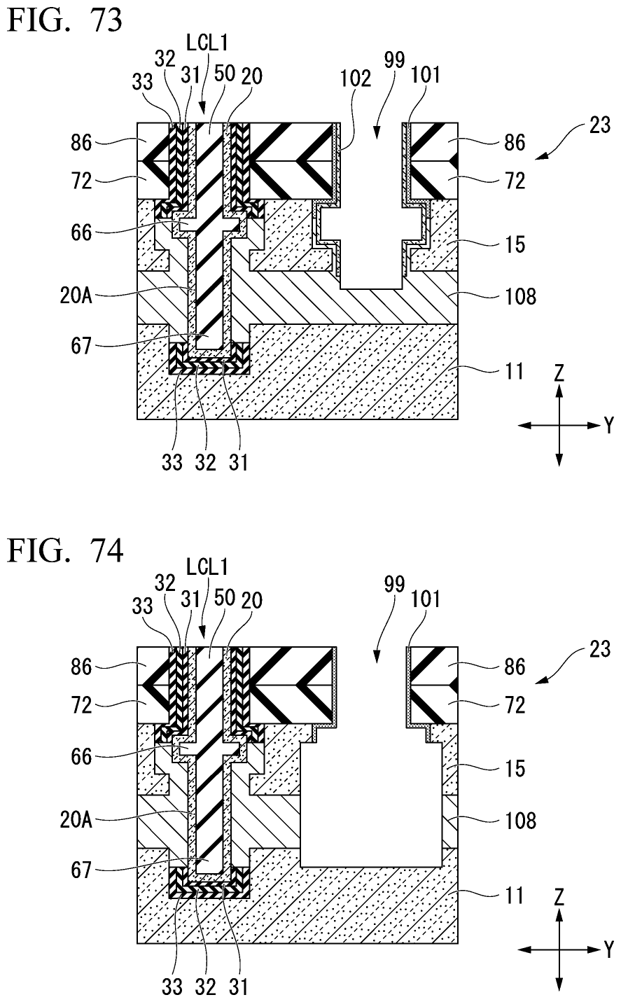

As shown in FIG. 73, an amorphous silicon film 108 is formed to fill the hollow part 105 through the connected hole slit 99.

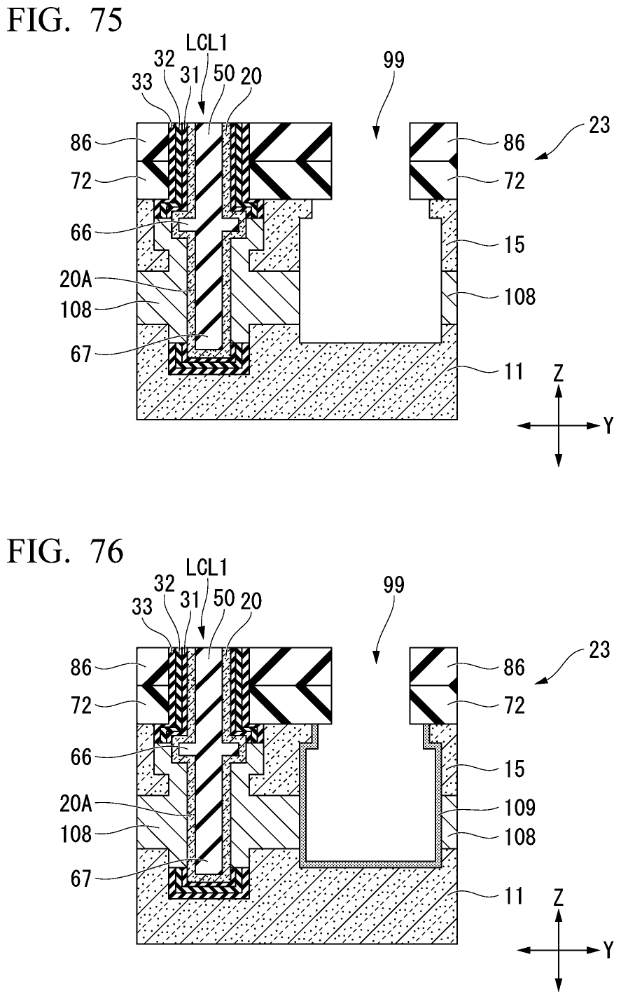

The connected hole slit 99 and the amorphous silicon film at the bottom portion thereof are removed by etching back as shown in FIG. 74, and the oxide layer 101 on the inner surface of the connected hole slit 99 is removed as shown in FIG. 75.

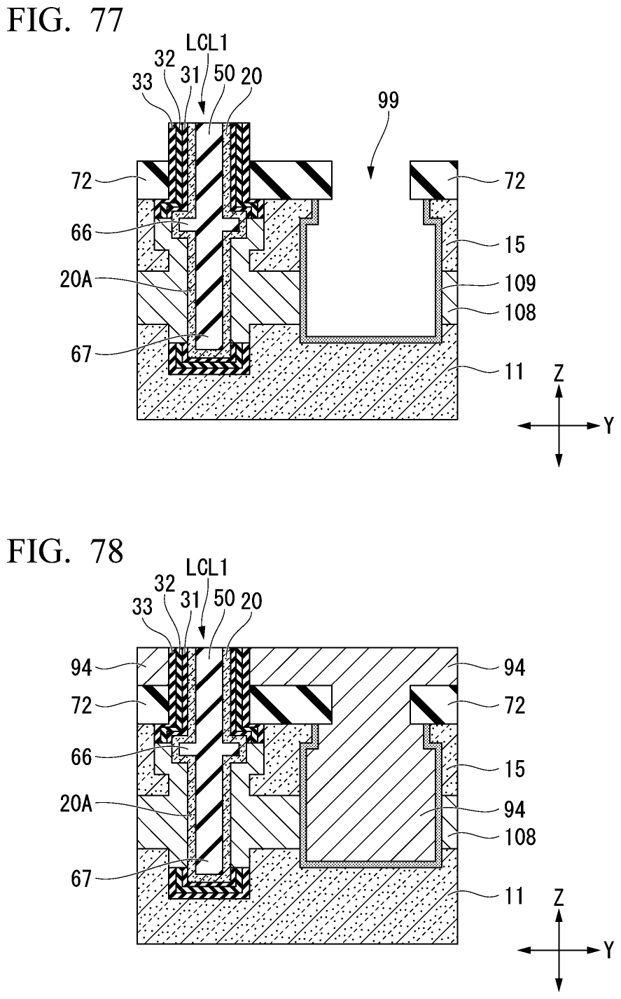

An oxide layer 109 is formed at the bottom portion of the connected hole slit 99 as shown in FIG. 76, and a sacrificial layer 86, which corresponds to the sacrificial layer 21 stacked on the lower multi-layered body 23 and the upper multi-layered body 29, is removed via the connected hole slit 99 as shown in FIG. 77. FIG. 77 shows a state in which only the lowermost sacrificial layer 86 of the lower multi-layered body 23 is removed.

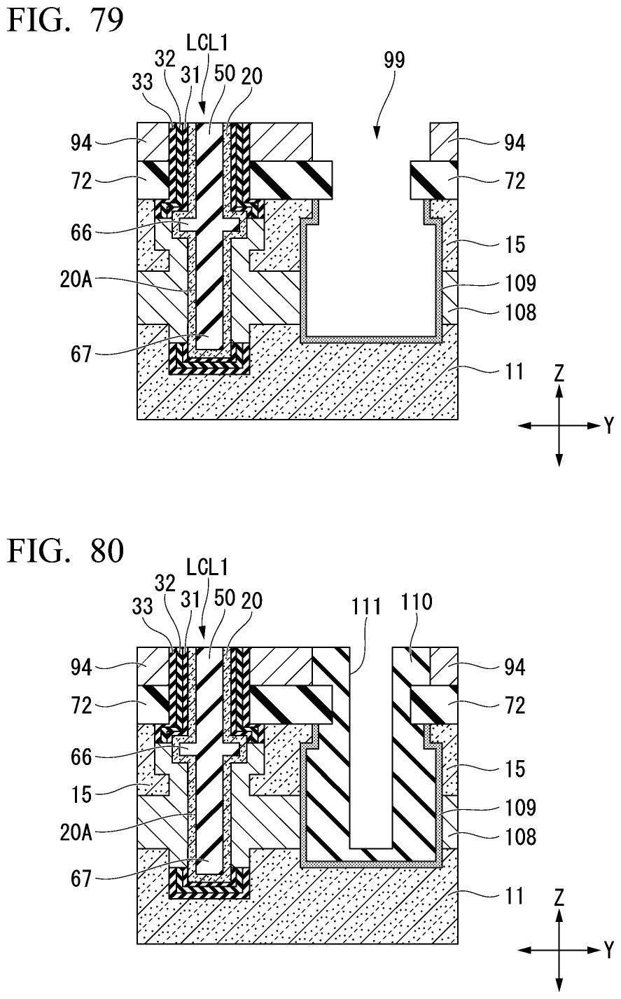

A metal layer 94 such as tungsten is formed through the connected hole slit 99 as shown in FIG. 78, and the metal layer 94 in the connected hole slit 99 is removed, leaving only the metal layer 94 stacked on the insulating layer 72 as shown in FIG. 79.

Through this processing, a multi-layered structure can be obtained which is similar to the lower multi-layered body 100c and the upper multi-layered body 100d having the insulating layer 72 and the conductive layer 70 which are stacked as shown in FIG. 4.

As shown in FIG. 80, an insulating layer 110 formed of, for example, silicon oxide is formed inside the connected hole slit 99. The insulating layer 110 is formed so that it covers facing inner side walls of the connected hole slit 99, and a hollow part 11 remains in a central portion in a width direction of the connected hole slit 99.

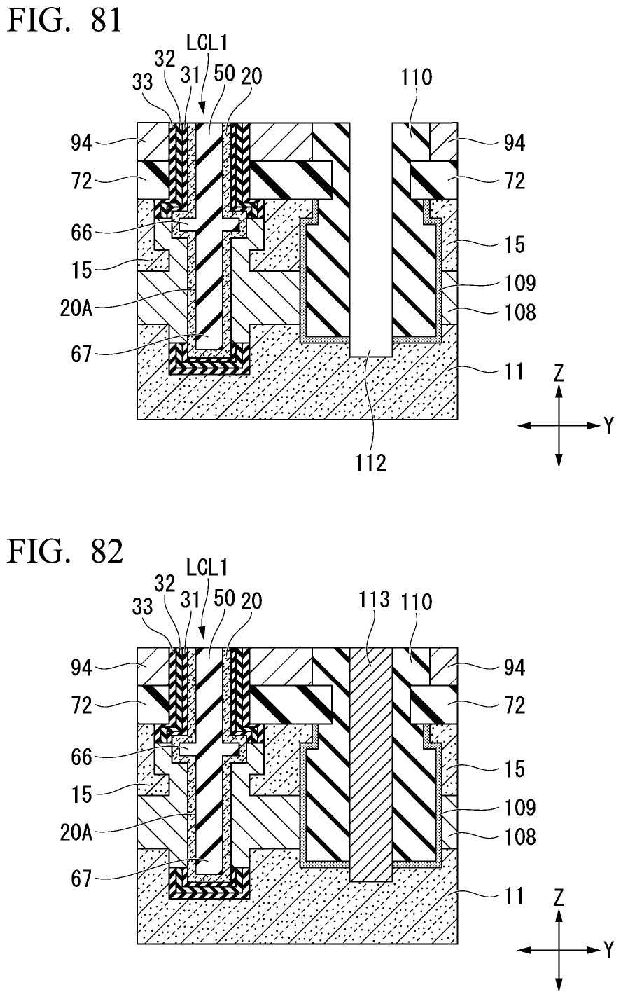

As shown in FIG. 81, a bottom portion of the hollow part 11 is dug down to form a stretched part 112 that reaches the semiconductor layer 11.

As shown in FIG. 82, a metal layer is formed to fill the hollow part 111 and the stretched part 112 so that an interconnection part 113 is formed.

The interconnection part 113 extends to an upper end portion of the insulating layer 110 that fills the connected hole slit 99. Therefore, when this is applied to the memory cell array 1 having the configuration shown in FIG. 3, a configuration can be employed which has a source line provided adjacent to the bit line BL and the interconnection part 113 connected to the source line.

### <Manufacturing Method of Fourth Embodiment>

Next, a manufacturing method of the semiconductor storage device according to the fourth embodiment will be described with reference to FIGS. 83 to 103. Of FIGS. 83 to 103, figures shown by a cross section correspond to the cross section of FIG. 4.

FIG. 83 shows a state in which a semiconductor layer 11, a protective layer 12, a sacrificial layer 13, a protective layer 14, and a semiconductor layer 15 are stacked on the semiconductor substrate 10 (not shown). The semiconductor layer 11 is, for example, a phosphorus-doped polycrystalline silicon layer. The protective layers 12 and 14 are, for example, silicon oxide films. The sacrificial layer 13 is, for example, an undoped polycrystalline silicon layer. The semiconductor layer 15 is, for example, an undoped or phosphorus-doped polycrystalline silicon layer.

As shown in FIGS. 83 and 84, a plurality of bottom memory holes 120 are formed. In the embodiment, since a plurality of columnar parts CL1 are formed in a staggered manner as shown in FIG. 2, the bottom memory holes 120 are formed corresponding to positions at which the columnar parts CL1 are formed. The bottom memory holes 120 can be formed by an etching method such as reactive ion etching. Each of the bottom memory holes 120 is formed to have a depth such that the bottom memory hole 120 penetrates the semiconductor layer 15, the protective layer 14, the sacrificial layer 13, and the protective layer 12, and the bottom memory hole 120 reaches the semiconductor layer 11 at a predetermined depth.

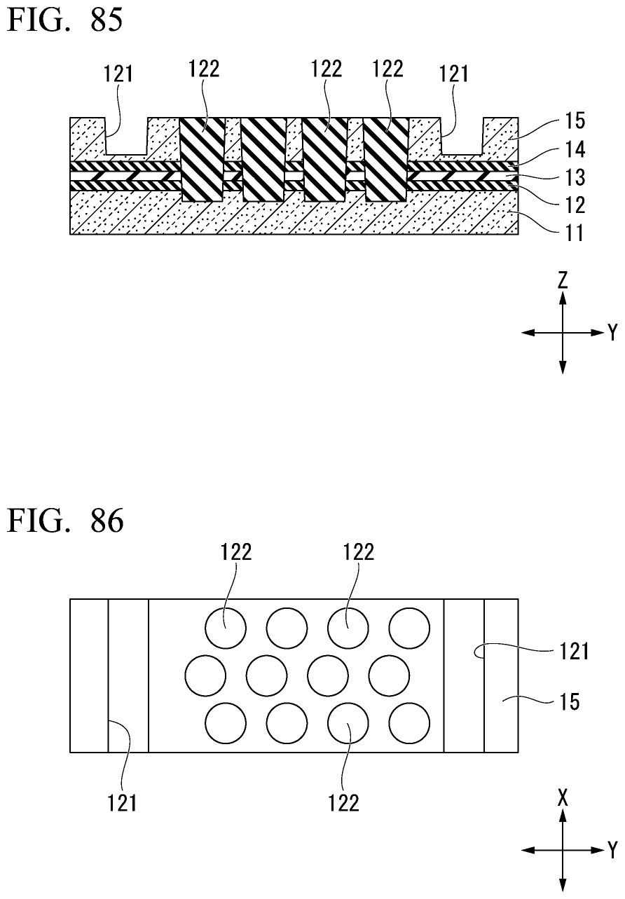

As shown in FIGS. 85 and 86, bottom slits 121 are formed on the left and right sides of a group of bottom memory holes 120 formed as shown in FIGS. 83 and 84. The bottom slits 121 formed here are slits having a uniform width.

When the bottom slits 121 are formed, it is preferable to form the bottom slits 121 after filling the inside of the bottom memory holes 120 with a filler 122 so that the bottom memory holes 120 are buried for protection.

The bottom slits 121 are formed in the semiconductor layer 15 at a depth close to the protective layer 14 so that the bottom slits 121 do not reach the protective layer 14.

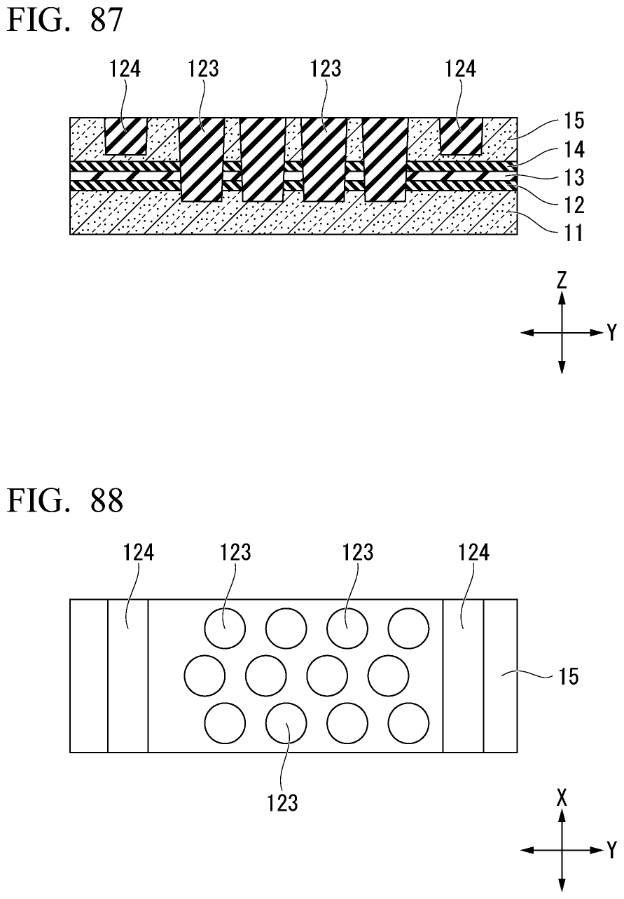

After the filler 122 is removed by a method such as ashing, a stopper material 123 is formed in each of the bottom memory holes 120, and a stopper material 124 is formed in each of the bottom slits 121 as shown in FIGS. 87 and 88. In forming the stopper materials 123 and 124, deposition is performed to fill the bottom memory hole 120 and the bottom slit 121 and multi-layered body a stopper material layer on an upper surface of the semiconductor layer 15, and then etching back is performed so that the state shown in FIG. 87 can be obtained.

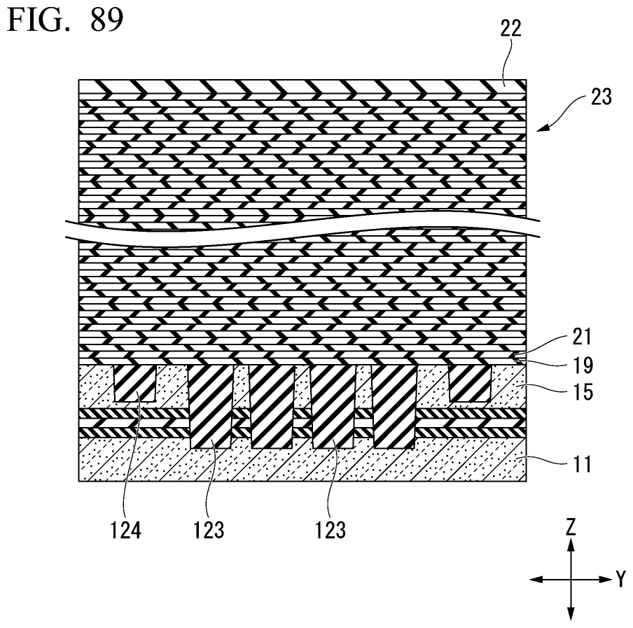

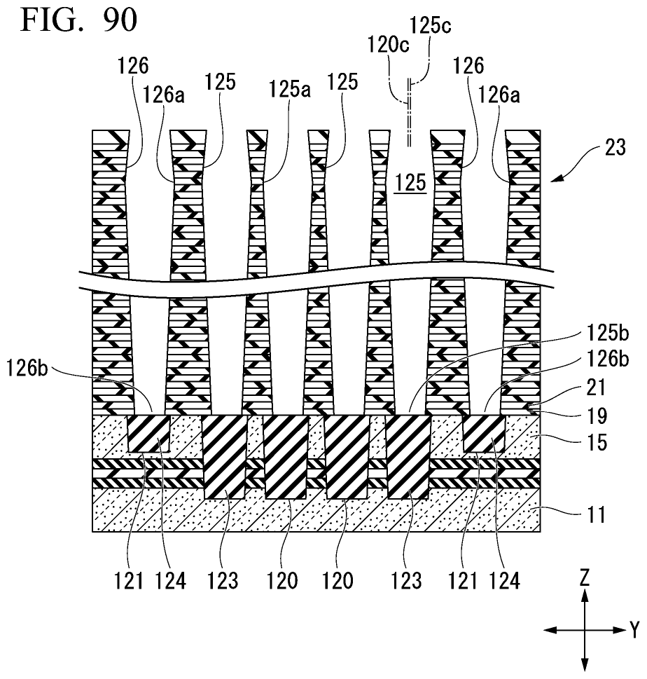

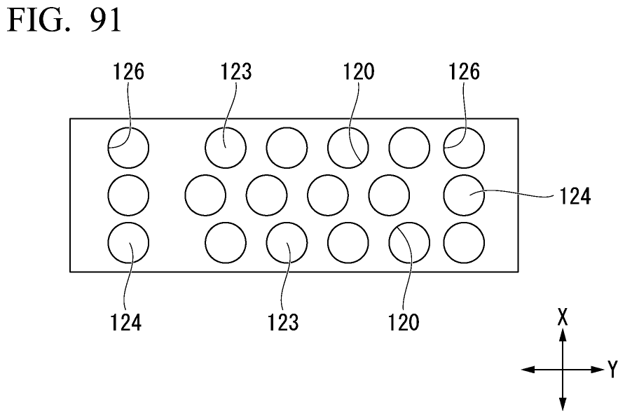

As shown in FIG. 89, a lower multi-layered body 23 is formed which includes an insulating layer 19 and a sacrificial layer 21 which are alternately stacked and includes an insulating layer 22 formed on an uppermost sacrificial layer 21. The insulating layers 19 and 22 are, for example, silicon oxide films, and the sacrificial layer 21 is, for example, a silicon nitride film.

As shown in FIG. 90, a lower memory hole 125 extending from a top part to a bottom part of the lower multi-layered body 23 is formed with respect to the lower multi-layered body 23 to correspond to the formation position of the bottom memory hole 120 described above. At the same time, a lower hole 126 extending from the top part to the bottom part of the lower multi-layered body 23 is formed to correspond to the formation position of the bottom slit 121. The lower memory hole 125 and the lower hole 126 can be formed by an etching method such as reactive ion etching. Although FIG. 91 is a plan view showing FIG. 90, what is formed in the lower multi-layered body 23 in the state shown in FIGS. 90 and 91 is the lower holes 126 formed to be adjacent at a predetermined interval in the X direction as shown in FIG. 91.

The lower memory hole 125 has a shape such that an inner diameter gradually decreases toward a lower end portion side thereof, and an enlarged inner diameter part 125a is formed at a position slightly lower than an upper end of the lower memory hole 125. A lower end portion 125b of the lower memory hole 125 reaches the stopper material 123 of the bottom memory hole 120.

The lower hole 126 has a shape such that an inner width (width in the Y direction) gradually decreases toward a lower end portion side thereof, and an enlarged inner width part 126a is formed at a position slightly lower than an upper end of the lower hole 126. A lower end portion 126b of the lower hole 126 reaches the stopper material 124 of the bottom slit 121.

Here, due to an error in positioning accuracy when the lower memory hole 125 is formed, a position of a central axis of the lower memory hole 125 and a position of a central axis of the bottom memory hole 120 may be slightly displaced in the Y direction (left-right direction) of FIG. 90. Furthermore, due to an error in positioning accuracy when the lower memory hole 125 is formed, a position of a center 125c of the lower memory hole 125 and a position of a center 120c of the bottom memory hole 120 may be slightly displaced in the Y direction (left-right direction) of FIG. 90.

However, since a Y-direction length (diameter) of an upper portion of the bottom memory hole 120 is larger than a Y-direction length (inner diameter) of the lower end portion 125b of the lower memory hole 125, the positional displacement described above can be absorbed. Therefore, the lower end portion 125b of the lower memory hole 125 can reliably reach an upper surface of the stopper material 123.

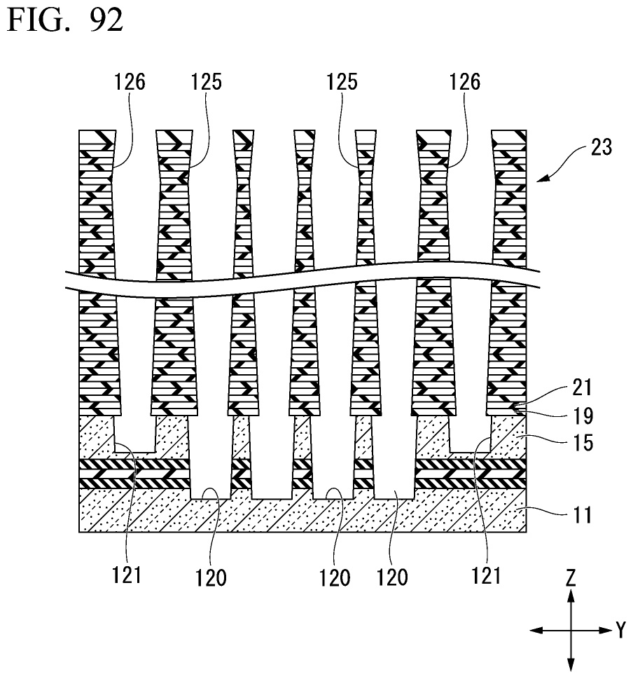

As shown in FIG. 92, through the lower memory hole 125 and the lower hole 126, the stopper materials 123 and 124 therebelow are removed by a method such as ashing. Therefore, the lower memory hole 125 and the bottom memory hole 120 communicate with each other, and the lower hole 126 and the bottom slit 121 communicate with each other. In this method, only the stopper materials 123 and 124 can be removed, and the inner diameter of the lower memory hole 125 and the inner width of the lower hole 126 are not unnecessarily expanded.

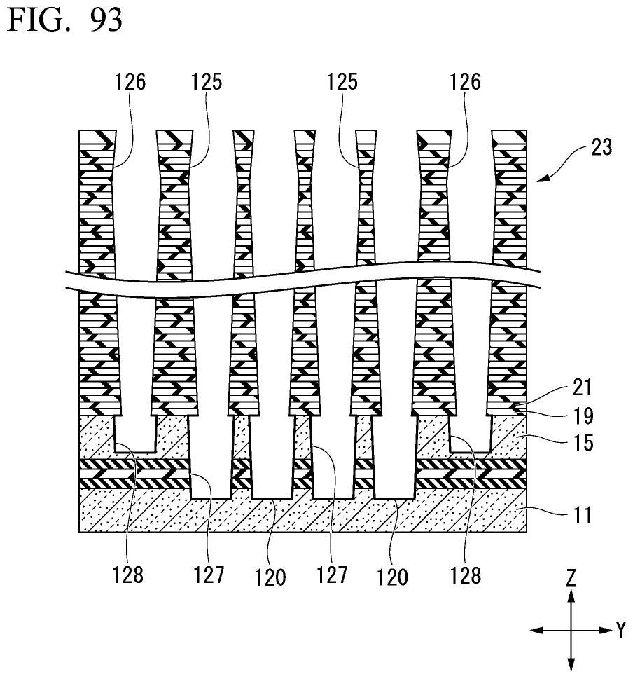

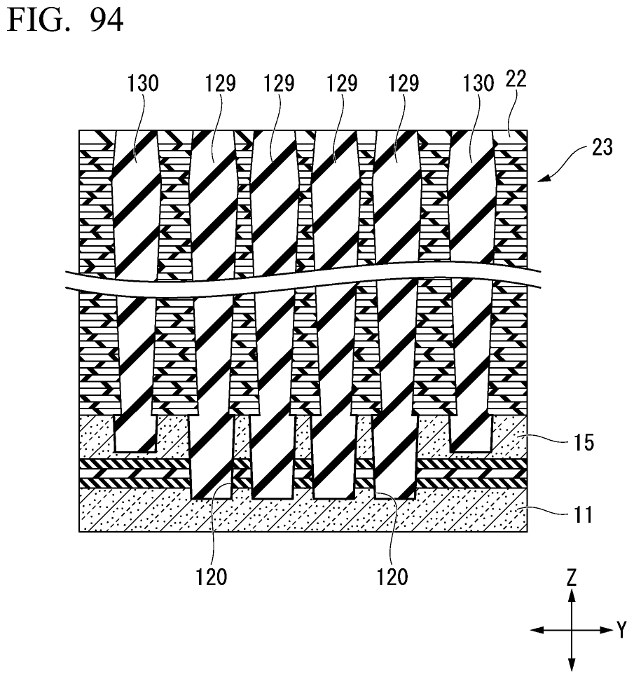

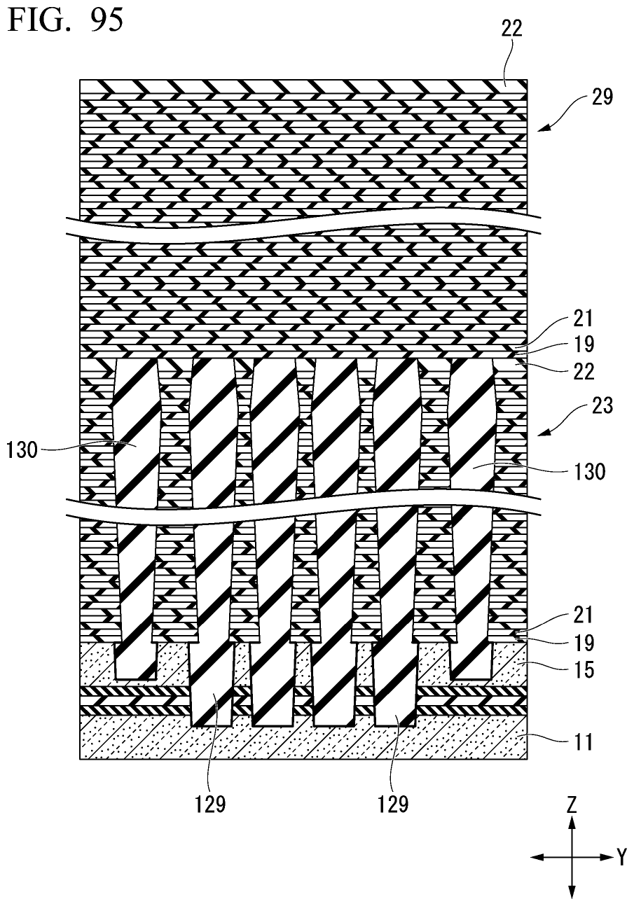

As shown in FIG. 93, the semiconductor layers 11 and 15 exposed on an inner surface of the bottom memory hole 120 are oxidized to form a silicon oxide layer 127. At the same time, the semiconductor layer 15 exposed on an inner surface of the bottom slit 121 is oxidized to form a silicon oxide layer 128.

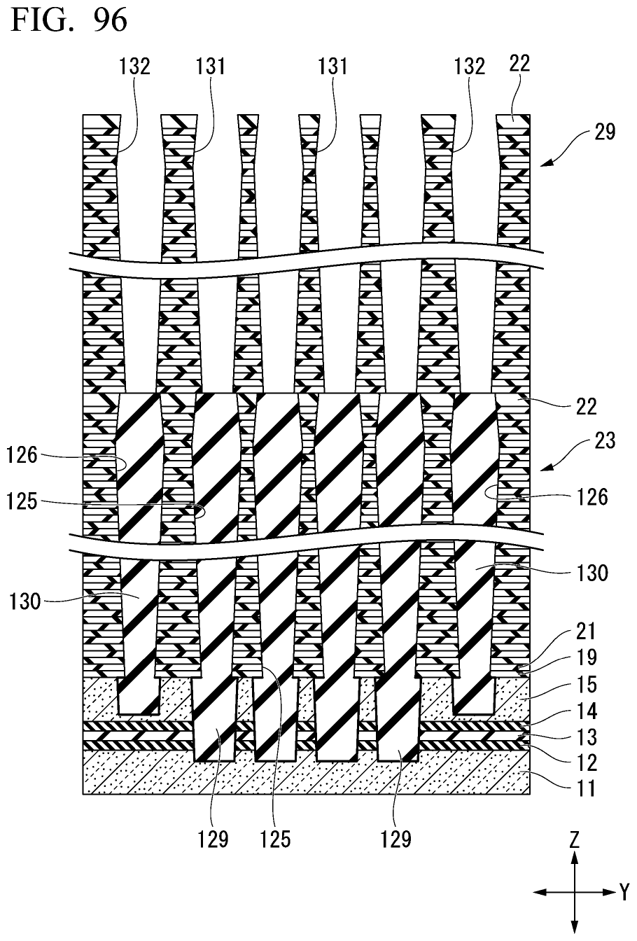

As shown in FIG. 94, a filler 129 is formed to fill the bottom memory hole 120 and the lower memory hole. A carbon film or the like can be applied to the filler 129. At the same time, a filler 130 is formed to fill the bottom slit 121 and the lower hole 126. A carbon film or the like can be applied to the filler 130.

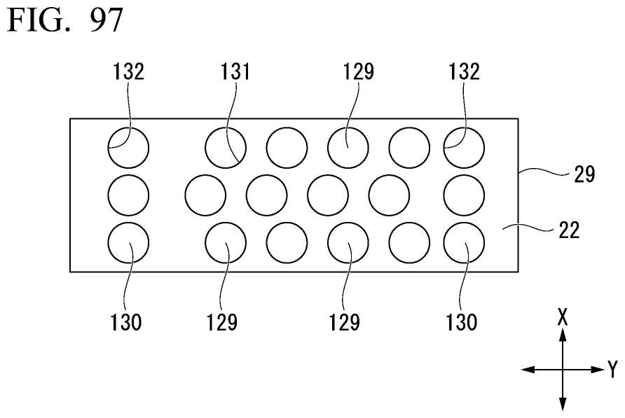

As shown in FIG. 95, an upper multi-layered body 29 is formed on the lower multi-layered body 23. A structure of the upper multi-layered body 29 is the same as that of the lower multi-layered body 23, the insulating layer 19 and the sacrificial layer 21 are alternately stacked, and the insulating layer 22 is formed on the uppermost sacrificial layer 21.

As shown in FIG. 96, an upper memory hole 131 extending from a top part to a bottom part of the upper multi-layered body 29 is formed with respect to the upper multi-layered body 29 to correspond to the formation position of the lower memory hole 125 described above. At the same time, an upper hole 132 extending from the top part to the bottom part of the upper multi-layered body 29 is formed with respect to the upper multi-layered body 29 to correspond to the formation position of the lower hole 126 described above. The upper memory hole 131 and the upper hole 132 can be formed by an etching method such as reactive ion etching. FIG. 97 is a plan view showing the structure of FIG. 96.

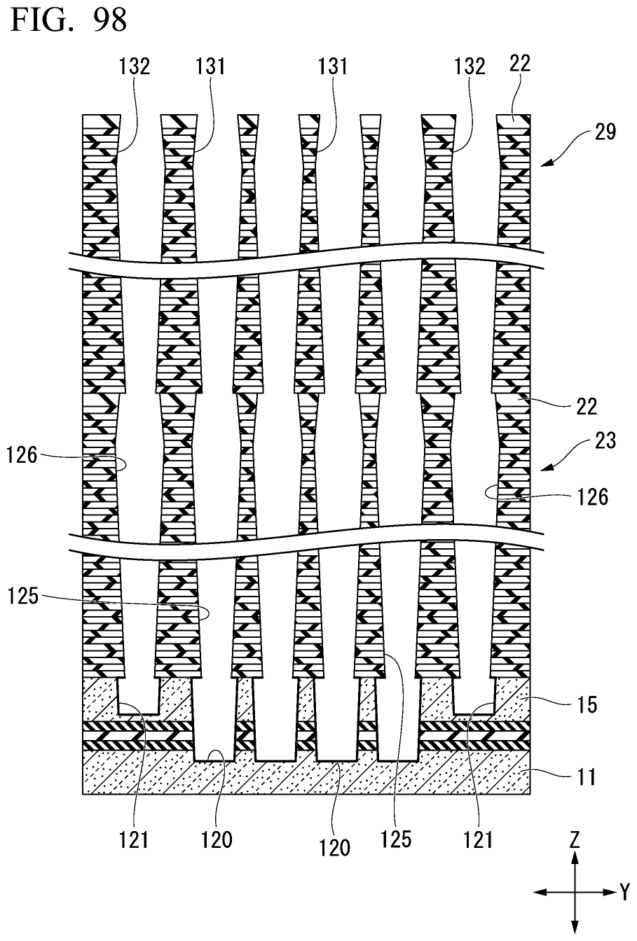

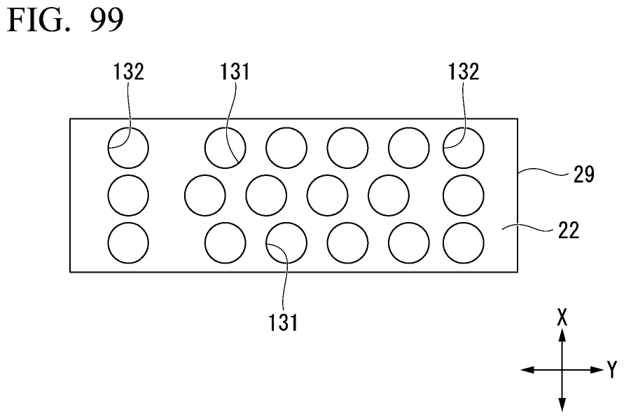

As shown in FIG. 98, the filler 129 of the lower memory hole 125 and the filler 129 of the bottom memory hole 120 are removed via the upper memory hole 131 by a method such as ashing. At the same time, the filler 130 of the lower hole 126 and the filler 130 of the bottom slit 121 are removed via the upper slit 132 by a method such as ashing.

Therefore, the upper memory hole 131, the lower memory hole 125, and the bottom memory hole 120 communicate with each other. Also, the upper slit 132, the lower hole 126, and the bottom slit 121 communicate with each other. FIG. 99 is a plan view showing the structure of FIG. 98.

In the above-described process of removing the carbon film by a method such as ashing, only the fillers 129 and 130 can be removed. Therefore, the upper memory hole 131 and the lower memory hole 125 having target inner diameters can be obtained without unnecessarily expanding the inner diameters of the upper memory hole 131 and the lower memory hole 125. Also, the upper hole 132 and the lower hole 126 having target inner widths can be obtained without unnecessarily expanding the inner widths of the upper hole 132 and the lower hole 126.

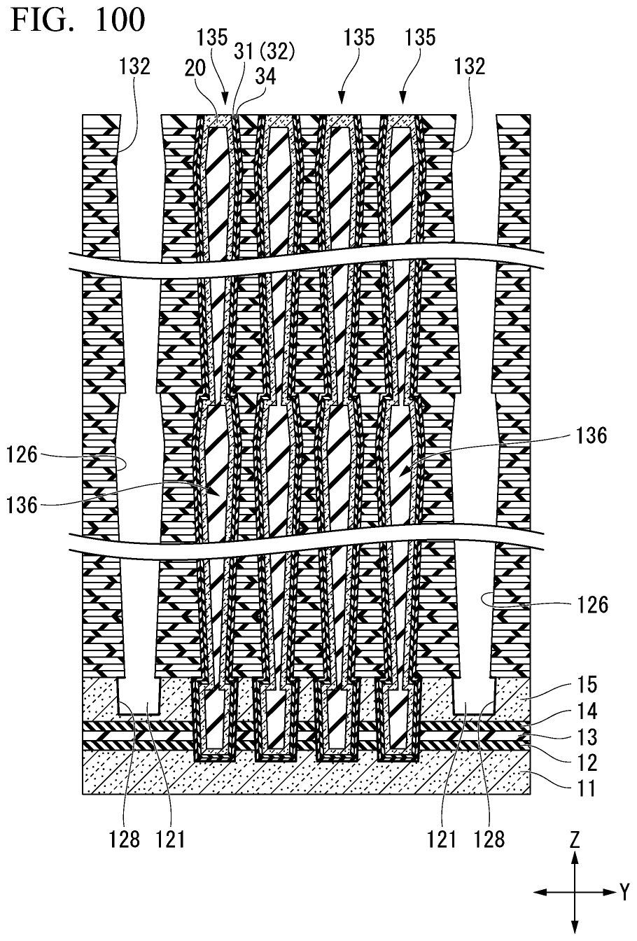

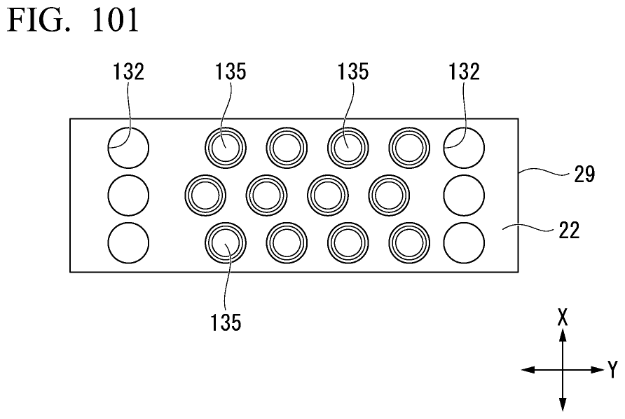

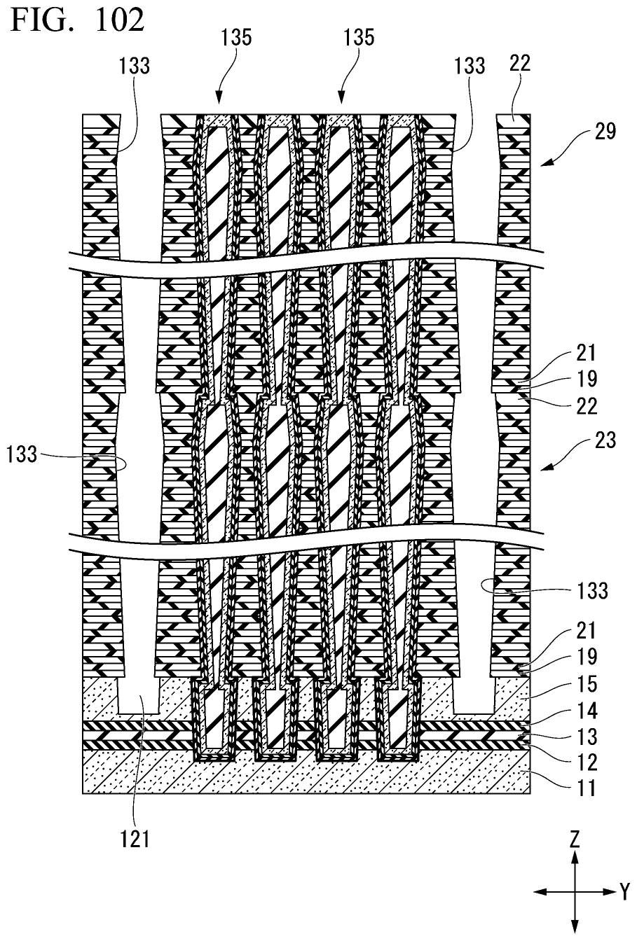

As shown in FIG. 100, depositions serving as a base for forming the columnar part LCL1 are performed in the bottom memory hole 120, the lower memory hole 125, and the upper memory hole 131. Depositions of the first block film 34, the charge storage film 32, the tunnel insulating film 31, the semiconductor body 20, and the core part 50 are performed. Therefore, an upper layer base columnar part 135 as a base for the upper layer columnar part UCL1 and a lower layer base columnar part 136 as a base for the lower layer columnar pan LCL1 are formed. FIG. 101 is a plan view showing the structure of FIG. 100.

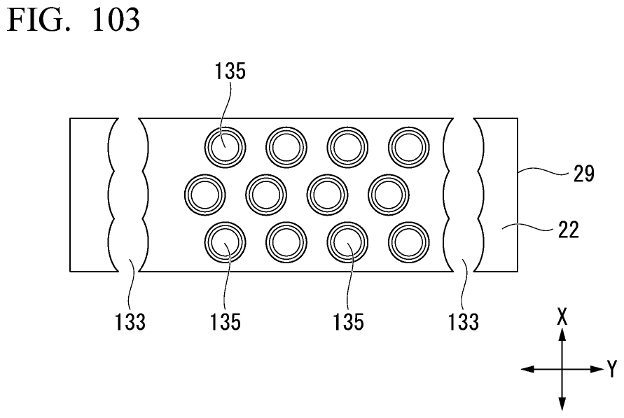

The silicon oxide layer 128 formed in the bottom slit 121 is removed, and portions between the plurality of the lower holes 126 disposed in the X direction and between the plurality of the upper holes 132 disposed in the X direction are removed by etching. Therefore, the lower holes 126 disposed in the X direction are connected to each other. The upper holes 132 disposed in the X direction are connected to each other. Therefore, the connected hole slit 133 shown in FIG. 103 is formed. As described above, the structure shown in FIGS. 102 and 103 is obtained.

The structure shown in FIGS. 102 and 103 is equivalent to the structure shown previously in FIG. 22, 37, 63, or the like in a state in the middle of the manufacture. Accordingly, when manufacturing methods equivalent to the subsequent manufacturing methods described after those figures are performed, a structure equivalent to that of the semiconductor storage devices shown in FIGS. 1 to 8 can be obtained.

For example, etching processing using an etchant is performed through the connected hole slit 133 and the slit 121, the protective layer 14, the sacrificial layer 13, and the protective layer 12 formed in a region that will become an interconnection layer region A are removed, and therefore a hollow part is formed.

From this state, a liner film is formed on inner surfaces of the connected hole slit 133 and the slit 121, and etching is performed on the large diameter part formed at the lower end portion of the lower layer base columnar part 38 exposed in the hollow part. Due to the etching, the first block film, the charge storage film, and the tunnel insulating film on an outer circumferential side of the large diameter part are removed. Due to the etching, a connection part of the semiconductor body can be formed in the hollow part.

Thereafter, when a conductive layer is formed to fill the hollow part, the source line 10b equivalent to the source line 10b shown in FIG. 4 can be formed. Therefore, the interconnection layer region 10A having the semiconductor layer 10a, the source line 10b, and the semiconductor layer 10c can be formed.

After the interconnection layer region 10A is formed, the liner film is removed, etching is performed through the connected hole slit 133 and the slit 121, and therefore the sacrificial layer 21 stacked on the lower multi-layered body 23 and the upper multi-layered body 29 are removed. The sacrificial layer 21 can be removed by an etchant or an etching gas supplied through the connected hole slit 133 and the slit 121. A hollow can be formed in the portion at which the sacrificial layer 21 has been formed.

When the block insulating film and electrodes are formed in the hollow, the structure according to the fourth embodiment whose detailed structure is shown in FIG. 42 can be realized.

While a plurality of embodiments and modified examples have been described above, the embodiments are not limited to the examples described above. For example, the plurality of embodiments and modified examples described above may be realized in combination with each other.

While certain embodiments have been described, these embodiments have been presented by way of example only, and are not intended to limit the scope of the inventions. Indeed, the novel embodiments described herein may be embodied in a variety of other forms: furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a substrate;
an interconnection layer region on the substrate;
a multi-layered body on the interconnection layer region, the multi-layered body including a plurality of conductive layers and a plurality of insulating layers, the plurality of the conductive layers and the plurality of the insulating layers being alternately stacked one layer by one layer in a first direction, the first direction being a thickness direction of the substrate; and
a columnar part including a semiconductor body and a memory part, the semiconductor body extending in the first direction, the memory part being between the semiconductor body and each of the plurality of the conductive layers, the columnar part penetrating the multi-layered body, the columnar part being connected to the interconnection layer region, wherein
the multi-layered body has an end portion facing the interconnection layer region as an end portion in the first direction,
the columnar part includes a first portion and a second portion, the first portion is at the end portion of the multi-layered body, the second portion is closer to the substrate than the first portion is,
the first portion has a center,
the second portion has a center, and
the center of the second portion in a second direction is displaced in the second direction with respect to the center of the first portion in the second direction, the second direction crosses the first direction.

2. The semiconductor storage device according to claim 1, wherein
a width of the second portion in the second direction is larger than a width of the first portion in the second direction.

3. The semiconductor storage device according to claim 1, wherein
the columnar part includes a large diameter part and a small diameter part,
the large diameter part is at a portion at which the columnar part faces the interconnection layer region,
the large diameter part is at a boundary position between the multi-layered body and the interconnection layer region, and
the small diameter part is closer to the substrate than the large diameter part is.

4. The semiconductor storage device according to claim 1, further comprising:
an insulating part dividing the multi-layered body into a plurality of regions in the second direction, wherein
the insulating part includes a portion penetrating the multi-layered body in the first direction and facing the interconnection layer region,
the insulating part includes a third portion and a fourth portion, the third portion being at the end portion of the multi-layered body, the fourth portion being closer to the substrate than the third portion is, and
a width of the fourth portion in the second direction is larger than a width of the third portion in the second direction.

5. The semiconductor storage device according to claim 1, further comprising:
an insulating part dividing the multi-layered body into a plurality of regions in the second direction, wherein
the insulating part includes a portion penetrating the multi-layered body in the first direction and facing the interconnection layer region,
the insulating part includes a third portion and a fourth portion, the third portion being at the end portion of the multi-layered body, the fourth portion being closer to the substrate than the third portion is,
the third portion has a center,
the fourth portion has a center, and
the center of the third portion in the second direction is displaced in the second direction with respect to the center of the fourth portion in the second direction.

6. The semiconductor storage device according to claim 1, wherein
the columnar part includes a large diameter part,
the large diameter part has a circumferential portion
the large diameter part is at a portion at which the columnar part is on the interconnection layer region,
the large diameter part is at a boundary position between the multi-layered body and the interconnection layer region,
the semiconductor body includes a connection part, and
the connection part of the semiconductor body is on the circumferential portion of the large diameter part.

7. The semiconductor storage device according to claim 1, wherein
the columnar part includes a maximum diameter part and a large diameter part,
the maximum diameter part is at a portion at which the columnar part is on the interconnection layer region,
the maximum diameter part and the large diameter part overlaps each other at a boundary position between the multi-layered body and the interconnection layer region.
